(19) United States
(12) Patent Application Publication
(10) Pub. No.: US 2022/0137266 A1
(43) Pub. Date: May 5, 2022

(54) RESIN LAYER, OPTICAL FILM, AND IMAGE DISPLAY DEVICE

(71) Applicant: DAI NIPPON PRINTING CO., LTD., Tokyo (JP)

(72) Inventors: Keisuke EBISU, Tokyo (JP); Yoshimasa OGAWA, Tokyo (JP); Jun SATO, Tokyo (JP); Kana HORII, Tokyo (JP); Keisuke YAMADA, Tokyo (JP); Kazuya HONDA, Tokyo (JP); Atsuhiro KOBAYASHI, Tokyo (JP); Yousuke KOUSAKA, Tokyo (JP); Takayuki FUKUDA, Tokyo (JP)

(21) Appl. No.: 17/435,327

(22) PCT Filed: Feb. 27, 2020
(86) PCT No.: PCT/JP2020/008186

§ 371 Date: Aug. 31, 2021

(30) Foreign Application Priority Data
Mar. 1, 2019 (JP) 2019-037342
Mar. 29, 2019 (JP) 2019-068027
Sep. 27, 2019 (JP) 2019-177178

(51) Int. Cl. G02B 1/14; C08G 18/62; C08J 5/18; G06F 1/16; G09F 9/33

(52) U.S. Cl. CPC G02B 1/14; C08G 18/6225; C08J 2375/06; G06F 1/1652; G09F 9/335; C08J 5/18

(57) ABSTRACT

According to one aspect of the present invention, a light-transmitting resin layer used in an image display device is provided, in which the layer is divided into three equal parts in the film thickness direction of the layer, which are referred to as first region, second region, and third region, respectively, in the order from a first surface of the layer to a second surface opposite to the first surface. Upon an indentation test in which a Berkovich indenter is pressed into the first region, the second region, and the third region at a certain load on the cross-section of the layer in the film thickness direction, and in which the displacement amount in the first region, in the second region, and in the third region are determined as d1, d2, and d3, respectively, the layer satisfies the relationship of d1<d2<d3.

### CROSS-REFERENCE TO RELATED APPLICATION

The present application enjoys the benefit of priority to the prior Japanese Patent Application Nos. 2019-37342 (filed on Mar. 1, 2019), 2019-68027 (filed on Mar. 29, 2019) and 2019-177178 (filed on Sep. 27, 2019), the entire disclosures of which are incorporated herein by reference.

### TECHNICAL FIELD

The present invention relates to a resin layer, an optical film, and an image display device.

### BACKGROUND ART

Image display devices such as smartphone and tablet terminal have been popular in recent years, and development of foldable image display devices is currently ongoing. Such devices as smartphone and tablet terminal are usually covered with glass. However, since the glass is excellent in hardness but is difficult to bend, if an image display device covered with glass is deliberately folded, the glass cover is highly likely to be broken. Thus, a foldable optical film comprising a foldable resin base material and a hard coat layer or a foldable optical film composed of a resin is contemplated, instead of a glass cover, for use in foldable image display devices (see, for example, Japanese Patent Documents 1 and 2). Patent Document 2 further discloses that the hard coat layer contains organic particles in order to suppress the outside light reflection and glare.

### PRIOR ART DOCUMENTS

### Patent Document

Patent Document 1: JP2016-125063A
Patent Document 2: WO2017/14198

### SUMMARY OF THE INVENTION

An optical film used in such a foldable image display device is required to have, in addition to good foldability, impact resistance because the front surface of the optical film may receive impacts. In this respect, when an impact force is applied from the front surface of an optical film, a depression may be formed on the front surface of the optical film, and some components located interior to the optical film in an image display device (for example, a polarizing plate) may be damaged. Therefore, the impact resistance which prevents the depression on the front surface of the optical film when an impact force is applied on the front surface of the optical film, or the impact resistance which prevents the depression on the front surface of the optical film and damages on components located interior to the optical film in the image display device (for example, a polarizing plate) when an impact force is applied on the front surface of the optical film is required.

Further, when such an optical film is maintained in a folded state, the bent part of the optical film may be creased. So far, optical films having good foldability have been proposed, but creases have not been considered. Since the foldability evaluates cracking or breaking upon folding, the foldability is not an index which is related to the fact that there is no crease. Therefore, even an optical film having good foldability may have a crease.

Further, since the foldable optical film as described above is used instead of the cover glass, the film may be pressed by a finger. Since the foldable optical film is softer than the cover glass, the film may be temporarily dented and a mark (pressing mark) may remain.

At present, it is considered to add organic particles to the hard coat layer in order to make the pressing marks less noticeable. However, when the organic particles are added, cracks can be generated at the interface between the organic particles and the binder resin when the optical film is folded, resulting in cracking of the optical film.

The present invention is designed to solve the above problems. That is, an object of the present invention is to provide a resin layer having good foldability and good impact resistance, and an optical film and an image display device including the resin layer. Moreover, another object of the present invention is to provide a foldable optical film which does not easily crease and has excellent impact resistance, and an image display device containing the foldable optical film. Still another object of the present invention is to provide a foldable optical film which does not cause noticeable pressing marks and does not easily crack when folded, and an image display device containing the foldable optical film.

The present invention includes the following inventions.

[1] A light-transmitting resin layer for use in an image display device, wherein the resin layer is divided into three equal parts in the film thickness direction of the resin layer, which are defined as first region, second region, and third region in the order from a first surface of the resin layer to a second surface opposite to the first surface; and upon an indentation test in which a Berkovich indenter is pressed into the first region, the second region, and the third region at a certain load on the cross-section of the resin layer in the film thickness direction and in which the displacement amounts in the first region, in the second region, and in the third region are determined as d1, d2, and d3, respectively, the resin layer satisfies the relationship of d1<d2<d3.
[2] The resin layer according to [1], wherein the ratio of the displacement amount d1 to the displacement amount d3 is 0.85 or less.
[3] The resin layer according to [1] or [2], wherein the displacement amounts d1 to d3 are each 200 nm or more and 1,000 nm or less.
[4] The optical resin layer according to any one of [1] to [3], wherein the film thickness is 20 μm or more and 150 μm or less.
[5] A foldable optical film with a laminated structure, comprising at least the resin layer according to any one of [1] to [4].
[6] The optical film according to [5], further comprising a functional layer provided on either one of the first surface and the second surface of the resin layer.
[7] The optical film according to [5] or [6], further comprising a resin base material provided on either one of the first surface and the second surface of the resin layer.
[8] A foldable light-transmitting optical film, comprising a resin base material and a resin layer provided on a first surface of the resin base material, wherein the thickness of the resin base material is 20 μm or less; the film thickness of the resin layer is 50 μm or more; the ratio of the film thickness of the resin layer to the thickness of the resin base material is 4.0 or more and 12.0 or less; when an indentation test in which a Berkovich indenter is pressed at a maximum load of 200 μN into the cross-section of the resin base material in the thickness direction is carried out, the displacement amount of the resin base material is 50 nm or more and 250 nm or less; and when the indentation test is carried out on the cross-section of the resin layer in the film thickness direction, the displacement amount of the resin layer is 200 nm or more and 1,500 nm or less.
[9] The optical film according to [8], wherein the resin base material contains at least any of a polyimide resin, a polyamide resin, and a polyamideimide resin.
[10] The optical film according to [8] or [9], further comprising a hard coat layer provided on a second surface opposite to the first surface of the resin base material.
[11] A foldable optical film for use in an image display device, comprising a resin base material and a resin layer provided on one surface of the resin base material and containing organic particles, wherein the resin layer has an uneven surface, and the organic particles are unevenly distributed on the side of the resin base material with respect to a center line that bisects the resin layer in the film thickness direction of the resin layer.
[12] The optical film according to [11], wherein the resin base material contains one or more resins selected from the group consisting of a polyimide resin, a polyamideimide resin, a polyamide resin, and a polyester resin.
[13] The optical film according to [11] or [12], wherein the resin layer has a film thickness of 2 μm or more and 15 μm or less.
[14] The optical film according to any one of [11] to [13], wherein the indentation hardness of the lower part of the resin layer is smaller than the indentation hardness of the upper part of the resin layer.
[15] The optical film according to any one of [11] to [14], wherein the resin layer contains a first resin layer and a second resin layer provided on the surface side of the resin layer than the first resin layer, and the first resin layer contains organic particles.
[16] The optical film according to any one of [5] to [15], wherein no crack or break is formed in the optical film when the optical film is folded at an angle of 180 degrees in a manner that leaves a gap of 10 mm between the opposite edges and then unfolded, and this process is repeated 100,000 times.
[17] An image display device comprising a display device and the resin layer according to any one of [1] to [4] or the optical film according to any one of [5] to [16] which is placed on the observer's side of the display device.
[18] The image display device according to [17], wherein the display device is an organic light-emitting diode device.

According to the first aspect of the present invention, a resin layer having good foldability and good impact resistance, and an optical film and an image display device containing the resin layer can be provided. According to the second aspect of the present invention, a foldable optical film which does not easily crease and has good impact resistance, and an image display device containing the foldable optical film can be provided. According to the third aspect of the present invention, a foldable optical film which does not cause noticeable pressing marks and does not easily crack when folded, and an image display device containing the foldable optical film can be provided.

### BRIEF DESCRIPTION OF THE DRAWINGS

FIG. 1 shows a schematic diagram of a resin layer according to the first embodiment.

FIG. 2 is an enlarged view showing a portion of the resin layer shown in FIG. 1.

FIG. 3 shows a schematic diagram of the optical film according to the first embodiment.

FIG. 4(A) to FIG. 4(C) schematically show the steps of the successive folding test.

FIG. 5 shows a schematic diagram of another optical film according to the first embodiment.

FIG. 6 shows a schematic diagram of an image display device according to the first embodiment.

FIG. 7 shows a schematic diagram of the optical film according to the second embodiment.

FIG. 8(A) and FIG. 8(B) schematically show steps of the static folding test.

FIG. 9 shows a schematic diagram of the optical film according to the third embodiment.

FIG. 10 is an enlarged top view showing a portion of the optical film shown in FIG. 9.

FIG. 11 shows a schematic diagram of another optical film according to the third embodiment.

### DESCRIPTION OF EMBODIMENTS

### First Embodiment

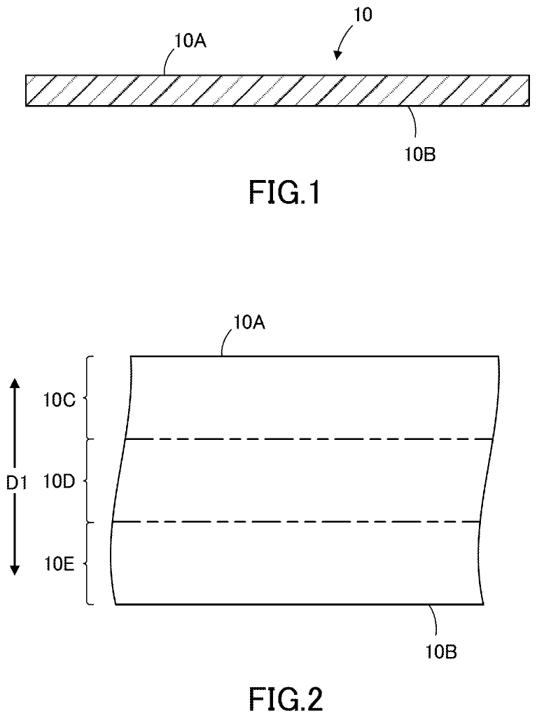

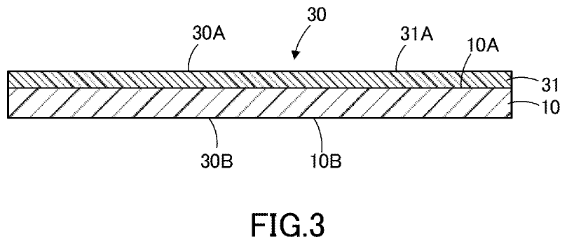

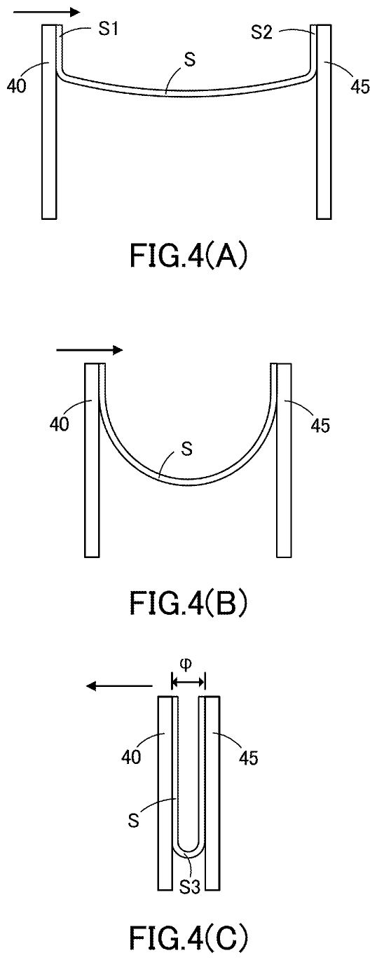

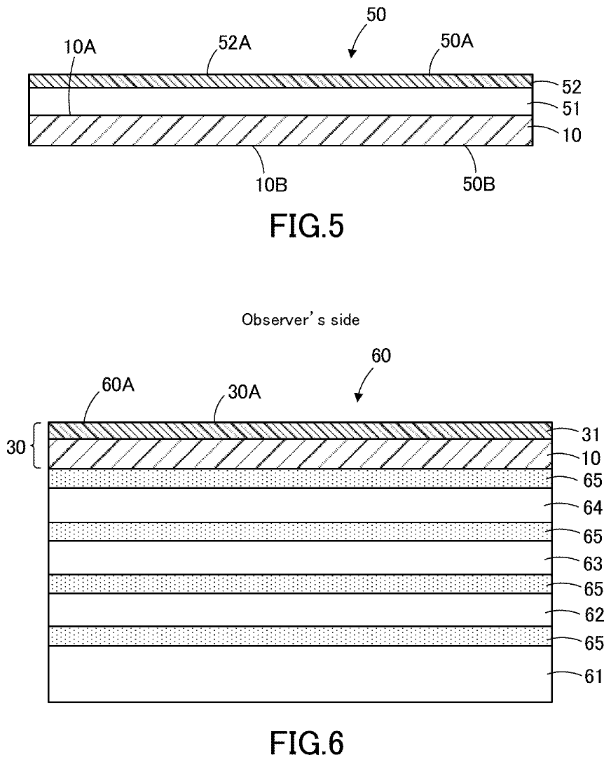

A resin layer, an optical film, and an optical film and an image display device according to the first embodiment of the present invention will be described below with reference to the drawings. In this specification, the terms “film” and “sheet” are not distinguished from each other only on the basis of the difference of names. For example, the term “film” is thus used to refer inclusively to a member called “sheet.” FIG. 1 shows a schematic diagram of the resin layer according to the present embodiment, and FIG. 2 is an enlarged view showing a portion of the resin layer shown in FIG. 1, and FIG. 3 shows a schematic diagram of the optical film according to the present embodiment. FIG. 4 schematically shows the steps of the successive folding test, and FIG. 5 shows a schematic diagram of another optical film according to the present embodiment.

### <<<Resin Layer>>>

The resin layer 10 shown in FIG. 1 is used in an image display device and is light-transmitting. The “resin layer” in the present embodiment is a layer of a monolayer structure containing a resin. The resin layer 10 is composed of a light-transmitting resin and provides impact absorption. The resin layer 10 may be used as a single resin layer 10, or may be incorporated in optical films 30 and 50 having a laminated structure. A mold release film may be provided on the resin layer 10. The term “light-transmitting” as used herein refers to a property that allows light transmission, including, for example, a total light transmittance of 50% or more, preferably 70% or more, more preferably 80% or more, and particularly preferably 90% or more. The term “light-transmitting” does not necessarily refer to transparency and may refer to translucency.

As shown in FIG. 2, the resin layer 10 is divided into three equal parts in the film thickness direction D1 of the resin layer 10, which are referred to as first region 10C, second region 10D, and third region 10E, in the order from the first surface 10A of the resin layer 10 to the second surface 10B opposite to the first surface 10A. Upon an indentation test in which a Berkovich indenter is pressed into the first region 10C, the second region 10D, and the third region 10E at a certain load on the cross-section of the resin layer 10 in the film thickness direction D1, and in which the displacement amount in the first region 10C, the displacement amount in the second region 10D, and the displacement amount in the third region 10E are determined as d1, d2, and d3, respectively, the resin layer 10 satisfies the following relationship (1). Since the resin layer of the present embodiment is softer than the functional layer (hard coat layer) and the resin base material, which will be described later, and is more affected by viscosity, the method of measuring the indentation hardness, the Martens hardness, or the like by the nanoindentation method was not suitable. Therefore, the amount of displacement is used as an index of hardness.

d1<d2<d3 (1)

The displacement amounts d1 to d3 can be obtained as follows, using a nanoindenter (for example, TI950 TriboIndenter manufactured by BRUKER Corporation). Specifically, a piece having a size of 1 mm×10 mm is cut out from the resin layer and embedded in an embedding resin to prepare a block, and homogeneous sections having a thickness of 70 nm or more and 100 nm or less and having no openings or the like are cut out from the block according to a commonly used sectioning technique. In this respect, the reason why sections having a thickness of 70 nm or more and 100 nm or less are sliced is because the block remaining after cutting out the sections is used for the measurement, and a cross-section with increased smoothness is produced in the remaining block by cutting sections with the above thickness from the block. If the remaining block has a rough surface, the measurement accuracy may be reduced. For the preparation of sections, for example, an “Ultramicrotome EM UC7” from Leica Microsystems GmbH or the like can be used. Then, the block remaining after cutting out the homogeneous sections having no openings or the like is used as a measurement sample. Subsequently, in the cross-section of the measurement sample obtained after cutting out the above-described sections, a Berkovich indenter (a trigonal pyramid, for example, TI-0039, manufactured by BRUKER Corporation) as the above-described indenter is pressed perpendicularly into the first region of the resin layer at the center in the thickness direction of the cross-section, wherein the indenter is pressed up to the maximum load of 200 μN over 40 seconds under the below-mentioned measurement conditions. The amount of displacement (indentation depth) d1 is thus measured. In this respect, in order to avoid the influence of the side edges of the resin layer, the Berkovich indenter should be pressed into a part of the first region which is 500 nm or more away from both edges of the resin layer toward the center of the resin layer. The arithmetic mean of the measurements at 10 different locations is determined as the displacement amount. In cases where a measured value which falls outside the arithmetic mean plus and minus 20% is included in the measured values, the measured value should be excluded to repeat the measurement again. Whether or not a measured value which falls outside the arithmetic mean plus and minus 20% is included in the measured values should be determined by whether or not a value (%) obtained by the formula (A−B)/B×100 equals or exceeds ±20%, where A represents a measured value and B represents the arithmetic mean. The displacement amounts of the second region and the third region of the resin layer are also measured in the same manner as the displacement amounts of the first region.

### (Measurement Conditions)

Control method: Load control (maximum load of 200 μN)

Lift amount: 0 nm

Preload: 0.5 μN

Loading speed: 5 μN/sec

Dwell time at maximum load: 5 sec

Unloading speed: 5 μN/sec

Temperature: 23±5° C.

Relative humidity: 30 to 70%

The ratio of the displacement amount d1 to the displacement amount d3 (d1/d3) is preferably 0.85 or less. In cases where d1/d3 is 0.85 or less, both excellent foldability and impact resistance can be achieved. The maximum value of d1/d3 is more preferably 0.82 or less or 0.80 or less, and the minimum value is preferably 0.40 or more, 0.50 or more, or 0.60 or more because the generation of wrinkles at the time of bending can be suppressed easily.

The ratio of the displacement amount d1 to the displacement amount d2 (d1/d2) is preferably 0.70 or more and 0.99 or less. In cases where d1/d2 is 0.70 or more, the generation of wrinkles at the time of bending can be suppressed, and when d1/d2 is 0.99 or less, both excellent foldability and impact resistance can be obtained. The minimum value of d1/d2 is more preferably 0.75 or more, 0.80 or more, or 0.85 or more, while the maximum value of d1/d2 is more preferably 0.95 or less, 0.92 or less, or 0.90 or less.

The ratio of the displacement amount d2 to the displacement amount d3 (d2/d3) is preferably 0.70 or more and 0.99 or less. In cases where d2/d3 is 0.70 or more, the generation of wrinkles at the time of bending can be suppressed, and when d2/d3 is 0.99 or less, both excellent foldability and impact resistance can be obtained. The minimum value of d2/d3 is more preferably 0.75 or more, 0.80 or more, or 0.85 or more, while the maximum value of d2/d3 is more preferably 0.95 or less, 0.92 or less, or 0.90 or less.

Each of the displacement amounts d1 to d3 is preferably 1,000 nm or less. In cases where the displacement amounts d1 to d3 are each 1,000 nm or less, the resin layer 10 has sufficient hardness, and excellent impact resistance can be obtained. The maximum value of the displacement amounts d1 to d3 is more preferably 900 nμm or less, 800 nm or less, or 700 nm or less for each, and the minimum value is more preferably 200 nm or more, 300 nm or more, or 350 nm or more for each in order to ensure the foldability of the resin layer 10.

The resin layer 10 preferably has a total light transmittance of 85% or more. The resin layer 10 having a total light transmittance of 85% or more can provide sufficient identifiability of images when the resin layer 10 is used in a mobile terminal. The resin layer 10 preferably has a total light transmittance of 87% or more or 90% or more.

The above total light transmittance can be measured using a haze meter (for example, product name: “HM-150”; manufactured by Murakami Color Research Laboratory Co., Ltd.) in the environment with a temperature of 23±5° C. and a relative humidity of 30% or more and 70% or less by a method in accordance with JIS K7361-1: 1997. The above-described total light transmittance is defined as the arithmetic mean of three measurements obtained by cutting the resin layer into a piece with a size of 50 mm×100 mm, and then setting the cut piece without any curl or wrinkle and without any dirt such as fingerprints or dust to measure the total light transmittance three times for one resin layer. The phrase “measured three times” as used herein should refer not to measuring at the same position three times but to measuring at three different positions. In the resin layer 10, the first surface 10A and the second surface 10B are visually observed to be smooth, and the deviation in the film thickness also falls within ±10%. Accordingly, it is considered that an approximate average total light transmittance of the whole resin layer can be obtained by measuring the total light transmittance at three different positions on the piece cut out from the resin layer. The deviation in total light transmittance is within ±10% even if a measurement object has a size as large as 1 m×3,000 m or as large as a 5-inch smartphone. In cases where it is impossible to cut out a piece in the size as described above from the resin layer, a piece having a diameter of 21 mm or more is required because, for example, the HM-150 has an entrance port aperture having a diameter of 20 mm for the measurement. Thus, a piece may be cut out in a size of 22 mm×22 mm or larger from the resin layer as appropriate. When the resin layer is small in size, the resin layer is gradually shifted or turned in such an extent that the light source spot is within the piece of the resin layer to secure three measurement positions.

The resin layer 10 preferably has a haze value (total haze value) of 3.0% or less. In cases where the above-described haze value of the resin layer is 3.0% or less, the image display screen of a mobile terminal in which the resin layer is used can be inhibited from turning white in color. The above-described haze value is more preferably 2.0% or less, 1.5% or less, 1.0% or less, or 0.5% or less.

The above haze value can be measured using a haze meter (for example, product name: “HM-150”; manufactured by Murakami Color Research Laboratory Co., Ltd.) in the environment with a temperature of 23±5° C. and a relative humidity of 30% or more and 70% or less by a method in accordance with JIS K7136: 2000. Specifically, the haze value is measured by the same method as for the total light transmittance.

The resin layer 10 preferably has a film thickness of 20 μm or more and 150 μm or less. In cases where the film thickness of the resin layer 10 is 20 μm or more, excellent impact resistance can be obtained. In cases where the film thickness of the resin layer 10 is 150 μm or less, the resin layer 10 does not crack easily and exhibits excellent performance in the successive folding test of 100,000 folding events. The minimum value of the film thickness of the resin layer 10 is more preferably 40 μm or more, or 50 μm or more, while the maximum value for the resin layer 10 is more preferably 120 μm or less, 100 μm or less, 80 μm or less, or 60 μm or less in view of being suitable for thickness reduction and of good workability.

A cross-section of the resin layer 10 is photographed using a scanning electron microscope (SEM) and the film thickness of the resin layer 10 is measured at 10 different locations within the image of the cross-section, and the arithmetic mean of the 10 film thickness values is determined as the film thickness of the resin layer 10.

A specific method of acquiring cross-sectional images is described below. First of all, a piece of 1 mm×10 mm cut from the resin layer is embedded in an embedding resin to prepare a block, and homogeneous sections having a thickness of 70 nm or more and 100 nm or less and having no openings or the like are sliced from the block according to a commonly used sectioning technique. For the preparation of sections, for example, an “Ultramicrotome EM UC7” from Leica Microsystems GmbH or the like can be used. Then, these homogeneous sections having no openings or the like are used as measurement samples. Subsequently, cross-sectional images of the measurement sample are acquired using a scanning transmission electron microscope (STEM). Examples of the scanning transmission electron microscope (STEM) include S-4800 manufactured by Hitachi High-Technologies Corporation. The cross-sectional images are acquired using the above-described S-4800 by setting the detector to “SE,” the accelerating voltage to “5 kV,” and the emission current to “10 μA.” The focus, contrast, and brightness are appropriately adjusted at a magnification of 100 to 100,000 times, preferably 500 to 50,000 times, still more preferably 1,000 to 10,000 times so that each layer can be identified by observation. Furthermore, the beam monitor aperture, the objective lens aperture, and the WD may be respectively set to “3,” “3,” and “8 mm,” in acquirement of cross-sectional images using the above-described S-4800. For the measurement of the film thickness of the resin layer, it is important that the contrast at the interfacial boundary between the resin layer and another layer (for example, the embedding resin) can be observed as clearly as possible when the cross-section is observed. In cases where the interfacial boundary is hardly observed due to lack of contrast, a staining process may be applied because interfacial boundaries between organic layers become easily observed by application of a staining procedure with osmium tetraoxide, ruthenium tetraoxide, phosphotungstic acid, or the like. Additionally, higher magnification may make it more difficult to find the contrast at the interface. In that case, the observation is also carried out with low magnification. For example, the observation is carried out with two magnifications consisting of a higher magnification and a lower magnification, such as 500 and 10,000 times, or 1,000 and 20,000 times, to determine the above arithmetic means at both magnifications, which are further averaged to determine the film thickness of the resin layer.

The resin as a component of the resin layer 10 is not limited to a particular resin as long as the resin satisfies the above relationship (1). Examples of such a resin include a cured product (polymerized product) of a radiation-curable compound (radiation-polymerizable compound). The radiation in the present specification includes visible light, ultraviolet light, X-rays, electron beams, α-rays, μ-rays, and γ-rays. Examples of the cured product of the radiation-curable compound include urethane resins and silicone resins.

### (Urethane Resin)

The urethane resin is a resin having urethane linkages. Examples of the urethane resin include a cured product of a radiation-curable urethane resin composition and a cured product of a thermosetting urethane resin composition. The urethane resin is preferably a cured product of a radiation-curable urethane resin composition, among those urethane resin compositions, because the cured product provides high hardness and is also highly mass-producible due to the fast cure rate.

The radiation-curable urethane resin composition contains a urethane (meth)acrylate, while the thermosetting urethane resin composition contains a polyol compound and an isocyanate compound. The urethane (meth)acrylate, the polyol compound, and the isocyanate compound may each be a monomer, oligomer, or prepolymer.

The number of (meth)acryloyl groups (number of functional groups) in the urethane (meth)acrylate is preferably 2 or more and 4 or less. In cases where the number of (meth)acryloyl groups in the urethane (meth)acrylate is less than 2, the optical film is likely to have a lower level of pencil hardness; additionally, in cases where the number of (meth)acryloyl groups in the urethane (meth)acrylate is more than 4, the optical film is curled due to high cure shrinkage and is also likely to be cracked in the resin layer when being folded. The maximum number of (meth)acryloyl groups in the urethane (meth)acrylate is more preferably 3 or less. Both “acryloyl group” and “methacryloyl group” are meant by the word “(meth)acryloyl group.”

The weight average molecular weight of the urethane (meth)acrylate is preferably 1,500 or more and 20,000 or less. In cases where the weight average molecular weight of the urethane (meth)acrylate is less than 1,500, the optical film is likely to have a reduced impact resistance; additionally, in cases where the weight average molecular weight of the urethane (meth)acrylate is more than 20,000, the radiation-curable urethane resin composition is likely to have an increased viscosity and result in reduced coating performance. The minimum weight average molecular weight of the urethane (meth)acrylate is more preferably 2,000 or more, while the maximum weight average molecular weight of the urethane (meth)acrylate is more preferably 15,000 or less.

Additionally, examples of the repeating unit having a structure derived from urethane (meth)acrylate include structures represented by the general formulae (1), (2), (3), and (4).

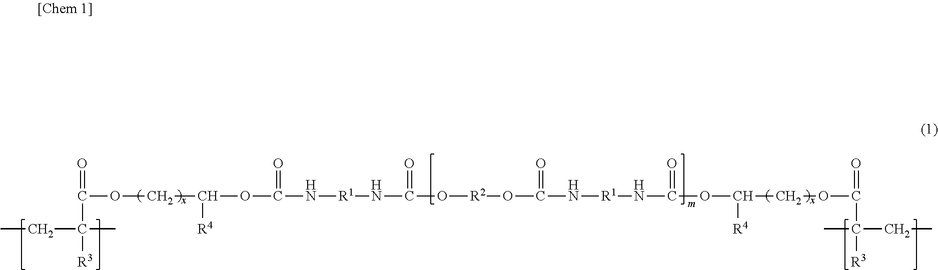

In the above-described general formula (1), R¹ represents a branched alkyl group; R² represents a branched alkyl group or a saturated alicyclic group; R³ represents a hydrogen atom or methyl group; R⁴ represents a hydrogen atom, methyl group, or ethyl group; m represents an integer of 0 or more; x represents an integer of 0 to 3.

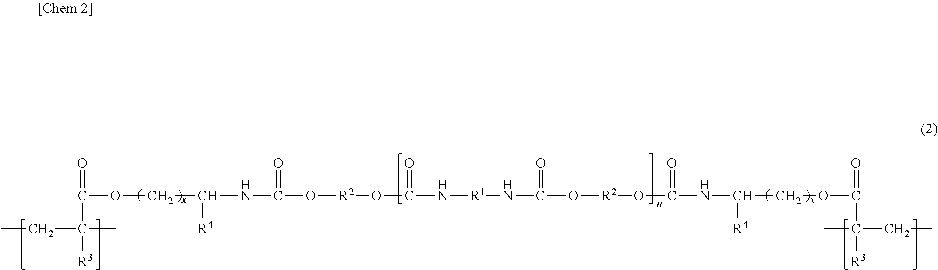

In the above-described general formula (2), R¹ represents a branched alkyl group; R² represents a branched alkyl group or a saturated alicyclic group; R³ represents a hydrogen atom or methyl group; R⁴ represents a hydrogen atom, methyl group, or ethyl group; n represents an integer of 1 or more; x represents an integer of 0 to 3.

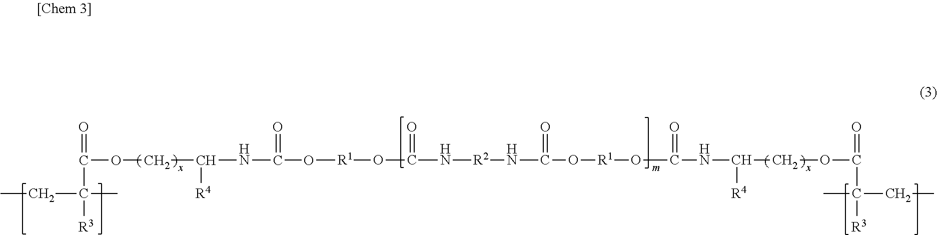

In the above-described general formula (3), R¹ represents a branched alkyl group; R² represents a branched alkyl group or a saturated alicyclic group; R³ represents a hydrogen atom or methyl group; R⁴ represents a hydrogen atom, methyl group, or ethyl group; m represents an integer of 0 or more; x represents an integer of 0 to 3.

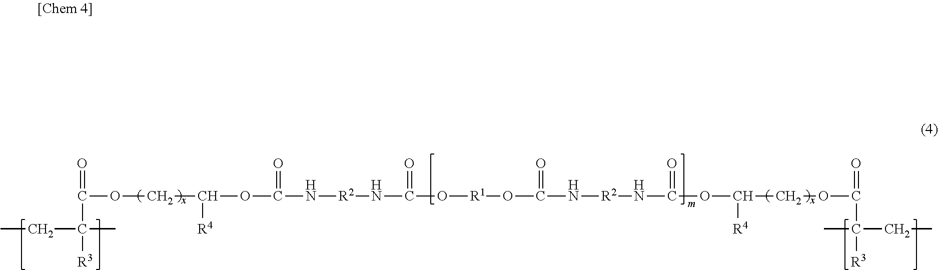

In the above-described general formula (4), R¹ represents a branched alkyl group; R² represents a branched alkyl group or a saturated alicyclic group; R³ represents a hydrogen atom or methyl group; R⁴ represents a hydrogen atom, methyl group, or ethyl group; n represents an integer of 1 or more; x represents an integer of 0 to 3.

Analysis of the resin layer 10 by, for example, pyrolysis gas chromatography mass spectrometry (GC-MS) and Fourier-transform infrared spectroscopy (FT-IR) can determine the structure of a polymer (a repeating unit) that constitutes the resin as a component of the resin layer 10. In particular, pyrolysis GC-MS is useful because it can detect monomers contained in the resin layer 10 and identify the monomer components.

The resin layer 10 may contain, for example, an ultraviolet absorber, a spectral transmittance modifier, an antifouling agent, inorganic particles, and/or organic particles, in addition to the above resin.

### <<<Optical Film>>>

The optical film 30 shown in FIG. 3 is a film having a laminated structure, and comprises at least a resin layer 10. The optical film 30 further comprises, in addition to the resin layer 10, a functional layer 31 provided on either one of the first surface 10A and the second surface 10B of the resin layer 10. The term “functional layer” as used herein refers to a layer which has a certain function. The functional layer 31 has a monolayer structure, and may have a multilayer structure composed of two or more layers. Further, the optical film 30 does not have a base material.

The optical film 30 is foldable. Specifically, no crack or break is preferably formed in the optical film 30 even if the optical film 30 is subjected to the folding test (successive folding test) 100,000 times, 200,000 times, 500,000 times, or 1,000,000 times, in an environment at a temperature of 23±5° C. and a relative humidity of 30% or more and 70% or less. In cases where the optical film 30 is, for example, broken or fractured when the successive folding test is repeated 100,000 times on the optical film 30, the foldability of the optical film 30 is evaluated as low. The evaluation is performed by the above successive folding test with at least 100,000 folding events for the following reason. For example, assuming that an optical film is incorporated in a foldable smartphone, the frequency of folding (the frequency of opening and closing) is very high. Thus, an evaluation obtained by the above successive folding test with, for example, 10,000 or 50,000 folding events is unlikely to be practically meaningful. Specifically, assuming, for example, those who constantly use a smartphone, the smartphone is supposed to be opened and closed at a frequency of 5 to 10 times even during a morning commute by, for example, train or bus, and is supposed to be opened and closed at least 30 times even for one day. Thus, assuming that a smartphone is opened and closed 30 times for one day, a successive folding test with 10,000 folding events is considered as a test assuming that the smartphone is used for one year because 30 times multiplied by 365 days equals 10,950 times. It means that an optical film in the smartphone may have, for example, creases or cracks after using the smartphone for one year, even if the optical film shows a good evaluation result in the successive folding test with 10,000 folding events. Accordingly, an evaluation obtained by the successive folding test with 10,000 folding events is only sufficient for identification of optical films with a level for which the optical films are not usable as commercial products, and even optical films that can be used but are insufficient are evaluated as good in such a successive folding test and are not able to be properly evaluated. Thus, the evaluation should be performed by the above successive folding test with at least 100,000 folding events, to assess whether or not an optical film is practically sufficient. It is more preferable that the bent part is not deformed when the successive folding test is performed on the optical film 30. The successive folding test may be carried out by folding the optical film 30 with the front surface 30A facing either inward or outward. In either case, no crack or break is preferably formed in the optical film 30.

The successive folding test is carried out as follows. As shown in FIG. 4(A), in the successive folding test, a sample S having a size of 30 mm×100 mm is first cut out from the optical film 30. In cases where it is impossible to cut the optical film 30 to a sample S having size of 30 mm×100 mm, for example, a sample S having a size of 10 mm×100 mm may be cut. Using the sample S thus cut out, the edge S1 and the edge S2, which is opposite to the edge S1 are fixed to the fixing members 40 and 45, respectively, arranged parallel to each other of a folding endurance testing machine (for example, product name: “Tension Free U-shape Folding Test Machine DLDMLH-FS”; manufactured by Yuasa System Co., Ltd.; in accordance with IEC 62715-6-1). The sample S is fixed by the fixing members 40 and 45 holding the longitudinal edges of the sample S within about 10 mm on each side. However, in cases where the sample S has a much smaller size than the above-described size, the sample S can be fixed to the fixing members 40 and 45 by means of a tape and then be provided for the measurement if the length required for fixing the sample is up to about 20 mm. Additionally, the fixing member 40 can slide in the horizontal direction, as shown in FIG. 4(A). Preferably, the above testing machine can conduct an evaluation of the durability of a sample against bending load without creating tension or friction inside the sample, differing from, for example, a conventional method in which a sample is wrapped around a rod.

Next, the fixing member 40 is moved close to the fixing member 45 to allow the sample S to be folded and deformed along a line passing through the central part, as shown in FIG. 4 (B); the fixing member 40 is further moved until the gap distance φ between the two opposing edges S1 and S2 of the sample S fixed to the fixing members 40 and 45 reaches 10 mm, as shown in FIG. 4(C); subsequently, the fixing member 40 is moved in the opposite direction to resolve the deformation of the optical film 30.

As shown in FIGS. 4(A) to (C), the fixing member 40 can be moved to allow the sample S to be folded along the line passing through the central part. Additionally, the gap distance φ between the two opposing edges S1 and S2 of the sample S can be maintained at 10 mm by carrying out the successive folding test under the following conditions in such a manner that the bent part S3 of the sample S is prevented from being forced out beyond the lower edges of the fixing members 40 and 45 and the gap distance between the fixing members 40 and 45 is controlled when they approach each other closest. In this case, the outer width of the bent part S3 is considered as 10 mm. It is preferable that no crack or break is formed in the sample S after folding the sample S in a manner that leaves a gap of 10 mm between the opposing edges of the sample S, unfolding the folded sample S, and repeating such a folding test 100,000 times. It is more preferable that no crack or break is formed in the sample S after folding the sample S in a manner that leaves a gap of 8 mm or 6 mm between the opposing edges S1 and S2 of the sample S, unfolding the folded sample S, and repeating such a successive folding test 100,000 times.

### (Folding Conditions)

Reciprocating speed: 40 rpm (revolutions per minute)

Test stroke: 60 mm

Bend angle: 180°

The front surface 30A of the optical film 30 (the surface 31A of the functional layer 31) preferably has a hardness (pencil hardness) of 3H or higher, and more preferably 4H or higher, when measured by the pencil hardness test specified by JIS K5600-5-4: 1999. The pencil hardness test should be carried out as follows: a piece of the optical film 30 is cut to a size of 30 mm×100 mm and fixed with Cello-tape®, manufactured by Nichiban Co., Ltd., over a glass plate without generation of any fold or wrinkle; and in an environment at a temperature of 23±5° C. and a relative humidity of 30% or more and 70% or less, a pencil (for example, product name: “uni”; manufactured by Mitsubishi Pencil Co., Ltd.) is moved using a pencil hardness tester (for example, product name: “Pencil Scratch Hardness Tester (electric type)”; manufactured by Toyo Seiki Seisaku-sho, Ltd.) at a speed of 1 mm/sec on the front surface 30A of the optical film 30 while a load of 750 g is applied to the pencil. The grade of the hardest pencil that does not scratch the front surface of the optical film during the pencil hardness test is determined as the pencil hardness of the optical film. A plural number of pencils with different hardness are used for the measurement of pencil hardness and the pencil hardness test is repeated five times on each pencil. In cases where no scratch is made on the front surface of the optical film with a pencil with specific hardness in four or more out of the five replicates, the pencil with the hardness is determined to make no scratch on the front surface of the optical film. The above-described scratch refers to a scratch which is visibly detectable when the front surface of an optical film subjected to the pencil hardness test is observed under transmitting fluorescent light.

The optical film 30 preferably has a total light transmittance of 85% or more for the same reason as described for the resin layer 10, and more preferably of 87% or more, 88% or more, or 90% or more. The total light transmittance of the optical film 30 is measured by the same method as for the total light transmittance of the resin layer 10.

The optical film 30 preferably has a haze value (total haze value) of 3.0% or less for the same reason as described for the resin layer 10, and more preferably 2.0% or less, 1.5% or less, 1.0% or less, or 0.5% or less. The haze value of the optical film 30 is measured by the same method as for the haze value of the resin layer 10.

In cases where an additional film, such as a polarizing plate, is provided on the front surface 30A or on the back surface 30B of the optical film 30 through an adhesive or adhesion layer, the folding test, the total light transmittance measurement, the haze value measurement, and the like should be carried out after removing the additional film and the adhesive or adhesion layer. Even if such a removal process is performed, the test and measurements are not significantly affected. The haze value measurement should be carried out after removing the adhesive or adhesion layer and further wiping out any residue of the adhesive or adhesion layer with alcohol.

Examples of applications of the optical film 30 include, but are not specifically limited to, image display devices in smartphones, tablet terminals, personal computers (PCs), wearable terminals, digital signage systems, televisions, automotive navigation systems, and the like. Additionally, the optical film 30 is also suitable for vehicle displays. The form of each above-described image display device is also favorable for applications which require flexible forms, such as foldable or rollable forms.

The optical film 30 can be cut into a desired size or may be rolled. In cases where the optical film 30 is cut to a desired size, the cut piece of the optical film is not limited to a particular size, and the size of the film is appropriately determined depending on the display size of an image display device. Specifically, the optical film 30 may be, for example, 2.8 inches or more and 500 inches or less in size. The term “inch” as used herein refers to the length of a diagonal when the optical film is rectangular, and to the length of a diameter when the optical film is circular, and to the average of major and minor axes when the optical film is elliptical. In cases where the optical film is rectangular, the aspect ratio of the optical film is not specifically limited, which refers to the above-described size in inch determined for the optical film, provided that no problem is found in the optical film used for the display screen of an image display device. Examples of the aspect ratio include height-to-width ratios of 1:1, 4:3, 16:10, 16:9, and 2:1. However, particularly in optical films used for vehicle displays and digital signage systems which are rich in designs, the aspect ratio is not limited to the above-described aspect ratios. Additionally, in cases where the optical film 30 is large in size, the optical film will be trimmed to the A5 size (148 mm×210 mm) starting at an arbitrary position and then trimmed to fit size requirements of each measurement item. For example, if the optical film 30 is in a roll form, the optical film 30 of predetermined length should be pulled from a roll to cut a piece of the optical film with a desired size not from an invalid region including both edges along the longitudinal direction of the roll, but from a valid region near the center of the optical film, where the quality is constant.

In an image display device, the optical film 30 may be installed inside the image display device, and is preferably installed near the surface of the image display device. The optical film 30 installed near the surface of an image display device would serve as a cover film (window film), which is used instead of a glass cover.

### <<Functional Layer>>

The functional layer 31 is preferably provided on the side of the first surface 10A of the resin layer 10, that is, on the side of the first region 10C. In cases where the functional layer 31 is provided on the side of the first region 10C, excellent abrasion resistance and foldability are obtained.

The functional layer 31 shown in FIG. 3 is a layer for imparting mainly hardness to the optical film 30, and specifically, a layer that functions as a hard coat layer. However, the functional layer 31 may be a layer which has another function. The “hard coat layer” in the present embodiment refers to a layer having a Martens hardness (HM) of 375 MPa or more at half the height of the cross-section of the functional layer. In this specification, the term “Martens hardness” refers to a hardness measured when an indenter is pressed into a specimen to a depth of 500 nm in a nanoindentation hardness test. Measurement of the Martens hardness based on the above-described nanoindentation technique will be performed on an optical film piece cut to a size of 30 mm×30 mm using a “TI950 TriboIndenter” manufactured by BRUKER Corporation. In other words, a Berkovich indenter (a trigonal pyramid, for example, TI-0039, manufactured by BRUKER Corporation) as the above-described indenter is pressed perpendicularly 500 nm into the cross-section of the functional layer under the below-mentioned measurement conditions. In this respect, a Berkovich indenter should be pressed into a portion of the functional layer in order to avoid the influence of the resin layer and the side edges of the functional layer, wherein the portion is located 500 nm away from the interface between the resin layer and the functional layer toward the center of the functional layer and 500 nm or more away from both edges of the functional layer toward the center of the functional layer. Subsequently, the indenter is held at the position for a certain period of time to relax the residual stress, and then unloaded to measure the maximum load after the relaxation, and the maximum load Pₘₐₓ and the depression area A having a depth of 500 nm are used to calculate a Martens hardness from the value of Pₘₐₓ/A. The Martens hardness is defined as the arithmetic mean of measured values at 10 different locations. In cases where a measured value which falls outside the arithmetic mean plus and minus 20% is included in the measured values, the measured value should be excluded to repeat the measurement again. Whether or not a measured value which falls outside the arithmetic mean plus and minus 20% is included in the measured values should be determined by whether or not a value (%) obtained by the formula (A−B)/B×100 equals or exceeds ±20%, where A represents a measured value and B represents the arithmetic mean.

### (Measurement Conditions)

Control method: Displacement control

Loading speed: 10 nm/sec

Dwell time: 5 sec

Unloading speed: 10 nm/sec

Measurement temperature: 23±5° C.

Relative humidity: 30 to 70%

The functional layer 31 preferably has a Martens hardness of 375 MPa or more and 1500 MPa or less. The functional layer 31 with a Martens hardness of 375 MPa or more can have good hardness, while the functional layer 31 with a Martens hardness of 1500 MPa or less can provide good foldability.

The functional layer 31 preferably has a film thickness of 3 μm or more and 10 μm or less. The functional layer 31 with a film thickness of 3 μm or more can have good hardness, while the functional layer with a film thickness of 10 μm or less can prevent reduction in workability. The “film thickness of the functional layer” as used herein refers to the sum of the film thickness (total thickness) of functional layers in cases where the functional layer has a multilayer structure. The minimum value of the film thickness of the functional layer 31 is more preferably 4 μm or more, or 5 μm or more, while the maximum value is more preferably 8 μm or less, or 7 μm or less.

The film thickness of the functional layer 31 is defined as the arithmetic mean of film thickness values measured at 10 different locations, where a cross-section of the functional layer 31 is imaged using a scanning transmission electron microscope (STEM) or a transmission electron microscope (TEM), and the film thickness of the functional layer 31 is measured at the 10 locations within the image of the cross-section. When the film thickness of the functional layer 31 is measured, a measurement sample is first prepared by the same method as for the resin layer 10. Subsequently, cross-sectional images of the measurement sample are acquired using a scanning transmission electron microscope (STEM) (for example, product name “S-4800”; manufactured by Hitachi High-Technologies Corporation). The cross-sectional images are acquired using the above-described S-4800 by setting the detector to “TE,” the accelerating voltage to “30 kV,” and the emission current to “10 μA.” The focus, contrast, and brightness are appropriately adjusted at a magnification of 5000 to 200,000 times, so that each layer can be identified by observation. The magnification is preferably 10,000 times to 100,000 times, more preferably 10,000 times to 50,000 times, most preferably 25,000 times to 50,000 times. Furthermore, the beam monitor aperture, the objective lens aperture, and the WD may be respectively set to “3,” “3,” and “8 mm,” in acquirement of cross-sectional images using the above-described S-4800. For the measurement of the film thickness of the functional layer, it is important that the contrast at the interface between the functional layer and another layer (for example, the resin layer) can be observed as clearly as possible when the cross-section is observed. In cases where the interfacial boundary is hardly observed due to lack of contrast, a staining process may be applied because interfacial boundaries between organic layers become easily observed by application of a staining procedure with osmium tetraoxide, ruthenium tetraoxide, phosphotungstic acid, or the like. Additionally, higher magnification may make it more difficult to find the interfacial contrast. In that case, the observation is also carried out with a low magnification. For example, the functional layer is observed at two different magnifications consisting of a higher magnification, such as 25,000 or 50,000 times, and a lower magnification, such as 50,000 or 100,000 times, to determine the above arithmetic means at both the magnifications, which are further averaged to determine the film thickness of the functional layer.

Preferably, the functional layer 31 further contains a resin and inorganic particles dispersed in the resin.

### <Resin>

The resin comprises a polymerized product (a cured product) of a polymerizable compound (a curable compound). The polymerizable compound refers to a molecule having at least one polymerizable functional group. Examples of the polymerizable functional group include ethylenic unsaturated groups such as (meth)acryloyl group, vinyl group, and allyl group.

The polymerizable compound is preferably a polyfunctional (meth)acrylate. Examples of the above-described polyfunctional (meth)acrylate include trimethylolpropane tri(meth)acrylate, tripropylene glycol di(meth)acrylate, diethylene glycol di(meth)acrylate, dipropylene glycol di(meth)acrylate, pentaerythritol tri(meth)acrylate, pentaerythritol tetra(meth)acrylate, dipentaerythritol hexa(meth)acrylate, 1,6-hexanediol di(meth)acrylate, neopentyl glycol di(meth)acrylate, ditrimethylolpropane tetra(meth)acrylate, dipentaerythritol penta(meth)acrylate, tripentaerythritol octa(meth)acrylate, tetrapentaerythritol deca(meth)acrylate, isocyanuric acid tri(meth)acrylate, isocyanuric acid di(meth)acrylate, polyester tri(meth)acrylate, polyesterdi(meth)acrylate, bisphenol di(meth)acrylate, digylcerol tetra(meth)acrylate, adamantyl di(meth)acrylate, isobornyl di(meth)acrylate, dicyclopentane di(meth)acrylate, tricyclodecane di(meth)acrylate, and those compounds modified with PO, EO, caprolactone, or the like.

Among those polyfunctional polymerizable compounds, polymerizable compounds with three to six functional groups, such as pentaerythritol triacrylate (PETA), dipentaerythritol hexaacrylate (DPHA), pentaerythritol tetraacrylate (PETTA), dipentaerythritol pentaacrylate (DPPA), trimethylolpropane tri(meth)acrylate, tripentaerythritol octa(meth)acrylate, and tetrapentaerythritol deca(meth)acrylate, are preferred in terms of the ability to achieve the above-described Martens hardness in a suitable manner. In this specification, the word “(meth)acrylate” means acrylate and methacrylate.

The polymerizable compound may further contain a monofunctional (meth)acrylate monomer for the purpose of, for example, adjusting the hardness of the resin and the viscosity of the composition, and improving the adhesiveness of the layer. Examples of the above-described monofunctional (meth)acrylate monomer include hydroxyethyl acrylate (HEA), glycidyl methacrylate, methoxypolyethylene glycol (meth)acrylate, isostearyl (meth)acrylate, 2-acryloyloxyethyl succinate, acryloyl morpholine, N-acryloyloxyethyl hexahydrophthalimide, cyclohexyl acrylate, tetrahydrofuryl acrylate, isobornyl acrylate, phenoxyethyl acrylate, and adamantyl acrylate.

The weight average molecular weight of the above-described monomer is preferably less than 1,000, more preferably 200 or more and 800 or less, in view of improving the hardness of the resin layer. Additionally, the weight average molecular weight of the above-described polymerizable oligomer is preferably 1,000 or more and 20,000 or less, more preferably 1,000 or more and 10,000 or less, and still more preferably 2,000 or more and 7,000 or less.

### <Inorganic Particles>

Silica particles are preferred as the inorganic particles in terms of the ability to achieve excellent hardness, though the inorganic particles are not limited to particular particles as long as those inorganic particles can improve the hardness. Among silica particles, reactive silica particles are preferred. The above-described reactive silica particle can form a cross-linked structure with the above-described polyfunctional (meth)acrylate and the presence of the reactive silica particles can sufficiently increase the hardness of the functional layer 31.

The above-described reactive silica particles preferably carry any reactive functional group on the surface, and polymerizable functional groups, such as those described above, are suitably used as the reactive functional group.

The above-described reactive silica particles are not limited to particular reactive silica particles, and conventionally known reactive silica particles can be used, examples of which include reactive silica particles described in JP2008-165040A. Additionally, examples of commercially available reactive silica particles as described above include MIBK-SD, MIBK-SD-MS, MIBK-SD-L, and MIBK-SD-ZL (all manufactured by Nissan Chemical Industries, Ltd.) and V8802 and V8803 (both manufactured by JGC C&C).

Additionally, the above-described silica particles may be spherical silica particles but are preferably deformed silica particles. Spherical silica particles may be combined with deformed silica particles. In this specification, the “spherical silica particle” refers to, for example, a spherical or ellipsoidal silica particle, while “deformed silica particle” refers to a silica particle with a randomly rough surface as observed on potato tubers (having an aspect ratio of 1.2 or more and 40 or less when a cross-section is observed). Because the above-described deformed silica particle has a larger surface area than that of a spherical silica particle, the presence of such deformed silica particles increases the contact area with, for example, the above-described polyfunctional (meth)acrylate and can thereby improve the hardness of the above-described hard coat layer. Observation of a cross-section of the functional layer under a transmission electron microscope (TEM) or a scanning transmission electron microscope (STEM) can determine whether or not the silica particles contained in the functional layer are deformed silica particles.

The average particle diameter of the above-described silica particles is preferably 5 nm or more and 200 nm or less. In cases where the average particle diameter of the silica particles is 5 nm or more, the production of the particles themselves is not difficult, the aggregation of the particles can be suppressed, and it is not difficult to make the silica particles deformed. On the other hand, in cases where the average particle diameter of the above deformed silica particles is 200 nm or less, it is possible to suppress the formation of large irregularities in the functional layer and also to suppress the increase in haze. In cases where the silica particles are spherical silica particles, the average particle diameter of the silica particles is defined as the arithmetic mean of the particle diameters of 20 particles, where the particle diameters of the 20 particles are measured from cross-sectional images of particles acquired using a transmission electron microscope (TEM) or scanning transmission electron microscope (STEM). Additionally, in cases where the silica particles are deformed silica particles, the average particle diameter of the silica particles is defined as the arithmetic mean of the particle diameters of 20 particles, where the maximum (major axis) and minimum (minor axis) values of the distance between two points on the circumference of each particle are measured from a cross-sectional image of the hard coat layer acquired using a transmission electron microscope (TEM) or a scanning transmission electron microscope (STEM), and these values are averaged to determine the particle diameter of the particle.

The hardness (Martens hardness) of the functional layer 31 can be controlled by adjusting the size and amount of the above-described inorganic particles. For example, in the formation of the functional layer 31, 25 to 60 parts by mass of the above silica particles with an average particle diameter of 5 nm or more and 200 nm or less are preferably contained with respect to 100 parts by mass of the above polymerizable compound.

The functional layer 31 may contain any materials other than the above-described materials as long as the above-described Martens hardness is achieved even if those additional materials are contained. For example, a polymerizable monomer, oligomer, or the like which forms a cured product upon exposure to ionizing radiation may be additionally contained as a resin component material. As the above-described polymerizable monomer or oligomer, (meth)acrylate monomers or oligomers each containing a radical polymerizable unsaturated group in the molecule are included. Examples of the above-described (meth)acrylate monomers or oligomers each containing a radical polymerizable unsaturated group in the molecule include monomers or oligomers of, for example, urethane (meth)acrylate, polyester (meth)acrylate, epoxy (meth)acrylate, melamine (meth)acrylate, polyfluoroalkyl (meth)acrylate, and silicone (meth)acrylate. These polymerizable monomers or oligomers may be used individually or in combination of two or more. Among those monomers or oligomers, a monomer or oligomer of polyfunctional (hexafunctional or higher) urethane (meth)acrylate with a weight average molecular weight of 1,000 to 10,000 is preferred.

The functional layer 31 may further contain an ultraviolet absorber, a spectral transmittance modifier, and/or an antifouling agent.

### <<<Additional Optical Film>>>

The optical film 30 shown in FIG. 3 does not contain a base material, but may contain a base material like the optical film 50 shown in FIG. 5. The optical film 50 comprises, as shown in FIG. 5, a resin layer 10, a resin base material 51, and a functional layer 52 in this order. The resin base material 51 is preferably provided on the first surface 10A of the resin layer 10. In the optical film 50, the resin layer 10 is directly provided on the resin base material 51, but may be attached to the resin base material through an adhesive layer.

The front surface 50A of the optical film 50 constitutes the surface 52A of the functional layer 52. In this specification, the front surface of the optical film is used to refer to one surface of the optical film. Thus, the surface opposite to the front surface of the optical film will be referred to as the back surface, distinguished from the front surface of the optical film. The back surface 50B of the optical film 50 corresponds to the second surface 10B of the resin layer 10.

The optical film 50 is also foldable like the optical film 30. The preferred number of folding events, the preferred gap distance φ between the opposing edges, and the conditions of the successive folding test are the same as those for the optical film 30, and the description thereof is thus omitted here.

The front surface 50A of the optical film 50 (the surface 52A of the functional layer 52) preferably has a hardness (pencil hardness) of 2B or more as measured by the pencil hardness test specified by JIS K5600-5-4: 1999. The pencil hardness of the optical film 50 is measured by the same method as for the pencil hardness of the optical film 30.

The optical film 50 preferably has a yellow index (YI) of 15 or less. The optical film 50 with a YI of 15 or less can be less yellow in color and be applied to uses that require transparency of optical films. The maximum yellow index (YI) of the optical film 50 is more preferably 10 or less, 5 or less, or 1.5 or less. The yellow index (YI) is a value determined by setting a cut piece of the optical film with a size of 50 mm×100 mm in a spectrophotometer (for example, product name: “UV-2450”; manufactured by Shimadzu Corporation; light source: tungsten lamp and deuterium lamp) in such a manner that the side of the resin layer faces the light source, measuring the transmittance in the wavelength range of 300 nm to 780 nm of the optical film in the environment with a temperature of 23±5° C. and a relative humidity of 30% or more and 70% or less, processing the obtained values according to the formula described in JIS Z8722: 2009 to calculate color tristimulus values X, Y, and Z, and processing the obtained tristimulus values X, Y, and Z according to a formula described in ASTM D1925: 1962. The maximum yellow index (YI) in the optical film 50 is more preferably 10 or less. The above-described yellow index (YI) is the arithmetic mean of three measurements obtained by measuring a cut piece of the optical film. In the UV-2450, a yellow index is calculated on the monitor connected to the UV-2450 by reading the measurement data of the above transmittance and selecting the item “YI” from calculation items. The measurement of transmittance in the wavelength range of 300 nm to 780 nm is performed under the following conditions, and the transmittance should be determined by measuring transmittance at least five points spaced 1 nm apart in the wavelength range of 300 nm to 780 nm and calculating the average of the transmittance values. Additionally, in cases where fluctuation is observed in spectral transmittance spectra, smoothing treatment may be performed with a delta of 5.0 nm.

### (Measurement Conditions)

Wavelength range: 300 to 780 nm

Scan speed: High

Slit width: 2.0

Sampling interval: Auto (0.5-nm intervals)

Illumination: C

Light source: D2 and WI

Field: 2°

Light source-switching wavelength: 360 nm

S/R switching: Standard

Detector: PM

Autozero: performed at 550 nm subsequent to the baseline scan

The optical film 50 preferably has a total light transmittance of 85% or more for the same reason as described for the resin layer 10, and preferably of 87% or more or of 90% or more. The total light transmittance of the optical film 50 is measured by the same method as for the total light transmittance of the resin layer 10.

The optical film 50 preferably has a haze value (total haze value) of 3.0% or less for the same reason as described for the resin layer 10, and more preferably 2.0% or less, 1.5% or less, 1.0% or less, or 0.5% or less. The haze value of the optical film 50 is measured by the same method as for the haze value of the resin layer 10.

### <<Resin Base Material>>

The resin base material 51 has a light-transmitting property. The resin base material 51 preferably contains, for example, one or more resins selected from the group consisting of a polyimide resin, a polyamideimide resin, a polyamide resin, a polyester resin (for example, polyethylene terephthalate resin and polyethylene naphthalate resin).

Among these resins, polyimide resins, polyamide resins, or mixtures thereof are preferred in terms of several aspects: the resulting optical film has excellent hardness and transparency as well as is less broken or fractured during the successive folding test, also has outstanding heat resistance, and can obtain further excellent hardness and transparency by film baking.

A polyimide resin can be obtained from the reaction between a tetracarboxylic component and a diamine component. The polyimide resin is not specifically limited, and preferably has, for example, at least one structure selected from the group consisting of the structures represented by the general formula (5) below and the general formula (7) below, to provide an excellent light-transmitting property and excellent rigidity.

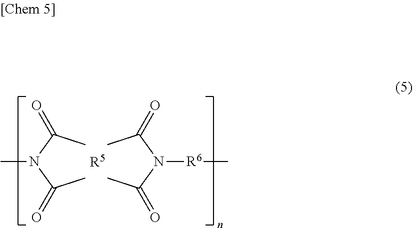

In the above-described general formula (5), R⁵ represents a tetracarboxylic acid residue as a tetravalent group; R⁶ represents at least one divalent group selected from the group consisting of trans-cyclohexanediamine residue, trans-1,4-bismethylene cyclohexanediamine residue, 4,4′-diaminodiphenyl sulfone residue, 3,4′-diaminodiphenyl sulfone residue, and divalent groups represented by the general formula (6) below; and n represents the number of repeating units, which is 1 or more. In this specification, the “tetracarboxylic acid residue” refers to a residue remaining after subtracting four carboxylic groups from a tetracarboxylic acid, and represents the same structure as a residue remaining after subtracting the acid dianhydride structure from a tetracarboxylic dianhydride. Additionally, the “diamine residue” refers to a residue remaining after subtracting two amino groups from a diamine.

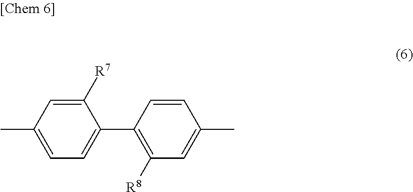

In the above-described general formula (6), R⁷ and R⁸ each independently represent a hydrogen atom, alkyl group, or perfluoroalkyl group.

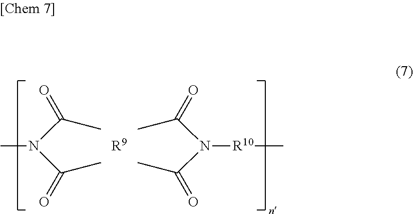

In the above-described general formula (7), R⁹ represents at least one tetravalent group selected from the group consisting of cyclohexane tetracarboxylic acid residue, cyclopentane tetracarboxylic acid residue, dicyclohexane-3,4,3′,4′-tetracarboxylic acid residue, and 4,4′-(hexafluoroisopropylidene)diphthalic acid residue; R¹⁰ represents a diamine residue as a divalent group; and n′ represents the number of repeating units, which is 1 or more.

In the above-described general formula (5), R⁵ refers to a tetracarboxylic acid residue and can represent, as indicated above, a residue remaining after subtracting the acid dianhydride structure from a tetracarboxylic dianhydride. As R⁵ in the above-described general formula (5), preferably at least one selected from the group consisting of 4,4′-(hexafluoroisopropylidene)diphthalic acid residue, 3,3′,4,4′-biphenyl tetracarboxylic acid residue, pyromellitic residue, 2,3′,3,4′-biphenyl tetracarboxylic acid residue, 3,3′,4,4′-benzophenone tetracarboxylic acid residue, 3,3′,4,4′-diphenylsulfone tetracarboxylic acid residue, 4,4′-oxydiphthalic acid residue, cyclohexane tetracarboxylic acid residue, and cyclopentane tetracarboxylic acid residue, more preferably at least one selected from the group consisting of 4,4′-(hexafluoroisopropylidene)diphthalic acid residue, 4,4′-oxydiphthalic acid residue, and 3,3′,4,4′-diphenylsulfone tetracarboxylic acid residue, is contained, among others, in view of improving the light-transmitting property and the rigidity.

As R⁵, those suitable residues are contained preferably at a total concentration of 50% by mole or more, further preferably 70% by mole or more, and still further preferably 90% by mole or more.

Additionally, a combination of at least one selected from a group of tetracarboxylic acid residues suitable for improving the rigidity (group A), such as the group consisting of 3,3′,4,4′-biphenyl tetracarboxylic acid residue, 3,3′,4,4′-benzophenone tetracarboxylic acid residue, and pyromellitic residue, and at least one selected from a group of tetracarboxylic acid residues suitable for improving the transparency (group B), such as the group consisting of 4,4′-(hexafluoroisopropylidene)diphthalic acid residue, 2,3′,3,4′-biphenyl tetracarboxylic acid residue, 3,3′,4,4′-diphenylsulfone tetracarboxylic acid residue, 4,4′-oxydiphthalic acid residue, cyclohexane tetracarboxylic acid residue, and cyclopentane tetracarboxylic acid residue, is preferably used as R⁵.

For the content ratio of the group of tetracarboxylic acid residues suitable for improving the rigidity (group A) to the group of tetracarboxylic acid residues suitable for improving the transparency (group B) in that case, preferably 0.05 moles or more and 9 moles or less, further preferably 0.1 moles or more and 5 moles or less, still further preferably 0.3 moles or more and 4 moles or less, of the group of tetracarboxylic acid residues suitable for improving the rigidity (group A) are combined with 1 mole of the group of tetracarboxylic acid residues suitable for improving the transparency (group B).

In the above-described general formula (5), R⁶ preferably represents at least one divalent group selected from the group consisting of 4,4′-diaminodiphenyl sulfone residue, 3,4′-diaminodiphenyl sulfone residue, and divalent groups represented by the above-described general formula (6), further preferably at least one divalent group selected from the group consisting of 4,4′-diaminodiphenyl sulfone residue, 3,4′-diaminodiphenyl sulfone residue, and divalent groups represented by the above-described general formula (6) where R⁷ and R⁸ each represent a perfluoroalkyl group, among others, in terms of improving the light-transmitting property and the rigidity.

As R⁹ in the above the general formula (7), 4,4′-(hexafluoroisopropylidene)diphthalic acid residue, 3,3′,4,4′-diphenylsulfone tetracarboxylic acid residue, and oxydiphthalic acid residue are preferably contained, among others, in view of improving the light-transmitting property and the rigidity.

As R⁹, those suitable residues are contained preferably at a concentration of 50% by mole or more, further preferably 70% by mole or more, and still further preferably 90% by mole or more.

In the above-described general formula (7), R¹⁰ refers to a diamine residue and can represent, as indicated above, a residue remaining after subtracting two amino groups from a diamine. As R¹⁰ in the above-described general formula (7), preferably at least one divalent group selected from the group consisting of 2,2′-bis(trifluoromethyl)benzidine residue, bis[4-(4-aminophenoxy)phenyl]sulfone residue, 4,4′-diaminodiphenyl sulfone residue, 2,2-bis[4-(4-aminophenoxy)phenyl]hexafluoropropane residue, bis[4-(3-aminophenoxy)phenyl]sulfone residue, 4,4′-diamino-2,2′-bis(trifluoromethyl)diphenyl ether residue, 1,4-bis[4-amino-2-(trifluoromethyl) phenoxy]benzene residue, 2,2-bis[4-(4-amino-2-trifluoromethylphenoxy)phenyl]hexafluoropropane residue, 4,4′-diamino-2-(trifluoromethyl)diphenyl ether residue, 4,4′-diaminobenzanilide residue, N,N′-bis(4-aminophenyl)terephthalamide residue, and 9,9-bis(4-aminophenyl)fluorene residue, further preferably at least one divalent group selected from the group consisting of 2,2′-bis(trifluoromethyl)benzidine residue, bis[4-(4-aminophenoxy)phenyl]sulfone residue, and 4,4′-diaminodiphenyl sulfone residue, is contained, among others, in view of improving the light-transmitting property and the rigidity.

As R¹⁰, those suitable residues are contained preferably at a total concentration of 50% by mole or more, further preferably 70% by mole or more, and still further preferably 90% by mole or more.

Additionally, a combination of at least one selected from a group of diamine residues suitable for improving the rigidity (group C), such as the group consisting of bis[4-(4-aminophenoxy)phenyl]sulfone residue, 4,4′-diaminobenzanilide residue, N,N′-bis(4-aminophenyl)terephthalamide residue, paraphenylenediamine residue, methaphenylenediamine residue, and 4,4′-diaminodiphenylmethane residue, and at least one selected from a group of diamine residues suitable for improving the transparency (group D), such as the group consisting of 2,2′-bis(trifluoromethyl)benzidine residue, 4,4′-diaminodiphenyl sulfone residue, 2,2-bis[4-(4-aminophenoxy)phenyl]hexafluoropropane residue, bis[4-(3-aminophenoxy)phenyl]sulfone residue, 4,4′-diamino-2,2′-bis(trifluoromethyl)diphenyl ether residue, 1,4-bis[4-amino-2-(trifluoromethyl)phenoxy]benzene residue, 2,2-bis[4-(4-amino-2-trifluoromethylphenoxy)phenyl]hexafluoropropane residue, 4,4′-diamino-2-(trifluoromethyl)diphenyl ether residue, and 9,9-bis(4-aminophenyl)fluorene residue, is preferably used as R¹⁰.

For the content ratio of the group of diamine residues suitable for improving the rigidity (group C) to the group of diamine residues suitable for improving the transparency (group D) in that case, preferably 0.05 moles or more and 9 moles or less, further preferably 0.1 moles or more and 5 moles or less, more preferably 0.3 moles or more and 4 moles or less, of the group of diamine residues suitable for improving the rigidity (group C) are combined with 1 mole of the group of diamine residues suitable for improving the transparency (group D).

For the structures represented by the above-described general formulae (5) and (7), n and n′ each independently represent the number of repeating units, which is 1 or more. The number of repeating units, n, in the polyimide may be appropriately selected depending on the structure to allow the polyimide to have a preferred glass transition temperature as described below, and is not limited to a particular number. The average number of repeating units is typically 10 to 2,000, further preferably 15 to 1,000.

Additionally, the polyimide resin may partially contain a polyamide structure. Examples of the polyamide structure that may be contained include a polyamide-imide structure containing a tricarboxylic acid residue such as trimellitic anhydride, and a polyamide structure containing a dicarboxylic acid residue such as terephthalic acid.

The polyimide resin preferably has a glass transition temperature of 250° C. or higher, further preferably 270° C. or higher, in terms of heat resistance, while the polyimide resin preferably has a glass transition temperature of 400° C. or lower, further preferably 380° C. or lower, in terms of ease of stretching and of reducing the baking temperature.

Examples of the polyimide resin include compounds having the structure represented by the chemical formulae below. In the chemical formulae below, n represents the number of repeating units, which is an integer of 2 or more.

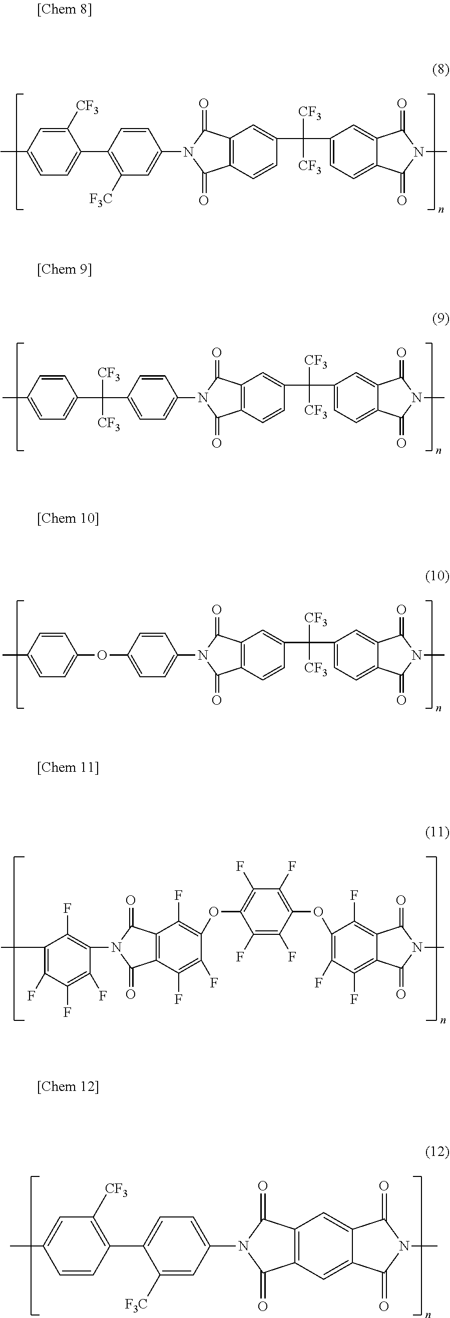

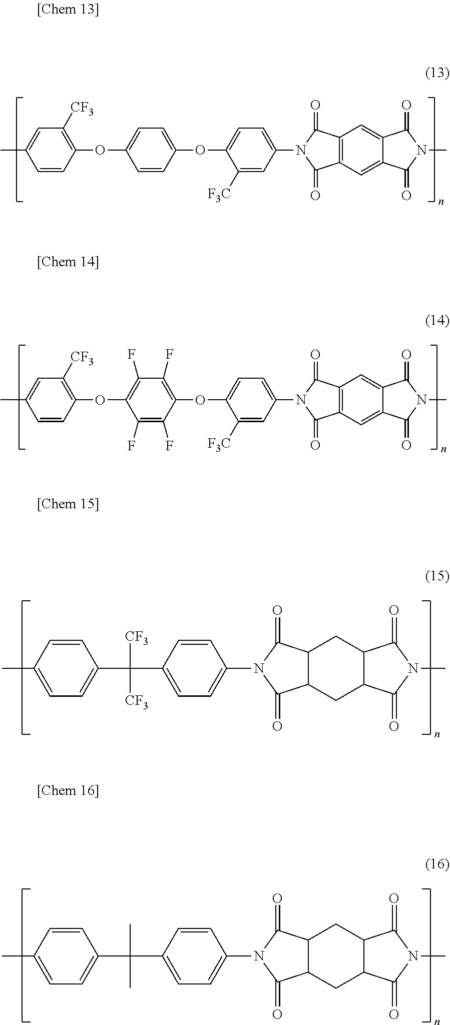

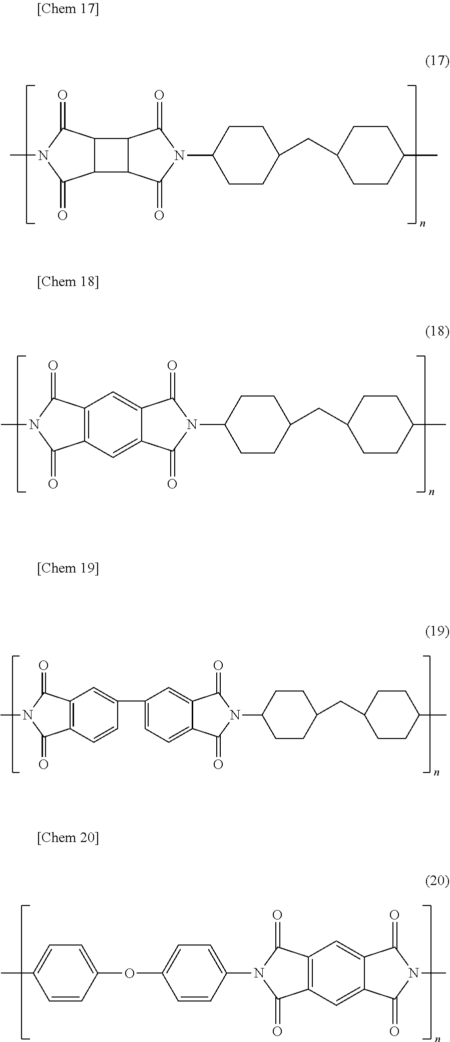

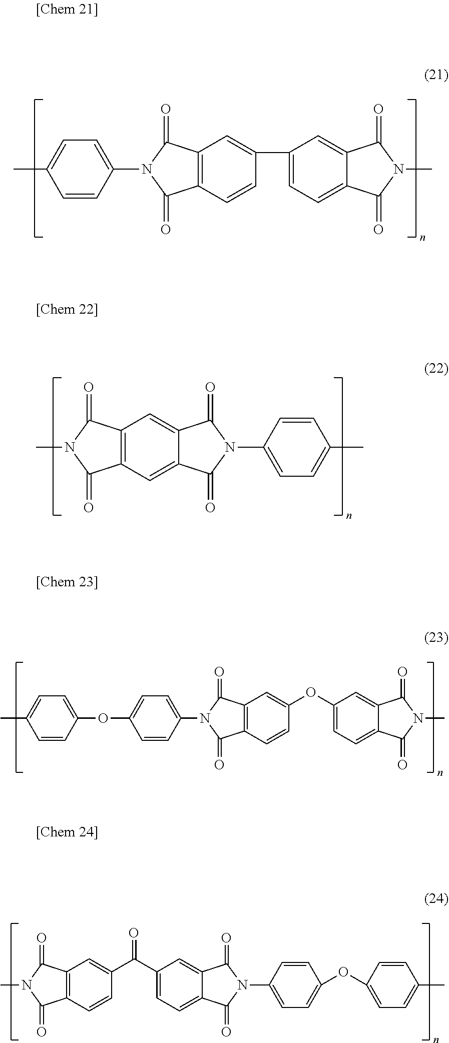

Among the above-described polyimide resins, the polyimide or polyamide resins having structures that inhibit intramolecular or intermolecular charge transfer are preferred because of the excellent transparency, specifically including the fluorinated polyimide resins represented by, for example, the above-described chemical formulae (8) to (15) and the polyimide resins containing alicyclic structures represented by, for example, the above-described formulae (15) to (19).

Additionally, the fluorinated polyimide resins represented by, for example, the above-described chemical formulae (8) to (15) contain a fluorinated structure and thus have high heat resistance, and are not colored by the heat generated during polyimide film production, which causes the resulting film to have excellent transparency.

The concept of polyamide resin includes aromatic polyamides (aramids) as well as aliphatic polyamides. Examples of the polyamide resin include compounds having any of the structures represented by the chemical formulae (25) to (27) below. In the formulae below, n represents the number of repeating units, which is an integer of 2 or more.

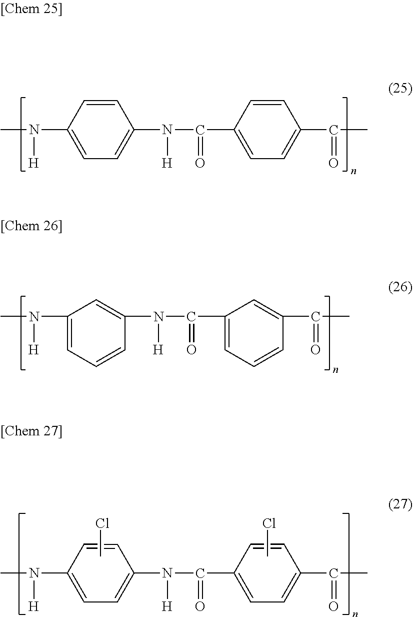

A commercially available base material may be used as a base material composed of the polyimide or polyamide resin represented by any of the above-described chemical formulae (8) to (24) and (27). Examples of a commercially available base material containing the above-described polyimide resin include Neopulim® manufactured by Mitsubishi Gas Chemical Company, Inc., and the like, while examples of a commercially available base material containing the above-described polyamide resin include Mictron® manufactured by Toray Industries, Inc., and the like.

Additionally, polyimide or polyamide resins synthesized by any known methods may be used as the polyimide or polyamide resins represented by the above-described chemical formulae (8) to (24) and (27). For example, the polyimide resin represented by the above-described chemical formula (8) is synthesized by a method described Japanese Patent Application Publication No. 2009-132091 and can be obtained, specifically, by a reaction of 4,4′-hexafluoropropylidenebisphthalic dianhydride (FPA) and 2,2′-bis(trifluoromethyl)-4,4′-diaminobiphenyl (TFDB), as represented by the chemical formula (28) below.

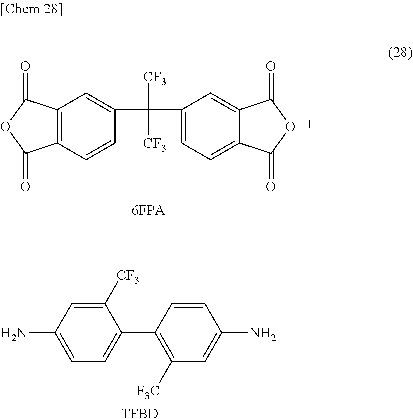

The weight average molecular weight of the above-described polyimide or polyamide resin preferably ranges from 3,000 to 500,000, more preferably from 5,000 to 300,000, further preferably from 10,000 to 200,000, inclusive. The resin with a weight average molecular weight of less than 3,000 may not have enough strength, while the resin with a weight average molecular weight of more than 500,000 has an increased viscosity and a reduced solubility, which in turn may result in failure to provide a base material with smooth surface and homogeneous film thickness. In this specification, the “weight average molecular weight” is measured by gel permeation chromatography (GPC) as a value in terms of polystyrene.

As the resin base material 51, a base material composed of any of the fluorinated polyimide resins represented by, for example, the above-described chemical formulae (8) to (15) or composed of the halogenated polyamide resin represented by, for example, the above-described chemical formula (27) is preferably used in terms of the ability to improve the hardness. Among those, a base material containing the polyimide resin represented by the above-described chemical formula (8) is more preferably used in view of the ability to further improve the hardness.

Examples of the polyester resin include resins containing at least one component selected from the group consisting of polyethylene terephthalate, polypropylene terephthalate, polybutylene terephthalate, and polyethylene naphthalate.

The thickness of the resin base material 51 is preferably 10 μm or more and 100 μm or less. In cases where the resin base material 51 has a thickness of 10 μm or more, the resulting optical film can be prevented from curling and also have sufficient hardness. Furthermore, with such a resin base material, even an optical film produced by roll-to-roll process is less prone to wrinkling and less likely to deteriorate in appearance. In contrast, in cases where the resin base material 51 has a thickness of 100 μm or less, the resulting optical film 50 has excellent foldability, is able to satisfy the requirements of the successive folding test, and is also desirable in view of reducing the weight of the optical film 50. The thickness of the resin base material 51 can be measured in the same manner as the film thickness of the resin layer 10. The minimum value for the resin base material 51 is more preferably 20 μm or more, 30 μm or more, or 40 μm or more, while the maximum value for the resin base material 51 is more preferably 80 μm or less or 50 μm or less.

### <Functional Layer>

The functional layer 52 is the same as the functional layer 31, and the description is thus omitted here.

### <<<Resin Layer and Optical Film Production Method>>>

The resin layer 10 and the optical films 30 and 50 can be produced as follows. For the production of the resin layer 10 and the optical film 30, a resin layer composition is applied on one surface of the mold release film by a coating apparatus such as bar coater to prepare a coating film.

### <<Resin Layer Composition>>

The resin layer composition contains at least a radiation-curable compound. In addition to the radiation-curable compound, the resin layer composition may contain a solvent and a polymerization initiator. Since the radiation-curable compound has been described in the section of the resin layer 10, the description will be omitted here.

### <Solvent>

Examples of the above-described solvent include alcohols (for example, methanol, ethanol, propanol, isopropanol, n-butanol, s-butanol, t-butanol, benzyl alcohol, PGME, ethylene glycol, diacetone alcohol), ketones (for example, acetone, methyl ethyl ketone, methyl isobutyl ketone, cyclopentanone, cyclohexanone, heptanone, diisobutyl ketone, diethyl ketone, diacetone alcohol), esters (methyl acetate, ethyl acetate, butyl acetate, n-propyl acetate, isopropyl acetate, methyl formate, PGMEA), aliphatic hydrocarbons (for example, hexane, cyclohexane), halogenated hydrocarbons (for example, methylene chloride, chloroform, carbon tetrachloride), aromatic hydrocarbons (for example, benzene, toluene, xylene), amides (for example, dimethylformamide, dimethylacetamide, n-methylpyrrolidone), ethers (for example, diethyl ether, dioxane, tetrahydrofurane), ether alcohols (for example, 1-methoxy-2-propanol), and carbonates (dimethyl carbonate, diethyl carbonate, ethylmethyl carbonate). These solvents may be used individually or in combination of two or more. Among those solvents, methyl isobutyl ketone and methyl ethyl ketone are preferred as the above-described solvent in terms of the ability to dissolve or disperse components such as urethane (meth)acrylate and other additives and thereby to apply the resin layer composition in a suitable manner.

### <Polymerization Initiator>

The polymerization initiator is a component which degrades, when exposed to ionizing radiation, and generates radicals to initiate or promote polymerization (cross-linking) of a polymerizable compound.

The polymerization initiator is not specifically limited, provided that the polymerization initiator can generate a substance that initiates a radical polymerization by exposure to ionizing radiation. Any known polymerization initiator can be used without any particular limitation, and specific examples of the polymerization initiator include acetophenones, benzophenones, Michler's benzoyl benzoate, α-amyloxime esters, thioxantones, propyophenones, benzyls, benzoins, and acylphosphine oxides. Additionally, a photosensitizer is preferably mixed for use, and specific examples of the photosensitizer include n-butylamine, triethylamine, and poly-n-butylphosphine.

In cases where the resin layer composition contains a solvent, after the coating film of the resin layer composition is prepared, the coating film is heated and dried at a temperature of, for example, 30° C. or higher and 120° C. or lower for a period of 10 to 120 seconds by various known techniques to evaporate the solvent.

After drying the coating film, the coating film is exposed to ionizing radiation such as ultraviolet light to cure the coating film. The mold release film is then peeled off to obtain a resin layer 10. The resin layer 10 satisfies the above relationship (1). Such a resin layer 10 can be obtained not only by adjusting the composition of the resin layer composition, but also, for example, by appropriately adjusting the irradiation conditions of the ionizing radiation and/or the type and amount of the polymerization initiator while irradiating the coating film with ionizing radiation from one surface.

In cases where the optical film 30 is formed, after drying the coating film of the resin layer composition, the coating film is exposed to ionizing radiation such as ultraviolet light to semi-cure (half cure) the coating film. The term “semi-cure” as used herein means that curing substantially proceeds upon further exposure to ionizing radiation.

After the coating film is semi-cured, a functional layer composition for forming a functional layer 31 is applied on the coating film by a coating apparatus such as bar coater to form a coating film of the functional layer composition.

### <<Functional Layer Composition>>

The functional layer composition contains a polymerizable compound. The functional layer composition may additionally contain an ultraviolet absorber, a spectral transmittance modifier, an antifouling agent, inorganic particles, a leveling agent, a solvent, and a polymerization initiator, as necessary. The solvent and the polymerization initiator are the same as those described for the resin layer composition, and will not be described here.

After the coating film of the functional layer composition is formed, the coating film is heated and dried, for example, at a temperature of 30° C. or higher and 120° C. or lower for 10 to 120 seconds by various known techniques to evaporate the solvent.

After drying the coating film of the functional layer composition, the coating film is exposed to ionizing radiation such as ultraviolet light to completely cure (full-cure) the coating film to form the functional layer 31. The phrase “completely cure” as used herein means that curing substantially no more proceeds in spite of further exposure to ionizing radiation. Then, the mold release film is peeled off to obtain an optical film 30.

When the optical film 50 is formed, for example, a functional layer 52 is first formed on one surface of the resin base material 51. The functional layer 52 can be formed by the same method as the functional layer 31. Then, the resin layer 10 is formed in the same manner as described above on the surface of the resin base material 51 opposite to the surface on which the functional layer 52 is formed. The optical film 50 can be thus obtained.

In cases where the resin layer has a monolayer structure composed of a soft resin layer having a uniform hardness, good foldability can be obtained, but the impact resistance is inferior because the resin layer is soft. In cases where the resin layer has a monolayer structure composed of a hard resin layer having a uniform hardness, good impact resistance can be obtained, but the foldability is inferior because the resin layer is hard. Further, in cases where the resin layer has a multilayer structure of a soft layer and a hard layer, peeling or cracking may occur at the interface between the soft layer and the hard layer when the resin layer is folded. In addition, the deformation of the soft layer may differ from the deformation of the hard layer when the resin layer is folded, resulting in wrinkles. Based on these observations, the present inventors have discovered that, in order to obtain a resin layer with good foldability and good impact resistance which prevents the depression on the front surface of an optical film and prevents damages on components located interior to the optical film in an image display device (for example, a polarizing plate) when an impact force is applied on the front surface of the optical film, it is necessary to gradually change the hardness of the resin layer having a monolayer structure from one surface to the other surface. According to the present embodiment, since the displacement amounts d1 to d3 in the first region 10C to the third region 10E of the resin layer 10 having a monolayer structure satisfy the relationship of d1<d2<d3, good foldability and good impact resistance can be obtained.

### <<<Image Display Device>>>

The optical film 30 may be incorporated into a foldable image display device and then used. FIG. 6 depicts the schematic diagram of the image display device according to the present embodiment. As shown in FIG. 6, the image display device 60 mainly comprises a housing 61 for accommodating, for example, a battery, a display device 62, a circularly polarizing plate 63, a touch sensor 64, and an optical film 30 laminated in this order toward the observer's side. Light-transmitting adhesive layers 65 or adhesion layers are placed along the interfaces between the housing 61 and the display device 62, between the display device 62 and the circularly polarizing plate 63, between the circularly polarizing plate 63 and the touch sensor 64, and between the touch sensor 64 and the optical film 30, and these components are anchored to each other with the adhesive layers 65 or adhesion layers. Here, the adhesive layers 65 are placed along the interfaces between the housing 61 and the display device 62, between the display device 62 and the circularly polarizing plate 63, between the circularly polarizing plate 63 and the touch sensor 64, and between the touch sensor 64 and the optical film 50. However, the position at which the adhesive layer is disposed is not particularly limited as long as the position is between the optical film and the display device.

In the optical film 30, the functional layer 31 is located on the observer's side of the resin layer 10. For the image display device 60, the front surface 30A of the optical film 30 constitutes the surface 60A of the image display device 60.

In the image display device 60, the display device 62 is an organic light-emitting diode device containing an organic light-emitting diode device and the like. The touch sensor 64 is located closer to the observer's side than the circularly polarizing plate 63, but may be located between the display device 62 and the circularly polarizing plate 63. Additionally, the touch sensor 64 may be an on-cell type or an in-cell type. As the adhesive layer 65, for example, an OCA (optical clear adhesive) can be used.

### Second Embodiment

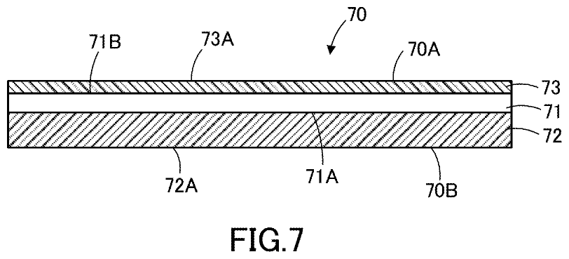

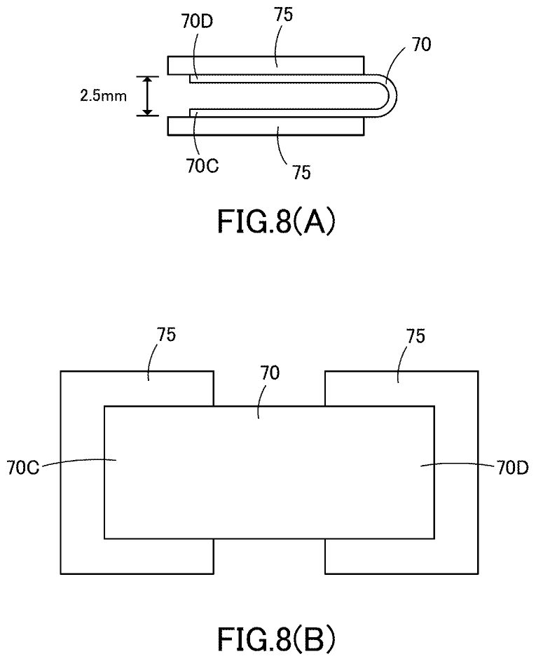

An optical film and an image display device according to the second embodiment of the present invention will be described below with reference to the drawings. FIG. 7 depicts a schematic diagram of the optical film according to the present embodiment, and FIG. 8(A) and FIG. 8(B) schematically show steps of the static folding test.

### <<<Optical Film>>>

An optical film 70 shown in FIG. 7 is foldable and light-transmitting. The optical film 70 has a front surface 70A and a back surface 70B opposite to the front surface 70A. Additionally, the optical film 70 comprises a resin base material 71, a resin layer 72, and a hard coat layer 73. In the optical film 70, the resin layer 72 is provided closer to the back surface 70B of the optical film 70 than the resin base material 71, and the hard coat layer 73 is provided closer to the front surface 70A of the optical film 70 than the resin base material 71. Specifically, the optical film 70 comprises the hard coat layer 73, the resin base material 71, and the resin layer 72 arranged in this order from the front surface 70A to the back surface 70B.

The optical film 70 does not easily crease even when the static folding test is performed. The static folding test and the observation of creases are carried out as follows. First, a piece having a size of 30 mm×100 mm is cut out from the optical film 70. Then, in order to reproduce the state in the image display device, as shown in FIG. 8(A), the regions of 30 mm×48 mm containing the edges 70C and 70D on the two opposing short sides (30 mm) of the cut optical film 70 are each fixed to glass plates 75 having a size of 50 mm×100 mm. The glass plate 75 is fixed to the side of the back surface 70B (side of the resin layer 72) of the optical film 70. Then, the glass plates 20 are arranged in parallel so that the distance between the opposing edges 70C and 70D of the optical film 70 is 2.5 mm. Thus, the optical film 70 is folded with the front surface 70A facing inward. In this state, the optical film is left at 25° C. for 100 hours. After that, the optical film 70 is opened with the glass plates 75 attached, and the front surface of the optical film 70 is flattened as shown in FIG. 8(B). In this state, the presence of a crease on the optical film 70 is visually confirmed.

The optical film 70 is foldable like the optical film 30. In the optical film 70, for example, no crack or break is formed in the optical film 70 even in cases where the folding test (successive folding test) is repeated on the optical film 70 preferably 100,000 times, more preferably 200,000 times, more preferably 300,000 times, and further preferably 1,000,000 times. The successive folding test is carried out in the same manner as the successive folding test described in the first embodiment. More preferably, in the optical film 70, no crack or break is formed even when the successive folding test is repeated 100,000 times on the optical film 70 in a manner that leaves a gap distance φ of 20 mm, 10 mm, 6 mm, or 3 mm between the two opposing edges. A smaller distance between the two opposing edges is more preferred.

In cases where an additional film, such as a polarizing plate, is provided on one surface of the optical film 70 through an adhesive or adhesion layer, the static folding test and the folding test should be carried out after removing the additional film and the adhesive or adhesion layer.

The front surface 70A of the optical film 70 (the surface 73A of the hard coat layer 73) preferably has a hardness (pencil hardness) of B or harder, more preferably H or harder, when measured by the pencil hardness test specified by JIS K5600-5-4: 1999. The pencil hardness test is carried out in the same manner as the pencil hardness test described in the first embodiment.

The yellow index of the optical film 70 and its measurement method are the same as the yellow index of the optical film 50 and its measurement method. The haze value (total haze value) and total light transmittance of the optical film 70, and their measurement methods are the same as the haze value and total light transmittance of the resin layer 10, and their measurement methods. The use, size, and position of the optical film 70 are the same as the use, size, and position of the optical film 30.

### <<Resin Base Material>>

The resin base material 71 is a base material containing a light-transmitting resin. Examples of the constituent materials of the resin base material 71 include the same materials as those of the resin base material 51. The thickness of the resin base material 71 is 20 μm or less. Since the resin base material 71 having a thickness of 20 μm or less is a thin resin base material, the elongation of the resin base material 71 is small when the optical film 70 is folded. The thickness of the resin base material 71 can be measured in the same manner as the film thickness of the resin layer 72. More preferably, the maximum value for the resin base material 71 is 18 μm or less, 16 μm or less, or 14 μm or less in order to reduce the elongation. The minimum value for the resin base material 71 is preferably 2 μm or more, 4 μm or more, or 6 μm or more in order to ensure the desired pencil hardness.

A cross-section of the resin base material 71 is photographed in the same manner as the cross-section of the functional layer 31 using a scanning transmission electron microscope (STEM), and the film thickness of the resin base material 71 is measured at 10 different locations within the image of the cross-section. The arithmetic mean of the 10 film thickness values is determined as the film thickness of the resin base material 71.

When the indentation test is carried out and the Berkovich indenter is pressed at a maximum load of 200 μN into the cross-section of the resin base material 71 in the thickness direction, the displacement amount d4 of the resin base material 71 is 50 nm or more and 250 nm or less. In cases where the resin base material 71 has a displacement amount d4 of 50 nm or more, good flexibility can be obtained. In cases where the resin base material 71 has a displacement amount d4 of 250 nm or less, desired pencil hardness can be maintained. The minimum displacement amount d4 of the resin base material 71 is preferably 80 nm or more, 100 nm or more, or 110 nm or more in order to obtain excellent flexibility. The maximum displacement amount d4 of the resin base material 71 is preferably 220 nm or less, 200 nm or less, or 180 nm or less in order to ensure the desired pencil hardness. The displacement amount d4 of the resin base material 71 can be measured in the same manner as the displacement amounts d1 to d3 of the resin layer 10. In order to avoid the influence of the side edges of the resin base material, the Berkovich indenter should be pressed into a part of the cross-section of the resin base material 71 in the thickness direction, which is 500 nm or more away from both edges of the resin base material toward the center of the resin base material.

### <<Resin Layer>>

The resin layer 72 is a layer containing a light-transmitting resin and having impact absorption. The resin layer 72 is provided on the first surface 71A of the resin base material 71. In the optical film 70 of FIG. 7, the resin layer 72 is adjacent to the first surface 71A of the resin base material 71.

The resin layer 72 has a film thickness of 50 μm or more. The resin layer 72 having a film thickness of 50 μm or more can provide good impact resistance. The minimum film thickness of the resin layer 72 is preferably 60 μm or more, 65 μm or more, or 70 μm or more. The maximum film thickness of the resin layer 72 is more preferably 120 μm or less, 110 μm or less, or 100 μm or less in view of thickness reduction and good workability. The film thickness of the resin layer 72 should be measured in the same manner as the thickness of the resin base material 71.

The ratio of the film thickness of the resin layer 72 to the thickness of the resin base material 71 (the film thickness of the resin layer 72/the thickness of the resin base material 71) is 4.0 or more and 12.0 or less. In cases where this ratio is 4.0 or more, both crease suppression and impact resistance can be achieved. Further, in cases where this ratio is 12.0 or less, desired pencil hardness can be ensured. The minimum value of this ratio is more preferably 4.5 or more, 5.0 or more, or 6.0 or more in order to obtain excellent crease suppression and excellent impact resistance, while the maximum value of this ratio is preferably 11.0 or less, 10.0 or less, or 8.0 or less in order to obtain excellent flexibility.

When the indentation test is carried out and the Berkovich indenter is pressed at a maximum load of 200 μN into the cross-section of the resin layer 72 in the film thickness direction, the displacement amount d5 of the resin layer 72 is 200 nm or more and 1500 nm or less. In cases where the resin layer 72 has a displacement amount d5 of 200 nm or more, desired flexibility can be ensured. In cases where the resin layer 72 has a displacement amount d5 of 1500 nm or less, impact resistance necessary for the impact resistance test, which will be described later, can be guaranteed. The minimum displacement amount d5 of the resin layer 72 is preferably 300 nm or more, 400 nm or more, or 500 nm or more in order to suppress further the protrusion of the resin layer 72 when the resin layer is folded. The maximum displacement amount d5 of the resin layer 72 is more preferably 1400 nm or less, 1200 nm or less, or 1100 nm or less in order to obtain excellent impact resistance. Since the resin layer of the present embodiment is softer than the resin base material and the hard coat layer and is more affected by viscosity, the method of measuring the indentation hardness by the nanoindentation method was not suitable. Therefore, the amount of displacement is used as an index of hardness. The above displacement amount d5 of the resin layer 72 should be measured in the same manner as the displacement amount d4 of the resin base material 71.

The ratio of the displacement amount d5 to the displacement amount d4 (d5/d4) is preferably 1.5 or more. In cases where d5/d4 is 1.5 or more, both crease suppression and impact resistance can be achieved. The minimum value of d5/d4 is more preferably 2.0 or more, 2.5 or more, or 3.0 or more in order to obtain excellent crease suppression and excellent impact resistance, while the maximum value of d5/d4 is preferably 10.0 or less, 7.0 or less, or 5.0 or less in order to ensure desired flexibility.

The resin as a component of the resin layer 72 is not limited to a particular resin as long as the resin allows the displacement amount d5 to be within 200 nm or more and 1500 nm or less. Examples of such a resin include a cured product (polymerized product) of a radiation-curable compound (radiation-polymerizable compound). Examples of the cured product of the radiation-curable compound include urethane resins and acrylic gels. The “gel” generally refers to a disperse system with high viscosity and no fluidity.

### (Urethane Resin)

The urethane resin is the same as the urethane resin described in the section of the resin layer 10.

### (Acrylic Gel)

Various acrylic gels can be used as long as those acrylic gels are polymers produced by polymerization of monomers containing acrylic esters used in, for example, adhesives. Specifically, an acrylic gel obtained by polymerization or copolymerization of an acrylic monomer, such as ethyl (meth)acrylate, n-propyl (meth)acrylate, i-propyl (meth)acrylate, n-butyl (meth)acrylate, i-butyl (meth)acrylate, 2-ethylhexyl (meth)acrylate, n-hexyl (meth)acrylate, n-amyl (meth)acrylate, i-amyl (meth)acrylate, octyl (meth)acrylate, i-octyl (meth)acrylate, i-myristyl (meth)acrylate, lauryl (meth)acrylate, nonyl (meth)acrylate, i-nonyl (meth)acrylate, i-decyl (meth)acrylate, tridecyl (meth)acrylate, stearyl (meth)acrylate, or i-stearyl (meth)acrylate, can be used as the acrylic gel. In this specification, both “acrylate” and “methacrylate” are meant by the word “(meth)acrylate.” The above-described acrylic esters used for the (co)polymerization may be used individually or in combination of two or more.

### <<Hard Coat Layer>>

The hard coat layer 73 is provided on the second surface 71B of the resin base material 71. In the optical film 70 of FIG. 7, the hard coat layer 73 is adjacent to the second surface 11B of the resin base material 11. The “hard coat layer” in the present embodiment means a layer having a pencil hardness of “H” or higher in the above-mentioned pencil hardness test.

When the indentation test is carried out and the Berkovich indenter is pressed at a maximum load of 500 μN into the cross-section of the hard coat layer 73 in the film thickness direction, the displacement amount d6 of the hard coat layer 73 is preferably 500 nm or less. In cases where the displacement amount d6 of the hard coat layer 73 is 500 nm or less, desired pencil hardness can be ensured. The minimum displacement amount d6 of the hard coat layer 73 is preferably 50 nm or more, 60 nm or more, or 70 nm or more in order to ensure the flexibility. More preferably, the maximum displacement amount d6 of the hard coat layer 73 is 500 nm or less, 490 nm or less, or 480 nm or less. The above displacement amount d6 of the hard coat layer 73 should be measured in the same manner as the displacement amount d4 of the resin base material 71. The conditions of the measurement are as follows.

### (Measurement Conditions)

Control method: Load control (maximum load of 500 μN)

Lift amount: 0 nm

Preload: 0.5 μN

Loading speed: 20 μN/sec

Dwell time: 5 seconds

Unloading speed: 20 μN/sec

Measurement temperature: 23±5° C.

Relative humidity: 30 to 70%

The hard coat layer 73 preferably has a film thickness of 3 μm or more and 10 μm or less. The hard coat layer 73 with a film thickness of 3 μm or more can have good hardness, while the hard coat layer 73 with a film thickness of 10 μm or less can prevent reduction in workability. The “film thickness of the hard coat layer” as used herein refers to the sum of the film thickness (total thickness) of hard coat layers in cases where the hard coat layer has a multilayer structure. More preferably, the hard coat layer 73 has a minimum film thickness of 5 μm or more and a maximum film thickness of 8 μm or less. The film thickness of the hard coat layer 73 should be measured in the same manner as the thickness of the resin base material 71.

Preferably, the hard coat layer 73 further contains a resin and inorganic particles dispersed in the resin. The resin and inorganic particles of the hard coat layer 73 are the same as the resin and inorganic particles described in the section of the functional layer 31.

The hard coat layer 73 may contain any materials other than the above-described materials as long as the above-described displacement amount is achieved even if those additional materials are contained. For example, a polymerizable monomer, oligomer, or the like which forms a cured product upon exposure to ionizing radiation may be additionally contained as a resin component material. The polymerizable monomers and the polymerizable oligomers are the same as those described in the section of the functional layer 31.

### <<<Production Method for Optical Film>>>

The optical film 70 can be produced as follows. First, a hard coat layer composition is applied on the second surface 71B of the resin base material 71 by a coating apparatus such as bar coater to form a coating film of the hard coat layer composition.

### <Hard Coat Layer Composition>

The hard coat layer composition contains a polymerizable compound. The hard coat layer composition may additionally contain an ultraviolet absorber, a spectral transmittance modifier, an antifouling agent, inorganic particles, a leveling agent, a solvent, and a polymerization initiator, as necessary. The solvent and the polymerization initiator are the same as the solvent and polymerization initiator described in the section of the resin layer composition of the first embodiment.

After the coating film of the hard coat layer composition is prepared, the coating film is heated and dried at a temperature of, for example, 30° C. or higher and 120° C. or lower for a period of 10 to 120 seconds by various known techniques to evaporate the solvent.

The coating film of the hard coat layer composition is dried and then cured by exposure to ionizing radiation such as ultraviolet light to form a hard coat layer 73.

After forming the hard coat layer 73, a resin layer composition for forming a resin layer 72 is applied on the first surface 71A of the resin base material 71 by a coating apparatus such as bar coater to form a coating film of the resin layer composition. The resin layer 72 is formed by curing the coating film.

### <Resin Layer Composition>

In cases where the resin layer 72 is composed of a urethane resin, for example, any of the radiation-curable urethane resin compositions described in the section of the urethane resin can be used in the resin layer composition.

In cases where the resin layer composition contains a solvent, after the coating film of the resin layer composition is prepared, the coating film is heated and dried at a temperature of, for example, 30° C. or higher and 120° C. or lower for a period of 10 to 120 seconds by various known techniques to evaporate the solvent.

After drying the coating film, the coating film is exposed to ionizing radiation such as ultraviolet light to cure the coating film. The resin layer 12 is thus formed, and the optical film 70 can be obtained.

It is thought that creases occur because the inner surface or the outer surface of the resin base material is stretched when the optical film is folded, and the resin base material exceeds the elastic limit, resulting in plastic deformation. Therefore, in cases where the resin base material is thin, the elongation of the resin base material when the optical film is folded can be suppressed. However, a thin resin base material results in reduced impact resistance. The resin layer having a displacement amount of 200 nm or more and 1500 nm or less upon the indentation test has a wider elastic region than the resin base material. Therefore, in the resin layer, plastic deformation and creases are less likely to be generated compared with the resin base material. In cases where such a resin layer has a small film thickness, the impact resistance is reduced. Therefore, in order to obtain good impact resistance which prevents the depression of the front surface of the optical film when an impact force is applied on the front surface of the optical film, a film thickness of a certain level or more is required. According to the present embodiment, on the first surface 71A of the resin base material 71 having a thickness of 20 μm or less and a displacement amount d4 of 50 nm or more and 250 nm or less upon the indentation test, the resin layer 72 having a displacement amount d5 of 200 nm or more and 1500 nm or less upon the indentation test is provided; the thickness of the resin base material 71 is 20 μm or less; the film thickness of the resin layer 72 is 50 μm or more; and the ratio of the film thickness of the resin layer 72 to the thickness of the resin base material 71 is 4.0 or more and 12.0 or less. Thus, the creases are less likely to occur when the optical film 70 is folded, and good impact resistance can be obtained.

### <<<Image Display Device>>>

The optical film 70 may be incorporated into a foldable image display device and then used. The structure of the image display device integrating the optical film 70 is the same as the structure of the image display device 60 except that the optical film 70 is integrated instead of the optical film 30.

### Third Embodiment

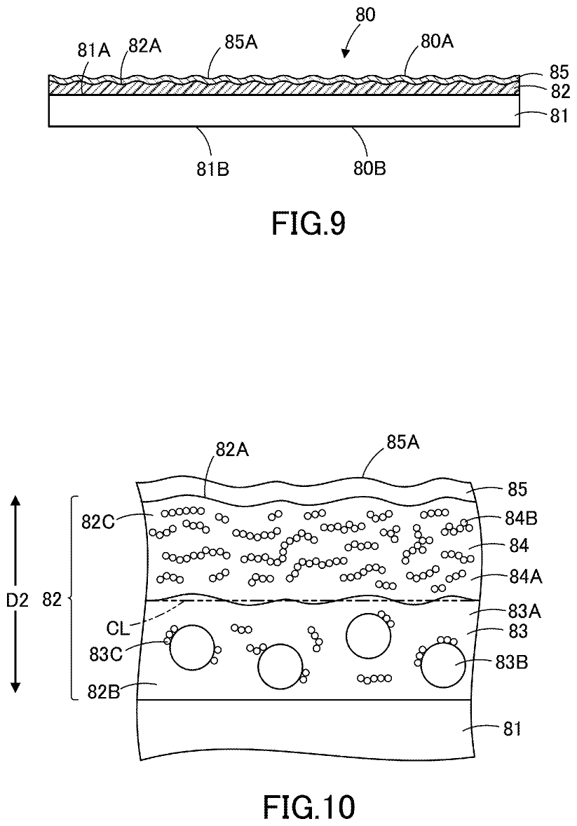

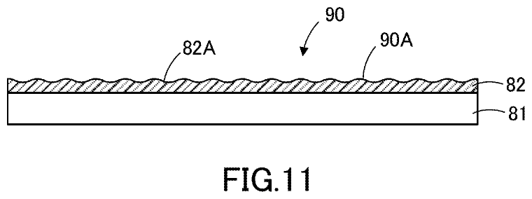

An optical film and an image display device according to the third embodiment of the present invention will be described below with reference to the drawings. FIG. 9 shows a schematic diagram of the optical film according to the present embodiment, and FIG. 10 is an enlarged view showing a portion of the optical film shown in FIG. 9, and FIG. 11 shows a schematic diagram of another optical film according to the present embodiment.

### <<<Optical Film>>>

An optical film 80 shown in FIG. 9 is used in an image display device and is foldable.

The optical film 80 comprises a resin base material 81 and a resin layer 82 provided on one surface of the resin base material 81, the first surface 81A, as shown in FIG. 9. The optical film 80 further comprises a functional layer 85 provided on the surface 82A of the resin layer 82. The “resin layer” in the present embodiment is a layer containing a resin, and may have a monolayer structure or a multilayer structure composed of two or more layers. The resin layer 82 has a multilayer structure composed of two or more layers, specifically a two-layer structure, but may have a monolayer structure. The functional layer 85 has a monolayer structure, and may have a multilayer structure composed of two or more layers.

The front surface 80A of the optical film 80 has an uneven surface. In FIG. 9, the front surface 80A of the optical film 80 corresponds to the surface 85A of the functional layer 85. The back surface 80B of the optical film 80 corresponds to the second surface 81B, the surface opposite to the first surface 81A of the resin base material 81.

The optical film 80 is foldable like the optical film 30. In the optical film 80, for example, no crack or break is formed in the optical film 80 even in cases where the folding test (successive folding test) is repeated on the optical film 80 preferably 100,000 times, more preferably 200,000 times, more preferably 300,000 times, and further preferably 1,000,000 times. The successive folding test is carried out in the same manner as the successive folding test described in the first embodiment, except for the gap distance φ between the two opposing edges is 8 mm. More preferably, in the optical film 80, no crack or break is formed even when the successive folding test is repeated 100,000 times on the optical film 80 in a manner that leaves a gap distance φ of 6 mm, 4 mm, or 2 mm between the two opposing edges.

When an abrasion resistance test is carried out, in which the front surface 80A of the optical film 80 (the surface 85A of the functional layer 85) is scrubbed to and fro 10 times at a rate of 60 mm/second using steel wool with a grade of 0.0000 (product name “Bonstar”; manufactured by Nihon Steel Wool Co., Ltd.) while a load of 1 kgf/cm² is applied to the steel wool, no scratch is preferably found. The above test should be measured on the optical film which is cut in a size of 50 mm×100 mm and fixed on a glass plate with Cello-tape®, manufactured by Nichiban Co., Ltd. without any fold or winkle and with the front surface of the optical film facing upward, in an environment at a temperature of 23±5° C. and a relative humidity of 30% or more and 70% or less. The above scratch refers to a scratch visible under a three-wavelength fluorescent lamp when a black vinyl tape (black vinyl tape NO200-38-21 manufactured by Yamato Co., Ltd.) is attached to the glass surface opposite to the optical film.

The yellow index of the optical film 80 and its measurement method are the same as the yellow index of the optical film 50 and its measurement method. The total light transmittance of the optical film 80 and its measurement method are the same as for the total light transmittance of the resin layer 10 and its measurement method. The use, size, and position of the optical film 80 are the same as the use, size, and position of the optical film 30.

The optical film 80 preferably has a haze value (total haze value) of 20% or less. In cases where the above haze value of the optical film 80 is 20% or less and the optical film 80 is used in a mobile terminal, the image display screen of the mobile terminal can be inhibited from turning white in color. The minimum haze value may be 1% or more, while the maximum haze value is more preferably 15% or less, 10% or less, or 5% or less. The haze value of the optical film 80 and its measurement method are the same as for the haze value of the resin layer 10 and its measurement method.

The transmission image sharpness of the optical film 80 is preferably 40% or more and 90% or less with a 0.125-mm bar pattern (comb A) and 80% or more with a 2.0-mm bar pattern (comb B). In cases where the transmission image sharpness with the 0.125-mm bar pattern (comb A) is 40% or more, glare (sparkle) can be suppressed. In cases where the transmission image sharpness with the 0.125-mm bar pattern (comb A) is 90% or less, the pressing marks can be less noticeable. Further, in cases where the transmission image sharpness with the 2.0-mm bar pattern (comb B) is 80% or more, the image can be clearly seen. The minimum value of the transmission image sharpness with the 0.125-mm bar pattern (comb A) is more preferably 45% or more, 50% or more, or 55% or more, while the maximum value is more preferably 85% or less. Further, the minimum value of the transmission image sharpness with the 2.0-mm bar pattern (comb B) is more preferably 90% or more.

The above transmission image sharpness value can be measured using an image clarity meter (for example, product name: “ICM-IT”; manufactured by Suga Test Instruments Co., Ltd.) in the environment with a temperature of 23±5° C. and a relative humidity of 30% or more and 70% or less by a transmission method of image sharpness determination in accordance with JIS K7374: 2007. The above transmission image sharpness is defined as the arithmetic mean of three measurements obtained by installing a cut piece of the optical film in a size of 50 mm×100 mm without generation of any curl or wrinkle and without any dirt such as fingerprints or grim in an image clarity meter set for transmission measurement with the resin base material facing the light source side, and measuring the cut piece of the optical film three times for one optical comb. If a piece having the same size as described above cannot be cut out from the optical film, a piece having a size equal to or greater than a diameter of 26 mm is required because, for example, the ICM-1T image clarity meter has an aperture of the sample stage having a diameter of 25 mm for use in the measurement. Thus, a piece having a size of 27 mm×27 mm or larger may be cut out from the optical film as appropriate. If the piece of the optical film is small in size, the optical film is gradually shifted or turned in such an extent that the light source spot is within the piece of the optical film to secure three measurement positions.

The front surface 80A of the optical film 80 has an uneven surface. The unevenness constituting the front surface 80A of the optical film 80 preferably satisfies the following relationship, in which the average spacing is Sm, the average inclination angle is θa, the arithmetic mean roughness is Ra, and the maximum height roughness is Ry.

0.15 mm≤Sm≤0.5 mm

0.02°≤θa≤0.50°

0.01 μm≤Ra≤0.15 μm

0.10 μm≤Ry≤0.50 μm

In cases where the average spacing Sm is 0.15 mm or more, the cloudiness of the image can be suppressed, and in cases where the Sm is 0.5 mm or less, glare (sparkle) can be suppressed. The minimum Sm is more preferably 0.20 mm or more or 0.22 mm or more, while the maximum Sm is more preferably 0.45 mm or less or 0.40 mm or less.

In cases where the average inclination angle θa is 0.02° or more, the pressing marks can be less noticeable, and in cases where θa is 0.05° or less, the cloudiness of the image can be suppressed. The minimum θa is more preferably 0.04° or more or 0.06° or more, while the maximum θa is more preferably 0.30° or less or 0.20° or less.

The above arithmetic mean roughness Ra is preferably 0.01 μm or more and 0.15 μm or less. In cases where Ra is 0.01 μm or more, the pressing marks can be less noticeable, and in cases where Ra is 0.15 μm or less, good identifiability of images can be obtained. The minimum Ra is more preferably 0.03 μm or more or 0.05 μm or more, while the maximum Ra is more preferably 0.12 μm or less or 0.10 μm or less.

The above maximum height roughness Ry is preferably 0.10 μm or more and 0.80 μm or less. In cases where Ry is 0.10 μm or more, the pressing marks can be less noticeable, and in cases where Ry is 0.50 μm or less, glare (sparkle) can be suppressed. The minimum Ry is more preferably 0.15 μm or more or 0.20 μm or more, while the maximum Ry is more preferably 0.60 μm or less or 0.40 μm or less.

The definition of “Sm”, “Ra” and “Ry” should follow JIS B0601: 1994. The definition of “θa” should follow the instruction manual (revised Jul. 20, 1995) of a surface roughness measuring instrument, Surfcoder SE-3400 (manufactured by Kosaka Laboratory Ltd.). θa is represented by the following mathematical formula (A).

θa=tan⁻¹ Δa (A)

In the formula (A), Δa represents the inclination expressed as an aspect ratio, and corresponds to the value obtained by dividing the sum of the differences between the minimum and maximum parts of each unevenness (corresponding to the height of each convex part) by the reference length.

Sm, Ra, Ry and θa can all be measured using, for example, Surfcoder SE-3400, SE-3500, or SE-500 (all manufactured by Kosaka Laboratory Ltd.). Even if θa cannot be measured directly, when Δa can be measured, θa can be obtained from Δa as measured since θa and Δa have the relationship shown in the above mathematical formula (A). The cutoff wavelength for measurement of Sm and the like should be set to 0.8 mm.

In cases where an additional film, such as a polarizing plate, is provided on the front surface of the optical film 80 through an adhesive or adhesion layer, the folding test, the yellow index measurement, the total light transmittance measurement, the haze value measurement, transmission image sharpness measurement, the average spacing Sm measurement and the like should be carried out after removing the additional film and the adhesive or adhesion layer.

The resin base material 81 is a base material containing a light-transmitting resin. Examples of the constituent materials of the resin base material 81 are the same materials as those of the resin base material 51. The thickness of the resin base material 81 is preferably 10 μm or more and 100 μm or less. In cases where the resin base material 81 has a thickness of 10 μm or more, the resulting optical film can be prevented from curling and also have sufficient hardness. Furthermore, with such a resin base material, even an optical film 80 produced by roll-to-roll process is less prone to wrinkling and less likely to deteriorate in appearance. In contrast, in cases where the resin base material 81 has a thickness of 100 μm or less, the resulting optical film 80 has excellent foldability, is able to satisfy the requirements of the successive folding test, and is also desirable in view of reducing the weight of the optical film 80. A cross-section of the resin base material 81 is photographed using a scanning electron microscope (SEM) and the film thickness of the resin base material 81 is measured at 10 different locations within the image of the cross-section, and the arithmetic mean of the 10 film thickness values is determined as the thickness of the resin base material 81. The minimum value for the resin base material 81 is more preferably 25 μm or more, 30 μm or more, or 35 μm or more, while the maximum value for the resin base material 81 is more preferably 80 μm or less, 75 μm or less, or 70 μm or less.

### <<Resin Layer>>

The surface 82A of the resin layer 82 has an uneven surface. This is due to the organic particles 83B described later. The Sm, θa, Ry, and Rz of the unevenness constituting the surface 82A preferably fall within the same range as the Sm, θa, Ry, and Rz of unevenness constituting the front surface 80A. The Sm and the like of the unevenness constituting the surface 82A can be measured in the same manner as the Sm and the like of unevenness constituting the front surface 80A.

The resin layer 82 is a layer which functions as a hard coat layer. The resin layer 82 may have another function in addition to the hard coat property. The “hard coat layer” in the present embodiment refers to a layer having an indentation hardness (H_{IT}) of 150 MPa or more at half the height of the cross-section of the hard coat layer. The “indentation hardness” as used herein refers to a value obtained from a load-displacement curve during the entire process from loading to unloading of an indenter. The arithmetic mean of the measurements at 10 different locations is determined as the indentation hardness. The method for measuring the indentation hardness is described below.

The indentation hardness of the lower part 82B of the resin layer 82 is preferably smaller than the indentation hardness of the upper part 82C of the resin layer 82. In cases where the indentation hardness of the lower part 82B of the resin layer 82 is smaller than the indentation hardness of the upper part 82C of the resin layer 82, since the organic particles 83B described later are present in the soft portion of the resin layer 82, the optical film 80 is less likely to crack when folded. Furthermore, since the hard portion is present closer to the side of the surface 82A than the organic particles 83B, more excellent surface hardness can be obtained.

Measurement of the indentation hardness (H_{IT}) should be performed on a measurement sample using a “TI950 TriboIndenter” manufactured by BRUKER Corporation. Specifically, a piece having a size of 1 mm×10 mm is cut out from the optical film and embedded in an embedding resin to prepare a block, and homogeneous sections having a thickness of 70 nm or more and 100 nm or less and having no openings or the like are cut out from the block according to a commonly used sectioning technique. For the preparation of sections, for example, an “Ultramicrotome EM UC7” from Leica Microsystems GmbH or the like can be used. Then, the block remaining after cutting out the homogeneous sections having no openings or the like is used as a measurement sample. Subsequently, in the cross-section of the measurement sample obtained after cutting out the above-described sections, a Berkovich indenter (a trigonal pyramid, TI-0039, manufactured by BRUKER Corporation) as the above-described indenter is pressed perpendicularly into the resin layer at the bottom cross-section, wherein the indenter is pressed up to the maximum pressing load of 50 μN over 10 seconds under the below-mentioned measurement conditions. In this respect, a Berkovich indenter is pressed into the lower part of the resin layer at a position located 500 nm away from the interface between the resin base material and the resin layer toward the center of the resin layer and 500 nm or more away from both edges of the resin layer toward the center of the resin layer, in order to avoid the influence of the resin layer and the side edges of the resin base material. Subsequently, the indenter is held for 5 seconds, and then unloaded over 10 seconds. The above maximum pressing load Pₘₐₓ and the contact projection area Aₚ are used to calculate an indentation hardness (H_{IT}) from Pₘₐₓ/Aₚ. The contact projection area is a contact projection area, for which the tip curvature of the indenter is corrected using fused quartz (5-0098, manufactured by BRUKER Corporation) as a standard sample in accordance with the Oliver-Pharr method. The arithmetic mean of the measurements at 10 different locations is determined as the indentation hardness (H_{IT}). In cases where a measured value which falls outside the arithmetic mean plus and minus 20% is included in the measured values, the measured value should be excluded to repeat the measurement again. Whether or not a measured value which falls outside the arithmetic mean plus and minus 20% is included in the measured values should be determined by whether or not a value (%) obtained by the formula (A−B)/B×100 equals or exceeds ±20%, where A represents a measured value and B represents the arithmetic mean. The indentation hardness of the upper part of the resin layer is also measured in the same manner as the indentation hardness of the lower part of the resin layer. In this case, a Berkovich indenter is pressed into the upper part of the resin layer at a position located 500 nm away from the interface between the resin layer and the functional layer toward the center of the resin layer and 500 nm or more away from both edges of the resin layer toward the center of the resin layer, in order to avoid the influence of the functional layer and the side edges of the resin layer.

### (Measurement Conditions)

Control mode: Load control mode

Loading speed: 5 μN/sec

Dwell time: 5 sec

Unloading speed: 5 μN/sec

Temperature: 23 to 25° C.

Relative humidity: 30 to 70%

The resin layer 82 preferably has a film thickness of 2 μm or more and 15 μm or less. The resin layer 82 with a film thickness of 2 μm or more can have sufficient hardness as a hard coat layer, while the resin layer with a film thickness of 15 μm or less can prevent reduction in workability. The “film thickness of the resin layer” as used in the present embodiment refers to the sum of the film thickness (total thickness) of resin layers in cases where the resin layer has a multilayer structure. The minimum value for the resin layer 82 is more preferably 3 μm or more, 4 μm or more, or 5 μm or more, while the maximum value for the resin layer 82 is more preferably 12 μm or less, 10 μm or less, or 8 μm or less.

A cross-section of the resin layer 12 is photographed in the same manner as the cross-section of the functional layer 31 using a scanning transmission electron microscope (STEM) or a transmission electron microscope (TEM), and the film thickness of the resin layer 82 is measured at 10 different locations within the image of the cross-section, and the arithmetic mean of the 10 film thickness values is determined as the film thickness of the resin layer 82. A mixed layer containing a component constituting the resin base material 81 and a component constituting the resin layer 82 may be present between the resin base material 81 and the resin layer 82. In this case, the film thickness of this mixed layer is not included in the film thickness of the resin layer.

The resin layer 82 contains the organic particles 83B described later. The organic particles 83B are unevenly distributed on the side of the resin base material 81 with respect to the center line CL (see FIG. 10) which is an imaginary line that bisects the resin layer 82 in the film thickness direction D2 of the resin layer 82. The uneven distribution of the organic particles 83B on the side of the resin base material 81 with respect to the center line CL can be determined as follows: the center of each organic particle 83B is determined from a cross-sectional image of the resin layer 12 by a scanning transmission electron microscope (STEM) or a transmission electron microscope (TEM); and whether or not the average position of the centers is present on the side of the resin base material 81 with respect to the center line CL can be judged. Specifically, as is the case with the measurement of the film thickness of the resin layer 82, a cross-section of the resin layer 82 is photographed using a scanning transmission electron microscope (STEM) or a transmission electron microscope (TEM), and cross-sectional images at 10 different locations are prepared. In each cross-sectional image, the film thickness of the resin layer 82 is measured to determine the position of the center line CL. In addition, the centers of the organic particles 83B present in each cross-sectional image are obtained. The center can be obtained by finding the midpoint of the imaginary line segment of an organic particle, connecting the point closest to and the point farthest from the resin base material in the film thickness direction of the resin layer. Then, in each cross-sectional image, the distance between the center of the organic particle 83B and the center line CL is measured for each organic particle 83B. When the center of the organic particle 83B is located below the center line CL (the side of the resin base material 81), the distance between the center of the organic particle 83B and the center line CL is expressed with “−”. When the center is located above the center line CL (on the side of the functional layer 85), the distance between the center of the organic particle 83B and the center line CL is expressed with “+”. Then, by determining the average distance, the average position of the centers of the organic particles 83B can be obtained. Whether or not this average position of the centers is present on the side of the resin base material 81 with respect to the center line CL can be determined depending on whether the obtained average position is “−” or “+”.

The ratio of the average particle diameter of the organic particles 83B to the film thickness of the resin layer 82 (average particle diameter/film thickness) is preferably 0.1 or more and 1 or less. In cases where this ratio is 0.1 or more, desired unevenness can be obtained. In cases where this ratio is 1 or less, it is easy to distribute the organic particles 83B unevenly on the side of the resin base material 11 with respect to the center line CL that bisects the resin layer 82 in the film thickness direction D2. The average particle diameter of the organic particles 83B is defined as the arithmetic mean of the particle diameters of 20 organic particles, where the particle diameters of the 20 particles are measured from cross-sectional images of organic particles acquired using a transmission electron microscope (TEM) or scanning transmission electron microscope (STEM) at a magnification of 5,000 to 20,000. The measurement of the particle diameter of the organic particles is performed by the following procedure. First, the major axis and the minor axis are measured, and the particle diameter of each particle is calculated from the average of the major axis and minor axis. The major axis herein is the longest diameter on the image of each particle. The minor axis is the distance between two points of the intersection of the particle and an orthogonal line which is orthogonal to the midpoint of the line segment constituting the major axis.

The resin layer 82 comprises a first resin layer 83 and a second resin layer 84 provided closer to the side of the surface 82A than the first resin layer 83. In FIG. 10, since the film thicknesses of the first resin layer 83 is the same as that of the second resin layer 84, the center line CL exists near the interface between the first resin layer 83 and the second resin layer 84.

### <First Resin Layer>

The first resin layer 83 contains a binder resin 83A and organic particles 83B. The presence of the organic particles 83B in the first resin layer 83 can make the surface 82A of the resin layer 82 uneven. Preferably, the first resin layer 83 further contains inorganic particles 83C. The presence of the inorganic particles 83C in the first resin layer 83 can lead to the easy control of the uneven shape. In addition to the binder resin 83A or the like, the first resin layer 83 may contain, if necessary, an additive such as an ultraviolet absorber, an adhesion-improving agent, a leveling agent, a thixotropy enhancing agent, a coupling agent, a plasticizer, an antifoam agent, a bulking agent, and a coloring agent as long as the effects of the present invention are not impaired.

The indentation hardness of the first resin layer 83 is preferably smaller than the indentation hardness of the second resin layer 84. In cases where the indentation hardness of the first resin layer 83 is smaller than the indentation hardness of the second resin layer 84, since the organic particles 83B are present in the soft, first resin layer 83, the optical film 80 is less likely to crack when folded. Furthermore, since the second resin layer 84, which is hard, is present closer to the side of the surface 82A than the organic particles 83B, more excellent surface hardness can be obtained.

The first resin layer 83 preferably has an indentation hardness of 150 MPa or more and 350 MPa or less. The first resin layer 83 with an indentation hardness of 150 MPa or more can have good pencil hardness, while the first resin layer 83 with an indentation hardness of 350 MPa or less can provide good flexibility. The minimum indentation hardness of the first resin layer 83 is more preferably 180 MPa or more, 200 MPa or more, or 220 MPa or more, while the maximum indentation hardness is more preferably 330 MPa or less, 300 MPa or less, or 280 MPa or less. The indentation hardness of the first resin layer 83 should be measured in the same manner and under the same measurement conditions as the indentation hardness of the lower part 82B of the resin layer 82.

### (Binder Resin)

The binder resin 83A comprises a polymerized product (a cured product) of a polymerizable compound (a curable compound). The polymerizable compound refers to a molecule having at least one polymerizable functional group. The polymerizable functional group and the polymerizable compound are the same as those described in the section of the functional layer 31.

### (Organic Particles)

The organic particles 83B are particles composed mainly of an organic component. In addition to the organic component, the organic particles 83B may contain an inorganic component. Examples of the organic particles include polymethyl methacrylate particles, polyacrylic-styrene copolymer particles, melamine resin particles, polycarbonate particles, polystyrene particles, crosslinked polystyrene particles, polyvinyl chloride particles, benzoguanamine-melamine formaldehyde particles, silicone particles, and fluororesin particles, and polyester resin particles.

The organic particles 83B are preferably spherical in view of facilitated control for forming the above-mentioned uneven shape. As used herein, the term “spherical” includes, for example, a true spherical shape, an elliptical spherical shape, and the like, but does not include so-called amorphous shapes.

The average particle diameter of the organic particles 83B is preferably 0.5 μm or more and 10 μm or less. When the average particle diameter of the organic particles 83B is within this range, the control for forming a desired uneven shape is facilitated. The minimum average particle diameter of the organic particles is more preferably 1.0 μm or more or 1.5 μm or more, while the maximum average particle diameter is more preferably 8 μm or less, 6 μm or less, or 4 μm or less.

### (Inorganic Particles)

The inorganic particles 83C are particles containing mainly an inorganic component. The average particle diameter of the inorganic particles 83C is preferably 1 nm or more and 50 nm or less. In cases where the average particle diameter of the inorganic particles 83C is 1 nm or more, it is easy to control the uneven shape. In cases where the average particle diameter of the inorganic particles 83C is 50 nm or less, the diffusion of light by the inorganic particles 83C can be suppressed, and thus excellent contrast can be obtained. The minimum average particle diameter of inorganic particles 83C is more preferably 3 nm or more, 5 nm or more, or 7 nm or more, while the maximum average particle diameter is more preferably 40 nm or less, 30 nm or less, or 20 nm or less. The average particle diameter of the inorganic particles 83C is defined as the arithmetic mean of the particle diameters of 20 inorganic particles, where the particle diameters of the 20 inorganic particles are measured from cross-sectional images of inorganic particles acquired using a transmission electron microscope (TEM) or scanning transmission electron microscope (STEM) at a magnification of 50,000 to 200,000.

The content of the inorganic particles 83C in the first resin layer 83 is smaller than the content of the inorganic particles 84B in the second resin layer 84, which will be described later. In cases where the content of the inorganic particles 83C is smaller than the content of the inorganic particles 84B, the first resin layer 83 can be made softer than the second resin layer 84.

Examples of the inorganic particles 83C include, but are not limited to, inorganic oxide particles, such as silica (SiO₂) fine particles, alumina particles, titania particles, tin oxide particles, antimony-doped tin oxide (abbreviation: ATO) particles, and zinc oxide particles.

In cases where silica particles are used as the inorganic particles 83C, fumed silica particles are preferred among silica particles in view of easer formation of a resin layer 82 having a smooth uneven surface. Fumed silica is amorphous silica having a particle diameter of 200 nm or less produced by a dry method, and can be obtained by reacting a volatile compound containing silicon in a gas phase. Specific examples thereof include those produced by hydrolyzing a silicon compound such as silicon tetrachloride (SiCl₄) in a flame of oxygen and hydrogen. Examples of commercially available fumed silica particles include AEROSIL® R805 manufactured by NIPPON AEROSIL Co., Ltd.

When inorganic oxide particles are used as inorganic particles 83C, the inorganic oxide particles are preferably amorphous. This is because when the inorganic oxide particles are crystalline, the Lewis acid salt of the inorganic oxide particles is dominant due to lattice defects contained in the crystal structure, and excessive aggregation of the inorganic oxide particles may not be able to be controlled.

Further, in cases where fumed silica particles are used as the inorganic particles 83C, among fumed silica particles which exhibit hydrophilicity or hydrophobicity, those exhibiting hydrophobicity are preferred in view of the reduced amount of absorbed water and facilitated dispersion in the resin layer composition. The hydrophobic fumed silica can be obtained by chemically reacting the silanol groups present on the surface of the fumed silica particles with a surface treatment agent as described above.

The inorganic particles 83C have preferably a spherical shape in a single particle state. In cases where each single particle of the inorganic particles 83C has such a spherical shape, it is possible to obtain an image having better contrast when the optical film is arranged on the image display surface of the image display device.

### <Second Resin Layer>

The second resin layer 84 contains a binder resin 84A and inorganic particles 84B. The presence of the organic particles 84B in the second resin layer 84 can improve the hardness of the resin layer 82. The second resin layer 84 does not contain an organic particle. In addition to the binder resin 84A and the like, the second resin layer 84 may contain, if necessary, an additive such as ab ultraviolet absorber, an adhesion-improving agent, a leveling agent, a thixotropy enhancing agent, a coupling agent, a plasticizer, an antifoam agent, a bulking agent, and a coloring agent as long as the effects of the present invention are not impaired.

The second resin layer 84 preferably has an indentation hardness of 250 MPa or more and 450 MPa or less. The second resin layer 84 with an indentation hardness of 250 MPa or more can have good pencil hardness and abrasion resistance, while the second resin layer 84 with an indentation hardness of 450 MPa or less can provide good flexibility. The minimum indentation hardness of the second resin layer 84 is more preferably 270 MPa or more, 300 MPa or more, or 320 MPa or more, while the maximum indentation hardness is more preferably 420 MPa or less, 400 MPa or less, or 370 MPa or less. The indentation hardness of the second resin layer 84 should be measured by the same manner and under the same measurement conditions as the indentation hardness of the upper part 82C of the resin layer 82.

### (Binder Resin)

The binder resin 84A contains a polymerized product (a cured product) of a polymerizable compound (a curable compound). The polymerizable compound is preferably a polyfunctional (meth)acrylate. The above-described polyfunctional (meth)acrylate include the same polyfunctional (meth)acrylates as described for the binder resin of the first resin layer 13. Additionally, the binder resin may contain, for example, polyfunctional urethane (meth)acrylate, polyfunctional epoxy (meth)acrylate, and/or reactive polymers, in addition to the above-described polyfunctional (meth)acrylate.

### (Inorganic Particles)

The inorganic particles 84B are the same as the inorganic particles described in the section of the functional layer 31.

### <<Functional Layer>>

The surface 85A of the functional layer 85 reflects the unevenness of the surface of the resin layer 82. The functional layer 85 may be a monolayer, but may have a multilayer structure composed of two or more layers. Specifically, the functional layer 85 may have, for example, a laminated structure of an inorganic layer and an antifouling layer. By forming the antifouling layer, it is possible to suppress the adhesion of fingerprints and the like.

### (Inorganic Layer)

The inorganic layer is a layer composed mainly of an inorganic substance, and, for example, a layer containing 55% by mass or more of inorganic substance falls under an inorganic layer. The inorganic layer may contain an organic substance, but is preferably composed only of an inorganic substance. The inorganic layer can be identified by X-ray photoelectron spectroscopy (X-Ray Photoelectron Spectroscopy: XPS or Electron Spectroscopy for Chemical Analysis: ESCA).

Examples of constituent materials for the inorganic layer include: metals such as Ti, Al, Mg, and Zr; inorganic oxides such as silicon oxide (SiOₓ (x=1 to 2)), aluminum oxide, silicon nitride oxide, aluminum nitride oxide, magnesium oxide, zinc oxide, indium oxide, tin oxide, and yttrium oxide; inorganic nitrides; diamondlike carbon; and the like. Among these, silicon oxide is preferable in terms of enhancing transmittance and enhancing abrasion resistance.

The inorganic layer preferably contains a Si atom. The inorganic layer containing Si atoms makes it possible to seek a lower refractive index. Whether or not the inorganic layer contains Si atoms can be checked by X-ray photoelectron spectroscopy (X-Ray Photoelectron Spectroscopy: XPS or Electron Spectroscopy for Chemical Analysis: ESCA).

The inorganic layer preferably has a film thickness of 10 nm or more and 300 nm or less. The inorganic layer having a film thickness of 10 nm or more affords excellent abrasion resistance, and 300 nm or less allows the adhesiveness to another layer to be favorable without affecting the flexibility and optical properties. The minimum film thickness of the inorganic layer is more preferably 30 nm or more, 50 nm or more, or 80 nm or more, while the maximum film thickness is more preferably 250 nm or less, 200 nm or less, or 150 nm or less. The film thickness of the inorganic layer should be determined in the same manner as the film thickness of the resin layer 82.

The inorganic layer can be formed, for example, by a vapor deposition method such as PVD or CVD. Examples of PVD methods include vacuum vapor deposition, sputtering, ion plating, and the like. Examples of vacuum vapor deposition methods include vacuum vapor deposition based on an electron beam (EB) heating method, vacuum vapor deposition based on a high-frequency dielectric heating method, and the like.

### (Antifouling Layer)

The antifouling layer is not particularly limited as long as it has water and oil repellency and can impart antifouling performance to the resulting optical film 80, but preferably is composed of a fluorine-containing organosilicon compound layer which is obtained by curing a film of a fluorine-containing organosilicon compound.

The thickness of the antifouling layer is not particularly limited. In cases where the antifouling layer is composed of the fluorine-containing organosilicon compound layer, the film thickness of the antifouling layer is preferably 1 nm or more and 20 nm or less. In cases where the thickness of the antifouling layer is 1 nm or more, the antifouling layer covers uniformly the inorganic layer, which is sufficient for practical use in view of abrasion resistance. In cases where the thickness of the antifouling layer is 20 nm or less, the optical properties such as the haze value of the optical film with the antifouling layer formed are good. The maximum film thickness of the antifouling layer is preferably 15 nm or less or 10 nm or less.

Examples of the method for forming a fluorine-containing organosilicon compound layer include a method in which a composition of a silane coupling agent having a fluoroalkyl group such as a perfluoroalkyl group; a fluoroalkyl group containing a perfluoro(polyoxyalkylene) chain is applied on the surface of the inorganic layer by a spin coating method, a dip coating method, a casting method, a slit coating method, a spray coating method, or the like, and then thermally treated, and a vacuum vapor deposition method in which a fluorine-containing organosilicon compound is vapor deposited on the surface of the inorganic layer and then thermally heated. In order to obtain a fluorine-containing organosilicon compound layer having high adhesiveness, the antifouling layer is preferably obtained by a vacuum vapor deposition method. The formation of the fluorine-containing organosilicon compound layer by the vacuum vapor deposition method is preferably performed with a film-forming composition containing a fluorine-containing hydrolyzable silicon compound.

The film-forming composition is a composition containing a fluorine-containing hydrolyzable silicon compound and is not particularly limited as long as it is a composition that can form a film by a vacuum vapor deposition method. The film-forming composition may contain any optional component other than the fluorine-containing hydrolyzable silicon compound, or may be composed only of the fluorine-containing hydrolyzable silicon compound. Examples of the optional component include a hydrolyzable silicon compound containing no fluorine atom (hereinafter referred to as “fluorine-free hydrolyzable silicon compound”), a catalyst and the like, which are used as long as the effects of the present invention are not impaired.

The fluorine-containing hydrolyzable silicon compound used for forming a film of the fluorine-containing organosilicon compound is not particularly limited as long as the resulting film of the fluorine-containing organosilicon compound has antifouling performance such as water repellency and oil repellency.

Specific examples of the fluorine-containing hydrolyzable silicon compound include a fluorine-containing hydrolyzable silicon compound having one or more groups selected from the group consisting of a perfluoropolyether group, a perfluoroalkylene group and a perfluoroalkyl group. These groups exist as fluorine-containing organic groups that are bound to the silicon atom of the hydrolyzable silyl group via a linking group or directly. The perfluoropolyether group refers to a divalent group having a structure in which a perfluoroalkylene group and an ether oxygen atom are alternately bound.

Examples of a commercially available fluorine-containing organosilicon compound having one or more groups selected from the group consisting of a perfluoropolyether group, a perfluoroalkylene group and a perfluoroalkyl group include KP-801, X-71 and KY-130, KY-178, KY-185 (all manufactured by Shin-Etsu Chemical Co., Ltd.), and OPTOOL® DSX (manufactured by Daikin Industries, Ltd.). Among these, KY-185 and OPTOOL® DSX are preferred.

When a commercially available fluorine-containing hydrolyzable silicon compound is supplied together with a solvent, the commercially available fluorine-containing hydrolyzable silicon compound is preferably used after the solvent is removed. The film-forming composition is prepared by mixing a fluorine-containing hydrolyzable silicon compound and an optional component added as needed, and is subjected to vacuum deposition.

Such a film-forming composition containing a fluorine-containing hydrolyzable silicon compound is adhered to the surface of the inorganic layer and reacted to form a film. Thus, a fluorine-containing organosilicon compound layer can be obtained. In this case, the antifouling layer is made of a cured product of a film-forming composition containing a fluorine-containing hydrolyzable silicon compound. For the specific method of the vacuum vapor deposition and reaction conditions, conventionally known methods, conditions and the like can be applied.

### <<Other Optical Films>>

The optical film 80 shown in FIG. 9 includes a functional layer 85, but may not include a functional layer like the optical film 90 shown in FIG. 11. The front surface 90A of the optical film 90 is constituted by the surface 82A of the resin layer 82.

### <<<Image Display Device>>>

The optical film 80 or 90 may be incorporated into a foldable image display device and then used. The structure of the image display device integrating the optical film 80 or 90 is the same as the structure of the image display device 60 except that the optical film 80 or 90 is integrated instead of the optical film 30.

According to the present embodiment, the presence of the organic particles 83B in the resin layer 82 allows not only the surface 82A of the resin layer 82 but also the front surface 80A of the optical film 80 to be uneven. As a result, the transmitted and reflected light can be blurred. Thus, even when the front surface is pressed with a finger to cause a temporary depression, the pressing mark is difficult to be noticed.

According to the present embodiment, since the organic particles 83B in the resin layer 82 are unevenly distributed on the side of resin base material 81 with respect to the center line CL, the pressure is difficult to be applied to the organic particles 83B near the bent part S3 when the optical film is folded, and thus the film is less likely to crack. In particular, in cases where the organic particles in the resin layer are present on the side of the surface of the resin layer, cracks occur easily when the optical film is folded in a way that the front surface of the resin layer faces outward (that is, when the optical film is bent outward). However, in the present embodiment, the organic particles 83B in the resin layer 82 are unevenly distributed on the side of the resin base material 81 with respect to the center line CL. Therefore, even when the optical film 80 is folded in a way that the surface 82A of the resin layer 82 faces outward, cracks can be suppressed. Thus, such an optical film 80 is particularly effective when the optical film 80 is folded in a way the surface 82A of the resin layer 82 faces outward.

According to the present embodiment, since the organic particles 83B in the resin layer 82 are unevenly distributed on the side of resin base material 81 with respect to the center line CL, the organic particles 83B are not present in the vicinity of the surface 82A of the resin layer 82. Consequently, the surface hardness and the abrasion resistance can be improved.

### EXAMPLES

Now, the present invention will be described in more detail by way of examples. However, the present invention is not limited to those examples.

### <Preparation of Hard Coat Layer Compositions>

First, the following components were combined to meet the composition requirements indicated below and thereby to obtain hard coat layer compositions.

### (Hard Coat Layer Composition 1)

A mixture of dipentaerythritol pentaacrylate and dipentaerythritol hexaacrylate (product name: “M403”; manufactured by Toagosei Co., Ltd.): 25 parts by mass;

EO-modified dipentaerythritol hexaacrylate (product name: “A-DPH-6E”; manufactured by Shin-Nakamura Chemical Co., Ltd.): 25 parts by mass;

Deformed silica particles (with an average particle diameter of 25 nm; manufactured by JGC C&C): 50 parts by mass (a converted value based on 100% solids);

Polymerization initiator (1-hydroxycyclohexyl phenyl ketone; product name: “Omnirad184”; manufactured by IGM Resins B.V.): 4 parts by mass;

Fluorine-based leveling agent (product name “F568”; manufactured by DIC Corporation): 0.2 parts by mass (a converted value based on 100% solids);

Methyl isobutyl ketone (MIBK): 150 parts by mass.

### (Hard Coat Layer Composition 2)

Polyfunctional acrylate (product name: “KAYARAD PET-30”; manufactured by Nippon Kayaku Co., Ltd.): 18 parts by mass;

EO-modified acrylate (product name: “ATM-35E”; manufactured by Shin-Nakamura Chemical Co., Ltd.): 12 parts by mass;

Inorganic particles (fumed silica, octylsilane-treated, average particle diameter of 12 nm, manufactured by NIPPON AEROSIL Co., Ltd.): 0.6 parts by mass;

Organic particles (particle diameter of 2 μm, refractive index of 1.555, spherical acrylic-styrene copolymer): 1.5 parts by mass;

Silicone leveling agent: 0.075 parts by mass;

Polymerization initiator (product name: “Omnirad184”; manufactured by IGM Resins B.V.): 0.3 parts by mass;

Toluene: 50 parts by mass;

Propylene glycol monomethyl ether acetate: 17 parts by mass;

Cyclohexanone: 1 part by mass;

Isopropanol: 2 parts by mass.

### (Hard Coat Layer Composition 3)

EO-modified acrylate (product name: “A-DPH18E”; manufactured by Shin-Nakamura Chemical Co., Ltd.): 15 parts by mass;

Reactive acrylic polymer (product name “SMP220A”, solid content of 50%, diluting solvent of methyl isobutyl ketone, manufactured by Kyoeisha Chemical Co., Ltd.): 10 parts by mass;

Inorganic particles (Organosilicasol, product name “MIBK-SD”, SiO₂ solid content of 30%, diluting solvent of methyl isobutyl ketone, particle diameter of 10 to 15 nm, manufactured by Nissan Chemical Corporation): 50 parts by mass;

Silicone leveling agent: 0.15 parts by mass;

Polymerization initiator (product name: “Omnirad184”; manufactured by IGM Resins B.V.): 1 part by mass;

Propylene glycol monomethyl ether: 24 parts by mass.

### (Hard Coat Layer Composition 4)

Polyfunctional acrylate (product name: “KAYARAD PET-30”; manufactured by Nippon Kayaku Co., Ltd.): 18 parts by mass;

EO-modified acrylate (product name: “ATM-35E”; manufactured by Shin-Nakamura Chemical Co., Ltd.): 12 parts by mass;

Organic particles (particle diameter of 3.5 μm, refractive index of 1.540, spherical acrylic-styrene copolymer): 2.5 parts by mass;

Organic particles (particle diameter of 3.5 μm, refractive index of 1.555, spherical acrylic-styrene copolymer): 0.4 parts by mass;

Silicone leveling agent: 0.075 parts by mass;

Polymerization initiator (product name: “Omnirad184”; manufactured by IGM Resins B.V.): 0.3 parts by mass;

Toluene: 50 parts by mass;

Propylene glycol monomethyl ether acetate: 18 parts by mass;

Cyclohexanone: 1 part by mass;

Isopropanol: 2 parts by mass.

### (Hard Coat Layer Composition 5)

Polyfunctional acrylate (product name: “KAYARAD PET-30”; manufactured by Nippon Kayaku Co., Ltd.): 19 parts by mass;

EO-modified acrylate (product name: “ATM35E”; manufactured by Shin-Nakamura Chemical Co., Ltd.): 16 parts by mass;

Silicone leveling agent: 0.15 parts by mass;

Polymerization initiator (product name: “Omnirad184”; manufactured by IGM Resins B.V.): 1 part by mass;

Propylene glycol monomethyl ether: 64 parts by mass.

### <Resin Layer Composition>

The following components were combined to meet the composition requirements indicated below and thereby obtain resin layer compositions.

### (Resin Layer Composition 1)

Urethane acrylate (product name: “UV3310B”; manufactured by Mitsubishi Chemical Corporation): 80 parts by mass;

Monofunctional acrylic monomer (product name: “Viscoat #200”; manufactured by Osaka Organic Chemical Industry Ltd.): 20 parts by mass;

Polymerization initiator (product name: “Ominirad127”; manufactured by IGM Resins B.V.): 3 parts by mass;

Methyl isobutyl ketone (MIBK): 10 parts by mass.

### (Resin Layer Composition 2)

Urethane acrylate (product name: “UV3310B”; manufactured by Mitsubishi Chemical Corporation): 80 parts by mass;

Monofunctional acrylic monomer (product name: “Viscoat #150D”; manufactured by Osaka Organic Chemical Industry Ltd.): 10 parts by mass;

Monofunctional acrylic monomer (product name: “Viscoat #200”; manufactured by Osaka Organic Chemical Industry Ltd.): 10 parts by mass;

Polymerization initiator (product name: “Ominirad127”; manufactured by IGM Resins B.V.): 3 parts by mass;

Methyl isobutyl ketone (MIBK): 10 parts by mass.

### (Resin Layer Composition 3)

Urethane acrylate (product name: “UV3310B”; manufactured by Mitsubishi Chemical Corporation): 80 parts by mass;

Monofunctional acrylic monomer (product name: “Viscoat #150D”; manufactured by Osaka Organic Chemical Industry Ltd.): 20 parts by mass;

Polymerization initiator (product name: “Ominirad127”; manufactured by IGM Resins B.V.): 3 parts by mass;

Methyl isobutyl ketone (MIBK): 10 parts by mass.

### (Resin Layer Composition 4)

Urethane acrylate (product name: “UV3310B”; manufactured by Mitsubishi Chemical Corporation): 80 parts by mass;

Monofunctional acrylic monomer (product name: “Viscoat #150D”; manufactured by Osaka Organic Chemical Industry Ltd.): 20 parts by mass;

Polymerization initiator (product name: “Ominirad127”; manufactured by IGM Resins B.V.): 1 part by mass;

Polymerization initiator (product name: “Ominirad184”; manufactured by IGM Resins B.V.): 2 parts by mass;

Methyl isobutyl ketone (MIBK): 10 parts by mass.

### (Resin Layer Composition 5)

Urethane acrylate (product name: “UV3310B”; manufactured by Mitsubishi Chemical Corporation): 80 parts by mass;

Monofunctional acrylic monomer (product name: “Viscoat #150D”; manufactured by Osaka Organic Chemical Industry Ltd.): 20 parts by mass;

Polymerization initiator (product name: “Ominirad127”; manufactured by IGM Resins B.V.): 6 parts by mass;

Methyl isobutyl ketone (MIBK): 10 parts by mass.

### (Resin Layer Composition 6)

Urethane acrylate (product name: “UV3310B”; manufactured by Mitsubishi Chemical Corporation): 80 parts by mass;

Monofunctional acrylic monomer (product name: “ACMO”; manufactured by KJ Chemicals Corporation): 20 parts by mass;

Polymerization initiator (product name: “Ominirad127”; manufactured by IGM Resins B.V.): 3 parts by mass;

Methyl isobutyl ketone (MIBK): 10 parts by mass.

### (Resin Layer Composition 7)

Urethane acrylate (product name: “UV3310B”; manufactured by Mitsubishi Chemical Corporation): 80 parts by mass;

Monofunctional acrylic monomer (product name: “IBXA”; manufactured by Osaka Organic Chemical Industry Ltd.): 20 parts by mass;

Polymerization initiator (product name: “Ominirad127”; manufactured by IGM Resins B.V.): 3 parts by mass;

Methyl isobutyl ketone (MIBK): 10 parts by mass.

### (Resin Layer Composition 8)

Urethane acrylate (product name: “UV3310B”; manufactured by Mitsubishi Chemical Corporation): 80 parts by mass;

Monofunctional acrylic monomer (product name: “Viscoat #150D”; manufactured by Osaka Organic Chemical Industry Ltd.): 10 parts by mass;

Monofunctional acrylic monomer (product name: “Viscoat #200”; manufactured by Osaka Organic Chemical Industry Ltd.): 5 parts by mass;

Monofunctional acrylic monomer (product name: “ACMO”; manufactured by KJ Chemicals Corporation): 5 parts by mass;

Polymerization initiator (product name: “Ominirad127”; manufactured by IGM Resins B.V.): 5 parts by mass;

Methyl isobutyl ketone (MIBK): 10 parts by mass.

### (Resin Layer Composition 9)

Urethane acrylate (product name: “UV3310B”; manufactured by Mitsubishi Chemical Corporation): 80 parts by mass;

Monofunctional acrylic monomer (product name: “Viscoat #150D”; manufactured by Osaka Organic Chemical Industry Ltd.): 20 parts by mass;

Polymerization initiator (product name: “OminiradTPOH”; manufactured by IGM Resins B.V.): 3 parts by mass;

Methyl isobutyl ketone (MIBK): 10 parts by mass.

### (Resin Layer Composition 10)

Urethane acrylate (product name: “UV3310B”; manufactured by Mitsubishi Chemical Corporation): 80 parts by mass;

Monofunctional acrylic monomer (product name: “Viscoat #150D”; manufactured by Osaka Organic Chemical Industry Ltd.): 20 parts by mass;

Polymerization initiator (product name: “Ominirad127”; manufactured by IGM Resins B.V.): 2 parts by mass;

Polymerization initiator (product name: “Ominirad184”; manufactured by IGM Resins B.V.): 2 parts by mass;

Polymerization initiator (product name: “OminiradTPOH”; manufactured by IGM Resins B.V.): 1 part by mass;

Methyl isobutyl ketone (MIBK): 10 parts by mass.

### (Resin Layer Composition 11)

Urethane acrylate (product name: “UV-3310B”; manufactured by Mitsubishi Chemical Corporation): 90 parts by mass;

Phenoxyethylacrylate (product name “Viscoat #192”; manufactured by Osaka Organic Chemical Industry Ltd.): 10 parts by mass;

Polymerization initiator (1-hydroxycyclohexyl phenyl ketone; product name: “Omnirad184”; manufactured by IGM Resins B.V.): 5 parts by mass;

Methyl isobutyl ketone: 10 parts by mass.

### (Resin Layer Composition 12)

Urethane acrylate (product name: “UV-3310B”; manufactured by Mitsubishi Chemical Corporation): 50 parts by mass;

Ethoxylated pentaerythritol tetraacrylate (product name: “ATM-35E”; manufactured by Shin-Nakamura Chemical Co., Ltd.): 40 parts by mass;

Dicyclopentanyl acrylate (product name “FA-513AS”, manufactured by Hitachi Chemical Co., Ltd.): 10 parts by mass;

Polymerization initiator (1-hydroxycyclohexyl phenyl ketone; product name: “Omnirad184”; manufactured by IGM Resins B.V.): 5 parts by mass;

Methyl isobutyl ketone: 10 parts by mass.

### (Resin Layer Composition 13)

Urethane acrylate (product name: “UV-3310B”; manufactured by Mitsubishi Chemical Corporation): 80 parts by mass;

Ethoxylated pentaerythritol tetraacrylate (product name: “ATM-35E”; manufactured by Shin-Nakamura Chemical Co., Ltd.): 10 parts by mass;

Phenoxyethylacrylate (product name “Viscoat #192”; manufactured by Osaka Organic Chemical Industry Ltd.): 10 parts by mass;

Polymerization initiator (1-hydroxycyclohexyl phenyl ketone; product name: “Omnirad184”; manufactured by IGM Resins B.V.): 5 parts by mass;

Methyl isobutyl ketone: 10 parts by mass.

### (Resin Layer Composition 14)

Urethane acrylate (product name: “UV-3310B”; manufactured by Mitsubishi Chemical Corporation): 80 parts by mass;

A mixture of pentaerythritol triacrylate and pentaerythritol tetraacrylate (product name “KAYARAD PET-30”; manufactured by Nippon Kayaku Co., Ltd.): 10 parts by mass;

Phenoxyethyl acrylate (product name “Viscoat #150”; manufactured by Osaka Organic Chemical Industry Ltd.): 10 parts by mass;

Polymerization initiator (1-hydroxycyclohexyl phenyl ketone; product name: “Omnirad184”; manufactured by IGM Resins B.V.): 5 parts by mass;

Methyl isobutyl ketone: 10 parts by mass.

### (Resin Layer Composition 15)

Urethane acrylate (product name: “UV-3310B”; manufactured by Mitsubishi Chemical Corporation): 50 parts by mass;

Ethoxylated pentaerythritol tetraacrylate (product name: “ATM-35E”; manufactured by Shin-Nakamura Chemical Co., Ltd.): 40 parts by mass;

Acryloyl morpholine (product name: “ACMO”; manufactured by KJ Chemicals Corporation): 10 parts by mass;

Polymerization initiator (1-hydroxycyclohexyl phenyl ketone; product name: “Omnirad184”; manufactured by IGM Resins B.V.): 5 parts by mass;

Methyl isobutyl ketone: 10 parts by mass.

### <Preparation of Polyimide Base Material Composition>

In a 5 L separable flask, 8,960 g of dehydrated dimethylacetamide and 16.0 g (0.07 mol) of 1,3-bis(3-aminopropyl)tetramethyldisiloxane (AprTMOS) were dissolved to make a solution, which was controlled at a liquid temperature of 30° C., and to the solution, 14.6 g (0.03 mol) of 4,4′-(hexafluoroisopropylidene)diphthalic anhydride (6FDA) was gradually added with the temperature rise regulated to 2° C. or less. The resulting mixture was stirred using a mechanical stirrer for 30 minutes. To the resulting solution, 400 g (1.25 mol) of 2,2′-bis(trifluoromethyl)benzidine (TFMB) was added, followed by verifying that they were completely dissolved, and then 565 g (1.27 mol) of 4,4′-(hexafluoroisopropylidene)diphthalic anhydride (6FDA) was gradually added in several installments with the temperature rise regulated to 2° C. or less, to synthesize a polyimide precursor solution 1 (having a solid content of 10% by mass) in which a polyimide precursor 1 was dissolved.

### Examples A and Comparative Examples A

### Example A1

A polyethylene terephthalate base material having a thickness of 50 μm (product name “Cosmoshine® A4100”; manufactured by Toyobo Co., Ltd.) was prepared as a mold release film, and the resin layer composition 1 was applied on the side of the untreated surface of the polyethylene terephthalate base material by a bar coater to form a coating film. Then, the resulting coating film was heated at 70° C. for 1 minute to evaporate the solvent in the coating film, and was then exposed to ultraviolet light from the coating film side to a cumulative light dose of 100 mJ/cm² in the air by using an ultraviolet irradiation device (with an H bulb as a light source; manufactured by Fusion UV Systems Inc.) to semi-cure (half cure) the coating film, and a resin layer having a film thickness of 50 μm and composed of the urethane resin was thereby formed.

The hard coat layer composition 1 was then applied with a bar coater on the surface of the resin layer to form a coating film. After that, the resulting coating film was heated at 70° C. for 1 minute to evaporate the solvent in the coating film, and was then exposed to ultraviolet light from the coating film side to a cumulative light dose of 300 mJ/cm² under an oxygen concentration of 200 ppm or lower by using an ultraviolet irradiation device (with an H bulb as a light source; manufactured by Fusion UV Systems Inc.) to obtain a completely cured (full-cured) coating film. Thus, a hard coat layer having a film thickness of 5 μm was formed.

After this, the resin layer was removed from the polyethylene terephthalate base material. Thus, an optical film composed of the resin layer of the urethane resin and the hard coat layer was obtained.

The film thickness of each layer was defined as the arithmetic mean of film thickness values measured at 10 different locations, where a cross-section of the optical film was imaged using a scanning transmission electron microscope (STEM) (product name “S-4800”; manufactured by Hitachi High-Technologies Corporation) and the film thickness of each layer was measured at the 10 locations within the image of the cross-section. The cross-section of the optical film was imaged in the below-mentioned manner. First of all, a piece of 1 mm×10 mm cut out from the optical film was embedded in an embedding resin to prepare a block, and homogeneous sections having a thickness of 70 nm or more and 100 nm or less and having no openings or the like were cut out from the block according to a commonly used sectioning technique. For the preparation of sections, an Ultramicrotome EM UC7 from Leica Microsystems GmbH was used. Then, these homogeneous sections having no openings or the like were used as measurement samples. Subsequently, cross-sectional images of the measurement sample were acquired using a scanning transmission electron microscope (STEM). The cross-sectional images of the resin layer were acquired by setting the detector to “SE,” the accelerating voltage to “5 kV,” and the emission current to “10 μA” in the SEM observation. The focus, contrast, and brightness were appropriately adjusted at a magnification of 1,000 to 10,000 times, so that each layer could be identified by observation. The cross-sectional images of the hard coat layer were acquired by setting the detector to “TE,” the accelerating voltage to “30 kV,” and the emission current to “10 μA” in the STEM observation. The focus, contrast, and brightness were appropriately adjusted at a magnification of 5,000 to 200,000 times, so that each layer could be identified by observation. Upon the observation by SEM and STEM, the beam monitor aperture, the objective lens aperture, and the WD were respectively set to “3,” “3,” and “8 mm”. Also in Examples A2 to A15 and Comparative Examples A1 and A2, the film thickness of each layer was measured in the same manner as in Example A1.

### Example A2

In Example A2, an optical film was obtained in the same manner as in Example A1, except that the resin layer composition 2 was used instead of the resin layer composition 1.

### Example A3

In Example A3, an optical film was obtained in the same manner as in Example A1, except that the resin layer composition 3 was used instead of the resin layer composition 1.

### Example A4

In Example A4, an optical film was obtained in the same manner as in Example A1, except that the resin layer composition 4 was used instead of the resin layer composition 1.

### Example A5

In Example A5, an optical film was obtained in the same manner as in Example A1, except that the resin layer composition 5 was used instead of the resin layer composition 1.

### Example A6

In Example A6, an optical film was obtained in the same manner as in Example A1, except that the resin layer composition 6 was used instead of the resin layer composition 1.

### Example A7

In Example A7, an optical film was obtained in the same manner as in Example A1, except that the resin layer composition 7 was used instead of the resin layer composition 1.

### Example A8

In Example A8, an optical film was obtained in the same manner as in Example A3, except that the thickness of the resin layer was 40 μm.

### Example A9

In Example A9, an optical film was obtained in the same manner as in Example A3, except that the thickness of the resin layer was 25 μm.

### Example A10

In Example A10, an optical film was obtained in the same manner as in Example A1, except that the resin layer composition 8 was used instead of the resin layer composition 1 and that the thickness of the resin layer was 70 μm.

### Example A11

In Example A11, an optical film was obtained in the same manner as in Example A10, except that the thickness of the resin layer was 80 μm.

### Example A12

In Example A12, an optical film was obtained in the same manner as in Example A10, except that the thickness of the resin layer was 90 μm.

### Example A13

In Example A13, an optical film was obtained in the same manner as in Example A10, except that the thickness of the resin layer was 100 μm.

### Example A14

In Example A14, an optical film was obtained in the same manner as in Example A10, except that the thickness of the resin layer was 115 μm.

### Example A15

In Example A15, an optical film was obtained in the same manner as in Example A10, except that the thickness of the resin layer was 140 μm.

### Comparative Example A1

In Comparative Example A1, an optical film was obtained in the same manner as in Example A1, except that the resin layer composition 9 was used instead of the resin layer composition 1 and that ultraviolet light was irradiated from the coating film side to a cumulative light dose of 500 mJ/cm² in the air when the resin layer was formed.

### Comparative Example A2

In Comparative Example A2, an optical film was obtained in the same manner as in Example A1, except that the resin layer composition 10 was used instead of the resin layer composition 1, and that additional ultraviolet light was irradiated from the mold release film side to a cumulative light dose of 300 mJ/cm² in the air when the hard coat layer was formed.

### <Measurement of Displacement Amount>

For the optical films according to Examples A1 to A15 and Comparative Examples A1 and A2, an indentation test was carried out as follows: a Berkovich indenter was pressed into the first to third regions of the resin layer at a certain load, and the displacement amounts d1 to d3 were each measured. Specifically, a piece having a size of 1 mm×10 mm was cut out from the optical film and embedded in an embedding resin to prepare a block, and homogeneous sections having a thickness of 70 nm or more and 100 nm or less and having no openings or the like were cut out from the block according to a commonly used sectioning technique. For the preparation of sections, an Ultramicrotome EM UC7 from Leica Microsystems GmbH was used. Then, the block remaining after cutting out the homogeneous sections having no openings or the like was used as a measurement sample. In this measurement sample, the resin layer was divided into three equal parts in the film thickness direction of the resin layer, and these three parts were defined as first region, second region, and third region in the order from the first surface, which was on the side of the hard coat layer of the resin layer, to the second surface opposite to the first surface. Subsequently, in the cross-section of the measurement sample obtained after cutting out the above-described sections, using a nanoindenter (TI950 TriboIndenter manufactured by BRUKER Corporation), a Berkovich indenter (a trigonal pyramid, TI-0039, manufactured by BRUKER Corporation) as the above-described indenter was pressed perpendicularly into the first region of the resin layer at the center of the cross-section, wherein the indenter was pressed up to the maximum load of 200 μN over 40 seconds under the below-mentioned measurement conditions. The amount of displacement (indentation depth) d1 was thus measured. Here, in order to avoid the influence of the side edges of the resin layer, the Berkovich indenter was pressed into a part of the first region which was 500 nm or more away from both edges of the resin layer toward the center of the resin layer. The arithmetic mean of the measurements at 3 different locations was determined as the displacement amount d1. In cases where a measured value which fell outside the arithmetic mean plus and minus 20% was included in the measured values, the measured value was to be excluded to repeat the measurement again. Whether or not a measured value which fell outside the arithmetic mean plus and minus 20% was included in the measured values was determined by the formula described in the embodiments. The displacement amount d2 of the second region and the displacement amount d3 of the third region of the resin layer were also measured in the same manner as the displacement amount d1 of the first region.

### (Measurement Conditions)

Control method: Load control (maximum load of 200 μN)

Lift amount: 0 nm

Preload: 0.5 μN

Loading speed: 5 μN/sec

Dwell time at maximum load: 5 sec

Unloading speed: 5 μN/sec

Temperature: 23° C.

Relative humidity: 50%

### <Foldability>

The optical films according to Examples A1 to A15 and Comparative Examples A1 and A2 were evaluated for foldability by carrying out a successive folding test on the optical films. Specifically, a sample was cut out from each optical film in a size of 30×100 mm. Two opposing edges of the sample thus cut out were fixed to the fixing members, respectively, arranged parallel to each other of a folding endurance testing machine (product name: “Tension Free U-shape Folding Test Machine DLDMLH-FS”; manufactured by Yuasa System Co., Ltd.; in accordance with IEC 62715-6-1). Then, as shown in FIG. 4(C), the sample was tested by repeating the folding test 100,000 times, in each of which the sample was folded under the following conditions in such a manner that the minimum gap distance p between the two opposing edges was 10 mm, with the front surface of the optical film (the side of the hard coat layer) facing outward. Thus, the presence of any deformation, crack or break at the bent part was examined. The successive folding test was performed in an environment at a temperature of 23° C. and a relative humidity of 50%. The evaluation criteria were as follows. The foldability was considered good as long as no crack or no break was formed at the bent part.

A: no deformation, crack or break was formed at the bent part in the successive folding tests.
B: deformation was found at a level which was not problematic for practical use, but no crack or break was formed at the bent part in the successive folding tests.
C: deformation was clearly observed, but no crack or break was formed at the bent part in the successive folding tests.
D: a crack(s) or a break(s) was/were formed at the bent part in the successive folding tests.

### <Impact Resistance>

The optical films according to Examples A1 to A15 and Comparative Examples A1 and A2 were subjected to an impact resistance test. Specifically, the impact resistance test was performed three times on each of the optical films according to Examples A1 to A15 and Comparative Examples A1 and A2, in which each optical film was directly placed on the surface of a soda-lime glass with a thickness of 0.7 mm in such a manner that the hard coat layer of the optical film was positioned uppermost, and a 100-g iron ball with a diameter of 30 mm was dropped from 30 cm above the surface of the hard coat layer. In the impact resistance test, the position to which the iron ball was dropped was to be changed each time when the ball was dropped. Then, each optical film after the impact resistance test was visually evaluated for the presence of any depression on the surface of the hard coat layer and any crack in the soda-lime glass. The evaluation results were based on the following evaluation criteria. The impact resistance was considered good as long as any of the depression evaluation on the surface of the hard coat layer and the crack evaluation of the soda-lime glass was not “D”.

### (Evaluation of a Depression on the Surface of a Hard Coat Layer)

A: no depression was identified on the surface of a hard coat layer in both cases where the hard coat layer was observed in the perpendicular direction and in the diagonal direction.
B: a depression was identified on the surface of a hard coat layer in either of the cases where the hard coat layer was observed in the perpendicular direction and in the diagonal direction, but the depression was not so serious as to warrant exclusion from practical use.
C: no depression was identified on the surface of a hard coat layer in a case where the hard coat layer was observed in the perpendicular direction, while a depression was identified on the surface of the hard coat layer in a case where the hard coat layer was observed in the diagonal direction.
D: an obvious depression was identified on the surface of a hard coat layer in both cases where the hard coat layer was observed in the perpendicular direction and in the diagonal direction.

### (Evaluation of a Crack in a Soda-Lime Glass)

A: neither any crack nor any scratch was formed in a soda-lime glass.
B: there was no crack but a scratch formed in a soda-lime glass.
C: the formation of crack in a soda-lime glass was observed in one trial.
D: the formation of crack in a soda-lime glass was observed in two and three trials.

### <Pencil Hardness>

The pencil hardness of the front surface of each of the optical films (the surface of each hard coat layer) according to Examples A1 to A15 and Comparative Examples A1 and A2 was measured based on JIS K5600-5-4: 1999. Specifically, a piece having a size of 30 mm×100 mm was cut out from the optical film and fixed on a glass plate having a thickness of 2 mm and a size of 50 mm×100 mm with Cello-tape®, manufactured by Nichiban Co., Ltd., so as to generate no fold or wrinkle. Using a pencil hardness testing machine (product name “Pencil Scratch Hardness Tester (electric type)”; manufactured by Toyo Seiki Seisaku-sho, Ltd.), in an environment at a temperature of 23° C. and a relative humidity of 50%, a pencil (product name “uni”; manufactured by Mitsubishi Pencil Co., Ltd.) was moved at a speed of 1 mm/second while a load of 750 g was applied to the pencil. The grade of the hardest pencil that did not scratch the front surface of the optical film (surface of the hard coat layer) during the pencil hardness test was determined as the pencil hardness of the optical film. A plural number of pencils with different hardness were used for the measurement of pencil hardness and the pencil hardness test was repeated five times on each pencil. In cases where no scratch was visibly detected on the front surface of the optical film in four or more out of the five replicates when the front surface of the optical film was observed under transmitting fluorescent light, the pencil with the hardness was determined to make no scratch on the front surface of the optical film.

The results are shown in Table 1 below.

TABLE 1

| | | | | | | | Impact resistance | | |
|---|---|---|---|---|---|---|---|---|---|
| | | | | Resin | | | Surface | Crack in | |
| | | | | layer | | | depression | soda- | |
| | Displacement amount (nm) | | | thickness | | | of hard | lime | Pencil |
| | d1 | d2 | d3 | (μm) | d1/d3 | Foldability | coat layer | glass | hardness |
| Example A1 | 166 | 171 | 204 | 50 | 0.81 | C | A | A | 6 H |
| Example A2 | 268 | 279 | 337 | 50 | 0.80 | B | A | A | 5 H |
| Example A3 | 398 | 485 | 524 | 50 | 0.76 | A | A | A | 4 H |
| Example A4 | 480 | 524 | 552 | 50 | 0.87 | B | A | A | 4 H |
| Example A5 | 324 | 459 | 476 | 50 | 0.68 | A | A | A | 4 H |
| Example A6 | 674 | 765 | 812 | 50 | 0.83 | A | B | B | 4 H |
| Example A7 | 810 | 907 | 1012 | 50 | 0.80 | A | C | B | 3 H |
| Example A8 | 421 | 492 | 531 | 40 | 0.76 | A | B | B | 4 H |
| Example A9 | 424 | 465 | 512 | 25 | 0.82 | A | B | C | 3 H |
| Example A10 | 350 | 444 | 465 | 70 | 0.75 | A | A | A | 5 H |
| Example A11 | 330 | 446 | 472 | 80 | 0.70 | A | A | A | 5 H |
| Example A12 | 330 | 455 | 481 | 90 | 0.69 | A | A | A | 5 H |
| Example A13 | 338 | 455 | 480 | 100 | 0.70 | A | A | A | 5 H |
| Example A14 | 321 | 462 | 486 | 115 | 0.66 | B | B | A | 6 H |
| Example A15 | 318 | 465 | 490 | 140 | 0.65 | C | B | A | 6 H |
| Comparative | 456 | 422 | 480 | 50 | 0.95 | D | B | A | 4 H |
| Example A1 | | | | | | | | | |
| Comparative | 393 | 455 | 429 | 50 | 0.92 | D | A | A | 4 H |
| Example A2 | | | | | | | | | |

The results will be described below. The optical film according to Comparative Example A1 was poor in foldability because the displacement amount d1 was larger than the displacement amount d2 and the above relationship (1) was not satisfied. The optical film according to Comparative Example A2 was also poor in foldability because the displacement amount d2 was larger than the displacement amount d3 and the above relationship (1) was not satisfied. On the other hand, the optical films according to Examples A1 to A15 had good foldability and impact resistance since the above relationship (1) was satisfied.

### Examples B and Comparative Examples B

### Example B1

Using the polyimide precursor solution 1 obtained above, a monolayered polyimide base material having a thickness of 12 μm was prepared by the following procedure. First, the polyimide precursor solution 1 was applied onto a glass plate and dried in a circulation oven at 120° C. for 10 minutes to form a coating film. After the coating film was formed, the glass plate with the coating film was heated to 350° C. under a nitrogen stream (oxygen concentration of 100 ppm or less) at a heating rate of 10° C./min, held at 350° C. for 1 hour, and then cooled to room temperature. As a result, a monolayered polyimide base material formed on the glass plate was obtained.

A hard coat layer composition 1 was then applied with a bar coater on the surface (second surface) of the polyimide base material to form a coating film. Then, the resulting coating film was heated at 70° C. for 1 minute to evaporate the solvent in the coating film, and was then exposed to ultraviolet light to a cumulative light dose of 200 mJ/cm² in the air by using an ultraviolet irradiation device (with an H bulb as a light source; manufactured by Fusion UV Systems Inc.) to obtain a cured coating film. Thus, a hard coat layer having a film thickness of 5 μm was formed on the polyimide base material.

After the hard coat layer was formed on the polyimide base material, the glass plate was removed from the polyimide base material. The resin layer composition 11 was applied on the first surface of the polyimide base material, which was opposite to the second surface, by a bar coater to form a coating film. Then, the resulting coating film was heated at 70° C. for 1 minute to evaporate the solvent in the coating film, and was then exposed to ultraviolet light to a cumulative light dose of 1,200 mJ/cm² in the air by using an ultraviolet irradiation device (with an H bulb as a light source; manufactured by Fusion UV Systems Inc.) to cure the coating film, and a resin layer having a film thickness of 80 μm and composed of the urethane resin was thereby formed. An optical film was thus obtained.

The thickness of the polyimide base material was defined as the arithmetic mean of thickness values measured at 20 different locations, where a cross-section of the polyimide base material was imaged using a scanning electron microscope (SEM) and the thickness of the polyimide base material was measured at the 20 locations within the image of the cross-section. The method of acquiring cross-sectional images was the same as the method of acquiring cross-sectional images of the hard coat layer during the measurement of the film thickness of the hard coat layer, which was described in Example A. The film thickness of the resin layer and the film thickness of the hard coat layer were also measured in the same manner as the thickness of the polyimide base material. Also in other Examples B2 to B7 and Comparative Examples B1 to B4, the thickness of the polyimide base material, the film thickness of the resin layer, and the film thickness of the hard coat layer were measured in the same manner as in Example B1.

### Example B2

In Example B2, an optical film was obtained in the same manner as in Example B1, except that the thickness of the polyimide base material was 8 μm.

### Example B3

In Example B3, an optical film was obtained in the same manner as in Example B1, except that the thickness of the polyimide base material was 18 μm.

### Example B4

In Example B4, an optical film was obtained in the same manner as in Example B1, except that the thickness of the resin layer was 60 μm.

### Example B5

In Example B5, an optical film was obtained in the same manner as in Example B1, except that the thickness of the resin layer was 100 μm.

### Example B6

In Example B6, an optical film was obtained in the same manner as in Example B1, except that the resin layer composition 12 was used instead of the resin layer composition 11.

### Example B7

In Example B7, an optical film was obtained in the same manner as in Example B1, except that the resin layer composition 13 was used instead of the resin layer composition 11.

### Comparative Example B1

In Comparative Example B1, an optical film was obtained in the same manner as in Example B1, except that the thickness of the polyimide base material was 30 μm.

### Comparative Example B2

In Comparative Example B2, an optical film was obtained in the same manner as in Example B1, except that the thickness of the resin layer was 30 μm.

### Comparative Example B3

In Comparative Example B3, an optical film was obtained in the same manner as in Example B1, except that the resin layer composition 14 was used instead of the resin layer composition 11.

### Comparative Example B4

In Comparative Example B4, an optical film was obtained in the same manner as in Example B1, except that the resin layer composition 15 was used instead of the resin layer composition 11.

### <Measurement of Displacement Amount>

For the optical films according to Examples B1 to B7 and Comparative Examples B1 to B4, an indentation test was carried out for each as follows: a Berkovich indenter was pressed into the cross-sections of polyimide base material and the resin layer at a maximum load of 200 μN, and the displacement amounts d4 of the polyimide base material and the displacement amount d5 of the resin layer were each measured. The displacement amount d4 was measured in the same manner as the displacement amounts d1 to d3 described in Example A. The Berkovich indenter was pressed into the polyimide base material at a position located 500 nm or more away from both edges of the polyimide base material toward the center of the polyimide base material, in order to avoid the influence of the side edges of the polyimide base material. The arithmetic mean of the measurements at 3 different locations was determined as the displacement amount d4. In cases where a measured value which fell outside the arithmetic mean plus and minus 20% was included in the measured values, the measured value was to be excluded to repeat the measurement again. Whether or not a measured value which fell outside the arithmetic mean plus and minus 20% was included in the measured values was determined by the formula described in the embodiments. The displacement amount d5 of the resin layer was also measured in the same manner as the displacement amount d4 of the polyimide base material.

### <Foldability>

The optical films according to Examples B1 to B7 and Comparative Examples B1 to B4 were evaluated for foldability by carrying out a successive folding test on the optical films. The successive folding test was carried out in the same manner as the successive folding test described in Example A. The evaluation criteria were also the same as those in the successive folding test described in Example A.

### <Crease Evaluation>

The optical films according to Examples B1 to B7 and Comparative Examples B1 to B4 were evaluated for a crease in the static folding test. Specifically, a piece having a size of 30 mm×100 mm was first cut out from each optical film. Then, the regions of 30 mm×48 mm containing the edges on the two opposing short sides (30 mm) of the cut optical film were fixed to glass plates having a size of 50 mm×100 mm. The glass plate was fixed to the side of the resin layer of the optical film. Then, the glass plates were arranged in parallel so that the distance between the opposing edges of the optical film was 2.5 mm. Thus, the optical film was folded with the hard coat layer facing inward. In this state, the optical film was subjected to the static folding test, in which the optical film was left at the temperature of 25° C. and the relative humidity of 50% for 100 hours. After that, the optical film was opened with the glass plates fixed, and the front surface of the optical film was flattened. In this state, the presence of a crease on the front surface of the optical film was visually confirmed. The evaluation criteria were as follows.

A: no crease was detected on the optical film in both cases where the optical film was observed in perpendicular and diagonal directions.
B: a slight crease was detected on the optical film in either of the cases where the optical film was observed in the perpendicular direction and in the diagonal direction, but the crease was not so serious as to warrant exclusion from practical use.
C: no crease was detected on the optical film when the optical film was observed in the perpendicular direction, while a crease was detected in the optical film when the optical film was observed in a diagonal direction.
D: a crease was clearly detected in the optical film in both cases where the optical film was observed in perpendicular and diagonal directions.

### <Impact Resistance Evaluation>

The optical films according to Examples B1 to B7 and Comparative Examples B1 to B4 were subjected to an impact resistance test. Specifically, a piece having a size of 50 mm×50 mm was first cut out from each optical film. The impact resistance test was performed three times on each of the optical films, in which each optical film was directly placed on the surface of a soda-lime glass with a thickness of 0.7 mm and a size of 50 mm×50 mm in such a manner that the hard coat layer was positioned uppermost. A 100-g ballpoint pen having a nib with a diameter of 0.7 mm (Orange 0.7 manufactured by BIC Japan) was dropped from 30 cm above the surface of the hard coat layer of the optical film, with the nib facing downward. Here, the position onto which the pen was dropped in an impact resistance test was changed each time. Then, each optical film after the impact resistance test was visually evaluated for the presence of any depression on the surface of the hard coat layer. The evaluation results were based on the following evaluation criteria.

A: no depression was identified on the surface of a hard coat layer in both cases where the hard coat layer was observed in the perpendicular direction and in the diagonal direction.
B: a depression was identified on the surface of a hard coat layer in either of the cases where the hard coat layer was observed in the perpendicular direction and in the diagonal direction, but the depression was not so serious as to warrant exclusion from practical use.
C: no depression was identified on the surface of a hard coat layer in a case where the hard coat layer was observed in the perpendicular direction, while a depression was identified on the surface of the hard coat layer in a case where the hard coat layer was observed in the diagonal direction.
D: an obvious depression was identified on the surface of a hard coat layer in both cases where the hard coat layer was observed in the perpendicular direction and in the diagonal direction.

### <Pencil Hardness>

The pencil hardness of the front surface of each of the optical films according to Examples B1 to B7 and Comparative Examples B1 to B4 (the surface of each hard coat layer) was measured based on JIS K5600-5-4: 1999. The pencil hardness was measured in the same manner as the pencil hardness described in Example A.

The results are shown in Table 2 below.

TABLE 2

| | | | Resin layer | | | | | | |
|---|---|---|---|---|---|---|---|---|---|
| | | | film | | | | | | |
| | PI base | Resin layer | thickness/ | | | | | | |
| | material | film | PI base | Displacement | Displacement | | | | |
| | thickness | thickness | material | amount d4 | amount d5 | | | Impact | Pencil |
| | (μm) | (μm) | thickness | (nm) | (nm) | Foldability | Crease | resistance | hardness |
| Example B1 | 12 | 80 | 6.67 | 151 | 812 | A | A | A | 3 H |
| Example B2 | 8 | 80 | 10.0 | 143 | 789 | A | A | A | 2 H |
| Example B3 | 18 | 80 | 4.44 | 163 | 803 | A | B | A | 4 H |
| Example B4 | 12 | 60 | 5.00 | 153 | 598 | A | A | B | 3 H |
| Example B5 | 12 | 100 | 5.33 | 154 | 997 | A | A | A | 3 H |
| Example B6 | 12 | 80 | 6.67 | 151 | 723 | A | A | B | 3 H |
| Example B7 | 12 | 80 | 6.67 | 152 | 759 | A | A | B | 3 H |
| Comparative | 30 | 80 | 2.67 | 186 | 782 | B | C | B | 5 H |
| Example B1 | | | | | | | | | |
| Comparative | 12 | 30 | 2.50 | 161 | 381 | A | A | D | 3 H |
| Example B2 | | | | | | | | | |
| Comparative | 12 | 80 | 6.67 | 157 | 195 | C | D | A | 3 H |
| Example B3 | | | | | | | | | |
| Comparative | 12 | 80 | 6.67 | 155 | 1601 | A | A | C | F |
| Example B4 | | | | | | | | | |

The results will be described below. In the optical film according to Comparative Example B1, the polyimide base material was so thick that a crease was detected after the static folding test. In the optical film according to Comparative Example B2, since the resin layer had an excessively thin film thickness, good impact resistance could not be obtained. In the optical film according to Comparative Example B3, the displacement amount of the resin layer in the indentation test was too small, and good foldability could not be obtained. In the optical film according to Comparative Example B4, the displacement amount of the resin layer in the indentation test was too large, and the impact resistance could not be ensured. On the other hand, in the optical films according to Examples B1 to B7, the thickness of the polyimide base material was 20 μm or less; the film thickness of the resin layer was 50 μm or more; the ratio of the film thickness of the resin layer to the thickness of the polyimide base material was 4.0 or more and 12.0 or more; the displacement amount d4 of the polyimide base material when the indentation test was performed was 50 nm or more and 250 nm or less; and the displacement amount d5 of the resin layer when the indentation test was performed was 200 nm or more and 1500 nm or less. Thus, no crease was detected when the static folding test was performed, and good impact resistance was obtained.

### Examples C and Comparative Examples C

### Example C1

A polyimide base material (product name: “Neopulim®”; manufactured by Mitsubishi Gas Chemical Company, Inc.) with a thickness of 50 μm was set up as a resin base material. The Neopulim® used in Examples C1 to C5 and Comparative Examples C1 to C3 was a commercially available polyimide film. The hard coat layer composition 2 was applied with a bar coater on one surface of the polyimide base material to form a coating film. Then, the resulting coating film was heated at 70° C. for one minute to evaporate the solvent in the coating film, and was then exposed to ultraviolet light to a cumulative light dose of 200 mJ/cm² in the air with an ultraviolet irradiation device (with an H bulb as a light source; manufactured by Fusion UV Systems Inc.) to be cured. Thus, a first hard coat layer having a film thickness of 3 μm was formed.

Next, the hard coat layer composition 3 was applied with a bar coater on the surface of the first hard coat layer to form a coating film. The resulting coating film was heated at 70° C. for 1 minute to evaporate the solvent in the coating film, and was then exposed to ultraviolet light to a cumulative light dose of 200 mJ/cm² under an oxygen concentration of 200 ppm or lower with an ultraviolet irradiation device (with an H bulb as a light source; manufactured by Fusion UV Systems Inc.) to cure the coating film. Thus, a hard coat layer composed of the first hard coat layer having a film thickness of 3 μm and placed on the polyimide base material and the second hard coat layer having a film thickness of 3 μm and overlaid on the first hard coat layer was formed, and an optical film was obtained.

The film thickness of each layer was defined as the arithmetic mean of film thickness values measured at 10 different locations, where a cross-section of the optical film was imaged using a scanning transmission electron microscope (STEM) (product name “S-4800”; manufactured by Hitachi High-Technologies Corporation) and the film thickness of each layer was measured at the 10 locations within the image of the cross-section. The cross-section of the optical film was imaged in the below-mentioned manner. First of all, a piece of 1 mm×10 mm cut out from the optical film was embedded in an embedding resin to prepare a block, and homogeneous sections having a thickness of 70 nm or more and 100 nm or less and having no openings or the like were cut out from the block according to a commonly used sectioning technique. For the preparation of sections, an Ultramicrotome EM UC7 from Leica Microsystems GmbH was used. Then, these homogeneous sections having no openings or the like were used as measurement samples. Subsequently, cross-sectional images of the measurement sample were acquired using a scanning transmission electron microscope (STEM). The cross-sectional images were acquired by setting the detector to “TE,” the accelerating voltage to “30 kV,” and the emission current to “10 μA” in the STEM observation. The focus, contrast, and brightness were appropriately adjusted at a magnification of 5,000 to 200,000 times, so that each layer could be identified by observation. Furthermore, the beam monitor aperture, the objective lens aperture, and the WD were respectively set to “3,” “3,” and “8 mm,” in acquirement of cross-sectional images. Also in Examples C2 to C5 and Comparative Examples C1 to C3, the film thickness of each layer was measured in the same manner as in Example C1.

### Example C2

In Example C2, an optical film was obtained in the same manner as in Example C1, except that the film thickness of the first hard coat layer was 4 μm and the film thickness of the second hard coat layer was 4 μm.

### Example C3

In Example C3, an optical film was obtained in the same manner as in Example C1, except that the hard coat layer composition 4 was used instead of the hard coat layer composition 2.

### Example C4

In Example C4, an optical film was obtained in the same manner as in Example C1, except that the hard coat layer composition 5 was used instead of the hard coat layer composition 3.

### Example C5

In Example C5, an optical film was obtained in the same manner as in Example C1, except that an inorganic layer having a film thickness of 100 nm and composed of SiOₓ (x=1 to less than 2) was formed on the surface of the second hard coat layer of the optical film according to Example C1 by sputtering, and that an antifouling layer having a film thickness of 2 nm and composed of a fluorine-containing organosilicon compound was further formed by a vacuum vapor deposition method.

### Comparative Example C1

A polyimide base material having a thickness of 50 μm (product name “Neopulim®”; manufactured by Mitsubishi Gas Chemical Company, Inc.) was set up as a resin base material, and the hard coat layer composition 2 was applied on one surface of the polyimide base material, considered as a first surface, by bar coater to form a coating film. Then, the resulting coating film was heated at 70° C. for one minute to evaporate the solvent in the coating film, and was then exposed to ultraviolet light to a cumulative light dose of 400 mJ/cm² under an oxygen concentration of 200 ppm with an ultraviolet irradiation device (with an H bulb as a light source; manufactured by Fusion UV Systems Inc.) to be cured. Thus, a hard coat layer having a film thickness of 6 μm was formed, and an optical film was obtained.

### Comparative Example C2

In Comparative Example C2, an optical film was obtained in the same manner as in Example C1, except that the hard coat layer composition 3 was used instead of the hard coat layer composition 2, and that the hard coat layer composition 2 was used instead of the hard coat layer composition 3. That is, the optical film according to Comparative Example C2 comprised a first hard coat layer and a second hard coat layer containing organic particles on the first hard coat layer.

### Comparative Example C3

A polyimide base material having a thickness of 50 μm (product name “Neopulim®”; manufactured by Mitsubishi Gas Chemical Company, Inc.) was set up as a resin base material, and the hard coat layer composition 3 was applied on one surface of the polyimide base material, considered as a first surface, by bar coater to form a coating film. Then, the resulting coating film was heated at 70° C. for one minute to evaporate the solvent in the coating film, and was then exposed to ultraviolet light to a cumulative light dose of 200 mJ/cm² in the air with an ultraviolet irradiation device (with an H bulb as a light source; manufactured by Fusion UV Systems Inc.) to be cured. Thus, a hard coat layer having a film thickness of 6 μm was formed, and an optical film was obtained.

### <Evaluation of Uneven Distribution of Organic Particles>

In the optical films according to Examples C1 to C5 and Comparative Examples C1 and C2, it was studied whether or not the organic particles were unevenly distributed on the side of the polyimide base material with respect to the center line that bisects the hard coat layer in the film thickness direction of the hard coat layer. Specifically, the cross-section of the hard coat layer was photographed using a scanning transmission electron microscope (STEM) (product name “S-4800”; manufactured by Hitachi High-Technologies Corporation), under the same conditions as in the measurement of the film thickness of each layer. The cross-sectional images at 10 locations were thus acquired. In each cross-sectional image, the film thickness of the hard coat layer was measured to determine the position of the center line. In addition, the centers of the organic particles present in each cross-sectional image were obtained. The center was obtained by finding the midpoint of the imaginary line segment of an organic particle, connecting the point closest to and the point farthest from the polyimide base material in the film thickness direction of the hard coat layer. Then, in each cross-sectional image, the distance between the center of the organic particle and the center line was measured. When the center of the organic particle was located below the center line (the side of the polyimide base material), the distance between the center of the organic particle and the center line was expressed with “−”. When the center was located above the center line, the distance between the center of the organic particle and the center line was expressed with “+”. Then, by determining the average distance, the average position of the centers was obtained. Whether or not this average position of the centers was present on the side of the polyimide base material with respect to the center line was determined depending on whether the obtained average position was “−” or “+”. The evaluation criteria were as follows. Since the optical film according to Comparative Example C3 did not contain organic particles, it was not evaluated.

A: Organic particles were unevenly distributed on the side of the polyimide base material with respect to the center line.
B: Organic particles were not unevenly distributed on the side of the polyimide base material with respect to the center line.

### <Foldability>

The optical films according to Examples C1 to C5 and Comparative Examples C1 to C3 were evaluated for foldability by carrying out a successive folding test on the optical film. Specifically, a piece of each optical film was first cut to a size of 30 mm×100 mm and was mounted to an endurance testing machine (product name: “DLDMLH-FS”: manufactured by Yuasa System Co., Ltd.) by fixing the short edges of the optical film to fixing members, as shown in FIG. 4(C), in such a manner that the minimum gap distance between the two opposing edges was 8 mm, and the piece of the optical film was folded 100,000 times in the successive folding test, in such a manner that the front surface of the optical film (the side of the hard coat layer in Examples C1 to C4 and Comparative Examples C1 to C3 and the side of the antifouling layer in Example C5) faced outward, to examine whether any crack or break was formed at the bent part. The evaluation criteria were as follows.

A: no crack or break was formed at the bent part in the successive folding tests.
B: a slight crack or break was formed at the bent part in the successive folding tests, but the damage was not so serious as to warrant exclusion from practical use.
C: a crack or a break was evidently formed at the bent part in the successive folding tests.

### <Measurement of Haze Value>

The optical films according to Examples C1 to C5 and Comparative Examples C1 to C3 were measured for the haze value (total haze value) in an environment at a temperature of 23° C. and a relative humidity of 50%, using a haze meter (product name “HM-150”; manufactured by Murakami Color Research Laboratory Co., Ltd.) in accordance with JIS K7136: 2000. The above-described total light transmittance and the above-described haze value were defined as the arithmetic mean of three measurements, wherein three haze values were obtained by cutting a piece of 50 mm×100 mm from one optical film and placing the optical film piece without any curl or wrinkle and without any fingerprint or dirt, into the haze meter in such a manner that the polyimide base material side faced the light source to measure the haze value, and repeating the measurement three times for one optical film.

### <Transmission Image Sharpness>

The optical films according to Examples C1 to C5 and Comparative Examples C1 to C3 were measured for the transmission image sharpness in an environment at a temperature of 23° C. and a relative humidity of 50%, using an image clarity meter (product name: “ICM-1T”; manufactured by Suga Test Instruments Co., Ltd.) in accordance with JIS K7374: 2007. The above transmission image sharpness was defined as the arithmetic mean of three measurements for one optical comb, obtained by installing a cut piece of the optical film in a size of 50 mm×100 mm without generation of any curl or wrinkle and without any dirt such as fingerprints or grim into an image clarity meter in which the optical axis rotation stage and sample stage were set with “transmission” in a way that the polyimide base material faced the light source, and measuring the cut piece of the optical film three times.

### <Pressing Mark Evaluation>

The appearance of each of the optical films according to Examples C1 to C5 and Comparative Examples C1 to C3 was observed in the environment with a temperature of 23° C. and a relative humidity of 50%. Specifically, a colorless transparent glass having a thickness of 1 mm and the side of the polyimide base material of the optical film were bonded together via two transparent adhesive layers (product number “8146-4”, manufactured by 3M) having a thickness of 100 μm. Thus, an evaluation sample having a size of 5 cm×10 cm was prepared. The evaluation sample was placed on the black stand with the optical film facing upward. A polyethylene terephthalate film (PET film) with a thickness of 250 μm and a size of 20 mm×200 mm (product name “A4300”, TOYOBO Co., Ltd.) was placed on the evaluation sample, and a cylindrical 300-g weight with a diameter of 35 mm was placed on the PET film. After the resulting film was allowed to stand for 1 minute, the weight and PET film were removed. It was observed whether a pressing mark of the weight was confirmed or not on the PET film after 3 seconds. The evaluation criteria were as follows.

### (Pressing Mark Evaluation)

A: no pressing mark was found.
B: a slight pressing mark was found, but the pressing mark was not so serious as to warrant exclusion from practical use.
C: a pressing mark(s) was/were clearly found.

### <Measurement of Indentation Hardness (H_{IT})>

The indentation hardness (H_{IT}) of the upper and lower parts of the hard coat layer of the optical film according to Examples C1 to C5 was measured. Specifically, a piece having a size of 1 mm×10 mm was cut out from each optical film and embedded in an embedding resin to prepare a block, and homogeneous sections having a thickness of 70 nm or more and 100 nm or less and having no openings or the like were cut out from the block according to a commonly used sectioning technique. For the preparation of sections, an Ultramicrotome EM UC7 from Leica Microsystems GmbH was used. Then, the block remaining after cutting out the homogeneous sections having no openings or the like was used as a measurement sample. Subsequently, in the cross-section of the measurement sample obtained after cutting out the above-described sections, using a TI950 TriboIndenter manufactured by BRUKER Corporation, a Berkovich indenter (a trigonal pyramid, TI-0039, manufactured by BRUKER Corporation) as the above-described indenter was pressed perpendicularly into the hard coat layer at the bottom cross-section, wherein the indenter was pressed up to the maximum pressing load of 50 μN over 10 seconds under the below-mentioned measurement conditions. Here, a Berkovich indenter was pressed into the lower part of the hard coat layer, wherein the part was 500 nm away from the interface between the polyimide base material and the hard coat layer toward the center of the hard coat layer and 500 nm or more away from both edges of the hard coat layer toward the center of the hard coat layer. Subsequently, the indenter was held for 5 seconds, and then unloaded over 10 seconds. The above maximum pressing load Pₘₐₓ and the contact projection area Aₚ were used to calculate an indentation hardness (H_{IT}) from Pₘₐₓ/Aₚ. The contact projection area is a contact projection area, for which the tip curvature of the indenter is corrected using fused quartz (5-0098, manufactured by BRUKER) as a standard sample in accordance with the Oliver-Pharr method. The arithmetic mean of the measurements at 10 different locations was determined as the indentation hardness (H_{IT}). In cases where a measured value which fell outside the arithmetic mean plus and minus 20% was included in the measured values, the measured value was to be excluded to repeat the measurement again. Whether or not a measured value which fell outside the arithmetic mean plus and minus 20% was included in the measured values was determined by whether or not a value (%) obtained by the formula (A−B)/B×100 equaled or exceeded ±20%, where A represents a measured value and B represents the arithmetic mean. The indentation hardness of the upper part of the hard coat layer was also measured in the same manner as the indentation hardness of the lower part of the hard coat layer. In this case, a Berkovich indenter was pressed into the upper part of the hard coat layer at a position located 500 nm away from the surface of the hard coat layer toward the center of the hard coat layer and 500 nm or more away from both edges of the hard coat layer toward the center of the hard coat layer.

### (Measurement Conditions)

Control mode: Load control mode

Loading speed: 5 μN/sec

Dwell time: 5 sec

Unloading speed: 5 μN/sec

Temperature: 23° C.

Relative humidity: 50%

### <Abrasion Resistance>

The front surface of each of the optical films according to Examples C1 to C5 was subjected to an abrasion resistance test. Specifically, a piece having a size of 50 mm×100 mm was cut out from each optical film and fixed on a glass plate with Cello-tape®, manufactured by Nichiban Co., Ltd., with the front surface of the optical film facing upward, so as to generate no fold or wrinkle. A steel wool test was carried out, in which the fixed piece was scrubbed to and fro 10 times at a speed of 60 mm/second in an environment at a temperature of 23° C. and a relative humidity of 50% with steel wool with a grade of 0.0000 (product name “Bonstar”; manufactured by Nihon Steel Wool Co., Ltd.) while a load of 1 kgf/cm² was applied. Then, a black vinyl tape (black vinyl tape NO200-38-21 manufactured by Yamato Co., Ltd.) was attached to the glass surface opposite to the side where the optical film was attached, and the presence/absence of a scratch was checked under a three-wavelength fluorescent lamp. The evaluation criteria were as follows.

A: no scratch was found.
B: a slight scratch was found, but the scratch was not so serious as to warrant exclusion from practical use.
C: one or more scratches were found.
D: many scratches were found.

The results are shown in Tables 3 and 4 below.

TABLE 3

| | | | | Transmission image | | |
|---|---|---|---|---|---|---|
| | Evaluation | | | sharpness (%) | | Evaluation |
| | of uneven | | Haze value | 0.125-mm bar | 2-mm bar | of pressing |
| | distribution | Foldability | (%) | pattern | pattern | mark |
| Example C1 | A | A | 5.5 | 81.8 | 94.9 | A |
| Example C2 | A | B | 6.7 | 85.6 | 94.4 | B |
| Example C3 | A | B | 3.1 | 85.1 | 95.9 | B |
| Example C4 | A | A | 5.2 | 81.0 | 95.0 | A |
| Example C5 | A | A | 5.4 | 82.2 | 95.0 | A |
| Comparative | B | C | 9.1 | 37.6 | 83.6 | A |
| Example C1 | | | | | | |
| Comparative | B | C | 6.2 | 58.4 | 94.1 | A |
| Example C2 | | | | | | |
| Comparative | — | B | 0.3 | 96.7 | 99.1 | C |
| Example C3 | | | | | | |

TABLE 4

| | H_{IT} (MPa) | | |
|---|---|---|---|
| | Lower | Upper | Abrasion |
| | part | part | resistance |
| Example C1 | 267 | 332 | A |
| Example C2 | 255 | 320 | A |
| Example C3 | 240 | 328 | A |
| Example C4 | 270 | 213 | B |
| Example C5 | 267 | 332 | A |

The results will be described below. The optical films according to Comparative Examples C1 and C2 had poor successive foldability because the organic particles were not unevenly distributed on the side of the polyimide base material with respect to the center line. It is believed that the optical film broke due to the crack at the interface between the organic particles and the binder resin near the surface of the hard coat layer at the bent part of the optical film during the successive folding test. The optical film according to Comparative Example C3 had a hard coat layer not containing any organic particle. Therefore, the pressing mark of the weight was clearly detected. It is believed that this was because the surface of the hard coat layer was a flattened surface. The optical films according to Examples C1 to C5 had excellent successive foldability and unnoticeable pressing marks because the organic particles were unevenly distributed on the side of the polyimide base material with respect to the center line.

### LIST OF REFERENCE NUMERALS

10, 72, 82 Resin layer
30, 50, 70, 80 Optical film
31, 52, 85 Functional layer
51, 71, 81 Resin base material
60 Image display device
62 Display device
73 Hard coat layer

1. A light-transmitting resin layer for use in an image display device, wherein the resin layer is divided into three equal parts in the film thickness direction of the resin layer, which are defined as first region, second region, and third region in the order from a first surface of the resin layer to a second surface opposite to the first surface; and upon an indentation test in which a Berkovich indenter is pressed into the first region, the second region, and the third region at a certain load on the cross-section of the resin layer in the film thickness direction and in which the displacement amounts in the first region, in the second region, and in the third region are determined as d1, d2, and d3, respectively, the resin layer satisfies the relationship of d1<d2<d3.

2. The resin layer according to claim 1, wherein the ratio of d1 to d3 is 0.85 or less.

3. The resin layer according to claim 1, wherein d1 to d3 are each 200 nm or more and 1,000 nm or less.

4. The resin layer according to claim 1, wherein the film thickness is 20 μm or more and 150 μm or less.

5. A foldable optical film with a laminated structure, comprising at least the resin layer of claim 1.

6. The optical film according to claim 5, further comprising a functional layer provided on either one of the first surface and the second surface of the resin layer.

7. The optical film according to claim 5, further comprising a resin base material provided on either one of the first surface and the second surface of the resin layer.

8. A foldable light-transmitting optical film, comprising:
a resin base material; and
a resin layer provided on a first surface of the resin base material;
wherein:
the thickness of the resin base material is 20 μm or less;
the film thickness of the resin layer is 50 μm or more;
the ratio of the film thickness of the resin layer to the thickness of the resin base material is 4.0 or more and 12.0 or less;
when an indentation test in which a Berkovich indenter is pressed at a maximum load of 200 μN into the cross-section of the resin base material in the thickness direction is carried out, the displacement amount of the resin base material is 50 nm or more and 250 nm or less; and
when the indentation test is carried out on the cross-section of the resin layer in the film thickness direction, the displacement amount of the resin layer is 200 nm or more and 1,500 nm or less.

9. The optical film according to claim 8, wherein the resin base material contains at least any of a polyimide resin, a polyamide resin, and a polyamideimide resin.

10. The optical film according to claim 8, further comprising a hard coat layer provided on a second surface opposite to the first surface of the resin base material.

11. A foldable optical film for use in an image display device, comprising:
a resin base material; and
a resin layer provided on one surface of the resin base material and containing organic particles;
wherein:
the resin layer has an uneven surface; and
the organic particles are unevenly distributed on the side of the resin base material with respect to a center line that bisects the resin layer in the film thickness direction of the resin layer.

12. The optical film according to claim 11, wherein the resin base material contains one or more resins selected from the group consisting of a polyimide resin, a polyamideimide resin, a polyamide resin, and a polyester resin.

13. The optical film according to claim 11, wherein the resin layer has a film thickness of 2 μm or more and 15 μm or less.

14. The optical film according to claim 11, wherein the indentation hardness of the lower part of the resin layer is smaller than the indentation hardness of the upper part of the resin layer.

15. The optical film according to claim 11, wherein the resin layer contains a first resin layer and a second resin layer provided on the surface side of the resin layer than the first resin layer, and the first resin layer contains the organic particles.

16. The optical film according to claim 5, wherein no crack or break is formed in the optical film when the optical film is folded at an angle of 180 degrees in a manner that leaves a gap of 10 mm between the opposite edges and then unfolded, and this process is repeated 100,000 times.

17. An image display device, comprising:
a display device; and
the resin layer according to claim 1, which is placed on the observer's side of the display device.

18. The image display device according to claim 17, wherein the display device is an organic light-emitting diode device.

19. An image display device, comprising:
a display device; and
the optical film according to claim 8, which is placed on the observer's side of the display device.

20. An image display device, comprising:
a display device; and
the optical film according to claim 11, which is placed on the observer's side of the display device.
